(19) United States
(12) Patent Application Publication
(10) Pub. No.: US 2025/0379586 A1
(43) Pub. Date: Dec. 11, 2025

(54) SYSTEMS AND METHODS FOR USE IN RECONSTRUCTION OF ANALOG SIGNALS

(71) Applicant: YEDA RESEARCH AND DEVELOPMENT CO. LTD., Rehovot (IL)

(72) Inventors: Yonina ELDAR, Rehovot (IL); Hila NAAMAN, Rehovot (IL)

(21) Appl. No.: 18/998,359

(22) PCT Filed: Aug. 15, 2023
(86) PCT No.: PCT/IL2023/050859

§ 371 Date: Jan. 24, 2025

Related U.S. Application Data
(60) Provisional application No. 63/398,583, filed on Aug. 17, 2022.
(60) Provisional application No. 63/489,311, filed on Mar. 9, 2023.

(51) Int. Cl. H03M 1/06; H03M 1/08; H03M 1/12

(52) U.S. Cl. CPC H03M 1/0626; H03M 1/08; H03M 1/125

(57) ABSTRACT

Some embodiments relates to the technique, including systems and methods, for use in analog-to-digital conversion (ADC). A sampling system is presented for sampling an input analog signal including a train of pulses of a predetermined shape and allowing a recovery of the degrees of freedom of the signal. The sampling system includes: a kernel for selectively passing components of an input signal, and an integrate and fire time encoding machine (IF-TEM), wherein the kernel has a size of kernel support set being in a predetermined relation with a number of degrees of freedom in the finite rate of innovation signal.

### CROSS-REFERENCE TO RELATED APPLICATIONS

This application is a national phase filing under 35 C.F.R. § 371 of and claims priority to PCT Patent Application No. PCT/IL2023/050859, filed on Aug. 15, 2023, which claims the priority benefit under 35 U.S.C. § 119 of U.S. Provisional Patent Application No. 63/398,583, filed on Aug. 17, 2022, and U.S. Provisional Patent Application No. 63/489,311, filed on Mar. 9, 2023, the contents of each are hereby incorporated in its entirety by reference.

### TECHNOLOGICAL FIELD

This disclosure is related to the field of sampling analog signals for the purposes of their reconstruction and is particularly useful in analog-to-digital converters.

### BACKGROUND ART

References considered to be relevant as background to the presently disclosed subject matter are listed below:
1. S. Rudresh, A. J. Kamath, and C. S. Seelamantula, “A time-based sampling framework for finite-rate-of-innovation signals,” in Proc. IEEE Int. Conf. Acoust. Speech Signal Process., 2020, pp. 5585-5589.
2. R. Tur, Y. C. Eldar, and Z. Friedman, “Innovation rate sampling of pulse streams with application to ultrasound imaging,”, IEEE Trans. Signal Process., vol. 59, no. 4, pp. 1827-1842, April 2011.
3. O. Bar-Ilan and Y. C. Eldar, “Sub-Nyquist radar via doppler focusing,” IEEE Trans. Signal Process., vol. 62, no. 7, pp. 1796-1811, April 2014.
4. G. Baechler, A. Scholefield, L. Baboulaz, and M. Vetterli, “Sampling and exact reconstruction of pulses with variable width,” IEEE Transactions on Signal Processing, vol. 65, no. 10, pp. 2629-2644, 2017.
5. G. Huang, Z. Yang, W. Lu, H. Peng, and J. Wang, “SubNyquist Sampling of ECG Signals Based on the Extension of Variable Pulsewidth Model,” IEEE Transactions on Instrumentation and Measurement, vol. 71, pp. 1-14, 2022.
6. S. Schellenberger, K. Shi, T. Steigleder, A. Malessa, F. Michler, L. Hameyer, N. Neumann, F. Lurz, R. Weigel, C. Ostgathe et al., “A dataset of clinically recorded radar vital signs with synchronised reference sensor signals,” Scientific data, vol. 7, no. 1, pp. 1-11, 2020.
7. H. Pan, T. Blu, and M. Vetterli, “Towards generalized fri sampling with an application to source resolution in radioastronomy,” IEEE Transactions on Signal Processing, vol. 65, no. 4, pp. 821-835, 2016.

### BACKGROUND

Analog-to-digital converters (ADCs) are widely used electronic hardware components. They bridge the gap between computers and the outside world, by processing, for example, a sound picked up by a microphone, or a radiation sensed by a photosensor. Also, they are used in neuromorphic-based hardware.

In the classical case, ADCs convert continuous-time signals to discrete-level representations based on the Nyquist sampling theorem, which entails acquiring samples at least at ½ W second intervals for signals with a frequency no greater than W Hz, to enable an appropriate reconstruction. Such sampling, in the Shannon-Nyquist sampling theory or more general shift-invariant sampling approach, is based on measuring instantaneous signal amplitudes uniformly. Hence, the amplitude samples in this framework are measured via a sample-and-hold circuit that is controlled by a global clock operating at a rate greater than or equal to the minimal, Nyquist, sampling rate. At high sampling rates, clocks are power-consuming and prone to electromagnetic interference. Also, those clocks, which operate at higher sampling rates, are more difficult to fabricate and are more expensive. Furthermore, clock jitter substantially impacts the recovery (i.e. reconstruction) performance of classical ADCs.

However, in some cases also sub-Nyquist sampling is feasible, for example, in case of signals consisting of short pulses, where the pulse shape is known. Such signals have a finite number of degrees of freedom per unit time, also known as the finite rate of innovation (FRI) property. FRI signals are characterized by a small number of degrees of freedom that permit such sampling because they have fewer degrees of freedom than the signal's Nyquist rate. Signals can be modeled or estimated as FRI in numerous applications, including, for example, radar, ultrasound, time-domain optical-coherence tomography (TDOCT), and light detection and ranging (LIDAR). There is a need for analog-to-digital conversion, including sampling and recovery, of FRI signals while reducing the power of the systems.

In FIG. 1, a conventional FRI sampling scheme is shown. An input signal x(t) is first filtered by a sampling kernel function s(t) to remove a redundancy and generate a kernel-filtered function y(t). Then, instantaneous samples are measured at a sub-Nyquist rate providing output signal y(nT). As with the classical ADC, the scheme uses a clock.

### General Description

There is a need in the art for a more conveniently usable ADC for sampling and reconstruction of input signals, being either finite rate of innovation (FRI) signals having a fixed pulse shape, or signals of a variable-pulse-width (VPW) type.

Most of the FRI sampling art is focused on reducing the ADC's sampling rate by using the signal structure. However, the inventors of the present disclosure have addressed the usability need by considering another approach for reducing the power-consumption by ADC in combination with improving the robustness of signal reconstruction in presence of various types of noise, and especially hardware, since, as they have found through simulations and experiments, there has to be more focus on the operation in noisy conditions.

The technique of the present disclosure is based on the inventors understanding of the following: The use of time encoding machine/mechanism (TEM) an asynchronous event-driven sampler, allows for reduction in the sampling rate, which is signal-dependent (e.g., dependent on the number of degrees of freedom in the signal). Reduction of the sampling rate leads to lower power consumption and reduced electromagnetic interference. Also, compared to the conventional amplitude-based ADCs, TEMs can use relatively simple, entirely analog, small size encoders. On the other hand, reduction of the sampling rate unavoidably results in a smaller number of samples from which the input signal is to be reconstructed. The reconstruction technique of the present disclosure allows for robust reconstruction signal (even sampled under noisy conditions) from such relatively small number of samples.

An integrate and fire time encoding machine (IF-TEM) integrates an input signal and then compares the integral to a predetermined threshold; if the threshold is met, a difference between a pair of corresponding consecutive time instances matching this condition is recorded into a memory of the sampler to be further used for the input signal reconstruction. The IF-TEM sampler can be utilized for ultra-wide-band (UWB) communications, remote sensing, heart activity monitoring, event-based cameras (also referred to as neuromorphic cameras), and other applications such as spiking neural network (SNN) interpretations.

It should be noted that an input analog signal includes a train of pulses of a predetermined shape. Such predetermined shape may be or may not be fixed, e.g., the pulses may be variable-pulse-width type pulses.

Thus, the input signal (e.g., FRI signal) is typically in the form of a series/train of L pulses with a known/predetermined shape (either fixed pulse shape, or VPW shape) and can thus be represented by a sum of up to L such pulses. This sum of L pulses can be considered as a parametric signal, uniquely defined by a known/predetermined number of characteristic parameters (e.g., amplitude and time delay of pulses forming the signal), further referred to in this disclosure as “degrees of freedom” of the input signal to be sampled and reconstructed.

For example, the signal may be in the form of L amplitude-scaled and time delayed pulses of known/predetermined shape. Since the pulse shape is known, each pulse is uniquely specified by its amplitude and time delay, defining thus 2 degrees of freedom per pulse. Thus, the signal is uniquely specified by L amplitudes and L time delays, which amounts to 2 L degrees of freedom. In another example, e.g., considering an ECG signal in the form of L ECG pulses, the signal can be modeled as a sum of L pulses being variable-pulse-width (VPW) pulses, where each pulse has 4 degrees of freedom related to the symmetric and anti-symmetric parts of the pulse. Thus, such signal in the form of a series/train of L VPW pulses is uniquely specified by 4 L degrees of freedom.

The present disclosure describes a novel technique for the sampling and reconstruction of input analog signals of various types, such as FRI and VPW types, providing relatively low power consumption (via significant reduction of the sampling rate) even at noisy conditions. To this end, the sampling technique of the present disclosure utilizes a kernel and a TEM-based sampler, wherein the kernel is configured with a size of a sampling support set being in a predetermined relation with a number F of degrees of freedom in the input signal. For example, and in some embodiments preferably, the kernel is configured with a minimal transmission coefficient for zero frequency component of the input signal as compared to transmission coefficients for other frequency components to thereby substantially suppress transmission of the zero-frequency component of the input signal. This advantageously enables noise-resilient reconstruction of the input analog signal.

As for the reconstruction technique, it provides for determining the unknown degrees of freedom (e.g., amplitudes and time delays of the pulses) of the input signal, via determination of a set of Fourier series coefficients (FSCs) describing the input signal. This converts the problem of determining the degrees of freedom (e.g., time-delays and amplitudes) to that of finding the frequencies and amplitudes of a sum of sinusoids. The latter is a standard problem in spectral analysis which can be solved using conventional methods, such as the annihilating method approach.

The inventors have shown that by properly utilizing parameters of the kernel and the IF-TEM, the data indicative of the time-encodings can be used to determine therefrom vector representation y of the kernel-filtered signal and then determining, from said vector representation y of the kernel-filtered signal and then determining, data indicative of a vector representation, \hat{x}, of Fourier series coefficients of the signal. By this, the input analog signal, x(t) can be reconstructed. In general, the inventors have shown that the problem of determining the FSCs describing the input signal may be cast into a linear inverse problem.

For example, the inventors have shown (have given theoretical guarantees) that use of a properly selected matrix-based approach (i.e., based on the kernel and IF-TEM parameter(s) used in the sampling procedure) provides for high-certainty reconstruction of the analog signal from relatively small number of samples and eliminates a need for any simulation procedure.

When considering a set of equations in the form y=M\hat{x}, where y represents IF-TEM measurements, \hat{x} is the desired Fourier coefficients vector characterizing the analog signal x, and M is a characteristic matrix, there are various method to find a solution for \hat{x} if such solution is shown to exist, e.g., by employing techniques computing the pseudoinverse of matrix M or using the least-squares solution. Here, the pseudoinverse of matrix M signifies the Moore-Penrose inverse M⁺. Another approach may involve introducing regularization to the solution \hat{x} and utilizing optimization methods like ISTA (Iterative Shrinkage-Thresholding Algorithms), FISTA (Fast Iterative Shrinkage-Thresholding Algorithms), or other convex or non-convex solvers for the optimization problems.

It is important to note that the inventors demonstrated that the characteristic matrix M has full column-rank. Thus, given the measurements y and using left inverse representation of the matrix M, one can find a unique solution for \hat{x}.

In the description below, the above approach using pseudoinverse of characteristic matrix describing a relation between the IF-TEM measurements and the desired Fourier coefficients vector \hat{x}, is exemplified with the use of the characteristic matrix A and its left inverse representation A⁺ (i.e., A⁺A=1); and also exemplified with the use of the characteristic matrix B and its left inverse representation B⁺ (i.e., B⁺B=1), where matrix B differs from matrix A in that matrix B is free of or almost free of zero-frequency component in the kernel-filtered signal. Also, in the description below, such characteristic matrix is exemplified as matrix C being a Vandermonde type matrix having linearly independent columns and describing relation between the data indicative of vector representation y and vector representation of \hat{X}.

Thus, according to one broad aspect of the presently disclosed subject matter, it provides a signal processing system for processing an input analog signal, x(t), comprising a train of L pulses of a predetermined shape, the system comprising a sampling system comprising:
a kernel is characterized by predetermined size of a kernel support set, K, and is configured to receive the input analog signal and generate a kernel-filtered signal, y(t);
a sampler configured as an integrate and fire time encoding machine, IF-TEM, being parametrized by one or more predetermined characteristic parameters comprising one or more positive real numbers, said sampler being operable to receive the kernel-filtered signal and produce sampling data indicative of a series of N time-encodings, tₙ, of the kernel-filtered signal forming discrete time representation of said input analog signal;
wherein said size of the kernel support set is in a predetermined relation with a number F of degrees of freedom in the input signal defined by characteristic parameters of the input signal.

The IF-TEM comprises: an integrator and a discharge circuit, a comparator, and a switch positioned to receive a signal transmitted from the comparator for initiating reset of the integrator and for switching on the discharge circuit, wherein the discharge circuit comprises a capacitor configured to operate in its linear zone to provide rapid and complete discharge of the integrator. The switch may comprise at least three terminals, and be configured to receive a control signal for initiating reset of the integrator at a first terminal, and to switch on the discharge circuit by allowing a current flow between the second and third terminals. For example, the switch comprises a Field Effect Transistor (FET). The first terminal may form a gate of the FET.

The IF-TEM may further comprise a differentiator located on a path from the comparator to the switch. For example, the IF-TEM further comprises an amplifier located on a path from the differentiator and upstream of the switch.

The signal processing system may further include or may be connectable to a remotely located signal reconstruction system for reconstructing an analog FRI signal, x(t). The reconstruction system receives or has access to pre-stored data including required data/parameters of the kernel and IF-TEM used for sampling the analog signal and generation of the discrete time representation thereof. The kernel related data includes data indicative of the kernel support set, [symbol] and the IF-TEM related data includes IF-TEM parametrization data including one or more of the following positive real numbers: a bias b satisfying a condition c<b<∞ where c is a maximum real value of the input signal, a scaling factor κ, and a threshold δ.

The reconstruction system receives the discrete time representation which is indicative of series of N time-encodings, tₙ, of the kernel-filtered signal (i.e., the N time-encodings, tₙ, and/or differences between each two consecutive time-encodings), and utilizes the above data, as well as data indicative of the predetermined shape of the analog signal being reconstructed, and determines/creates a linear relationship between data indicative of vector representation, y, of the kernel-filtered FRI signal and data indicative of a vector representation, k, of Fourier series coefficients of the FRI signal, thereby enabling reconstruction of the input FRI signal, x(t).

In some embodiments, the reconstruction system creates a characteristic matrix having pseudoinverse representation thereof and describing the relation between data indicative of vector representation, y, of the kernel-filtered FRI signal and data indicative of a vector representation, k, of Fourier series coefficients of the FRI signal, thereby enabling reconstruction of the input FRI signal, x(t).

More specifically, the reconstruction system may operate as follows: analyze the data indicative of the time-encodings of the kernel-filtered signal and utilize the data indicative of the characteristic parameters of the IF-TEM to generate data indicative of vector representation, y, of the kernel-filtered signal; process the data indicative of the time encodings of the kernel-filtered signal utilizing said data indicative of the kernel support set and said data indicative of the one or more characteristic parameters of the IF-TEM and create the linear relation (e.g., said characteristic matrix); process said data indicative of the vector representation, y, of the kernel-filtered signal (e.g., by applying a pseudoinverse representation (e.g., left inverse) of said characteristic matrix to the vector representation, y, of the kernel-filtered signal) to obtain the vector representation, \hat{x}, of the Fourier series coefficients of the input signal; and processes the vector representation, \hat{x}, of the Fourier series coefficients and extract parameters of the L pulses forming the input FRI signal.

According to another broad aspect of the present disclosure, it provides the above-described signal reconstruction system being in data communication with a storage device to receive the above data and perform the above processing and analyzing of data indicative of the series of time-encodings.

The reconstruction system may include:
an analyzer configured and operable to analyze the data indicative of the time-encodings of the kernel-filtered signal and utilize the data indicative of the characteristic parameters of the IF-TEM to generate data indicative of the vector representation, y, of the kernel-filtered signal;
a processor configured and operable to utilize said data indicative of the time-encodings of the kernel-filtered signal and said data indicative of the kernel support set and define a linear relation between the data indicative of the vector representation, y, of the kernel-filtered signal and the vector representation, \hat{x}, of the Fourier series coefficients of the input signal; and a signal reconstructor processor configured and operable to utilize said linear relation to determine, from said data indicative of the vector representation, y, the vector representation, \hat{x}, of the Fourier series coefficients of the input signal, thereby enabling reconstruction of the analog signal x(t).

In some embodiments, said processor for determining the linear relation comprises a matrix creator utility configured and operable to process the data indicative of the time encodings of the kernel-filtered signal utilizing said data indicative of the kernel support set to create the characteristic matrix having pseudoinverse representation thereof. The signal reconstructor processor is configured and operable to utilize said characteristic matrix and apply the inverse representation of said characteristic matrix to said data indicative of the vector representation, y, of the kernel-filtered signal to thereby directly obtain the vector representation, \hat{x}, of the Fourier series coefficients of the input signal.

The reconstruction system also includes an extractor utility configured and operable to process the vector representation, \hat{x}, of the Fourier series coefficients and extract parameters of the L pulses forming the input FRI signal.

In some embodiments, the kernel support set, [symbol] , includes integers symmetric around zero: [symbol] ={−K, . . . , −1, 0, 1, . . . , K}.

In some other embodiments, the kernel is configured with a minimal transmission coefficient for zero frequency component of the input signal as compared to transmission coefficients for other frequency components to thereby substantially suppress transmission of the zero frequency component of the input signal, said kernel support set C includes integers symmetric around zero: [symbol] ={−K, . . . , −1,1, . . . , K}.

In yet further embodiments, the kernel is configured with a minimal transmission coefficient for zero frequency component of the input signal as compared to transmission coefficients for other frequency components to thereby substantially suppress transmission of the zero frequency component of the input signal, said kernel support set C includes integers symmetric around zero: [symbol] ={−K, . . . , −1,1, . . . , K}; the system being configured and operable to create the characteristic matrix being a Vandermonde type matrix having linearly independent columns, said matrix describing the relation between partial sums vector z of the said vector representation, y, of the kernel-filtered signal and a vector \hat{z} associated with said vector representation, \hat{x}, of the Fourier series coefficients of the signal.

For example, signal reconstruction system is configured and operable to carry out the following: utilize said vector representation, y, of the kernel-filtered signal to generate the partial sums vector z; utilize the partial sums vector z and said matrix to determine the vector \hat{z} being in a predetermined relation with the vector representation, \hat{x}, of the Fourier series coefficients of the signal; and determine the vector representation, \hat{x}, from said vector z by selecting predetermined elements of the vector \hat{z}.

Each successive component of the vector of partial sums, being a successive partial sum, is determined as a sum of a preceding partial sum and a linear transform, yₙ, of a respective difference between two consecutive time encodings tₙ₊₁ and tₙ defined as:

$${y}_{n} = - b ( {t}_{n + 1} - {t}_{n} ) + κδ .$$

The extractor utility may be configured and operable to apply spectral analysis to the vector representation, \hat{x}, of the Fourier series coefficients to thereby extract the parameters of the L pulses of the input signal.

The reconstruction system may be configured and operable to determine the parameters of the input signal with a reconstruction error not exceeding −25 dB, for the input signal being sampled by the sampling system at asynchronous sampling rates of at least 10 times lower than the Nyquist rate.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In order to better understand the subject matter that is disclosed herein and to exemplify how it may be carried out in practice, embodiments will now be described, by way of non-limiting examples only, with reference to the accompanying drawings:

FIG. 1 schematically illustrates a known in the art kernel-based sampling framework, where a signal x(t) is first filtered by a sampling kernel s(t) and then instantaneous uniform samples are measured at a sub-Nyquist rate;

FIG. 2A schematically illustrates a signal processing system according to some embodiments of the present disclosure;

FIG. 2B exemplifies an IF-TEM with a spike trigger reset where the IF-TEM is parametrized by one or more of the following positive real numbers: bias, b, scaling factor x, and reset-associated threshold δ;

FIG. 3A illustrates, by way of block diagram, the configuration and operation of a signal reconstruction system according to the present disclosure;

FIGS. 3B and 3C illustrate, by way of block diagrams, two specific not limiting examples of the configuration and operation of the signal reconstruction system of FIG. 3A;

FIG. 4 shows an example of IF-TEM hardware sampling including the IF-TEM input signal y(t) (blue), the integrator output (green), and the IF-TEM output time instances (red);

FIGS. 5A to 5F shows sampling and reconstruction of a stream of Dirac impulses using TEM by applying the SoS kernel, according to the present disclosure, wherein both [symbol] and [symbol] are chosen uniformly at random over (0,1); FIGS. 5A to 5C show the input signal and its reconstruction for L=3 (FIG. 5A), L=5, (FIG. 5B), and L=10 (FIG. 5C), respectively. FIGS. 5D to 5F show the filtered signal y(t) and the time instants tₙ for L=3 (FIG. 5D), L=5, (FIG. 5E), and L=10 (FIG. 5F), respectively;

FIGS. 6A and 6B show sampling and reconstruction of stream of pulses using TEM by applying the SoS kernel, according to the present disclosure, wherein FIG. 6A shows the input signal and its reconstruction for L=3, and FIG. 6B shows the filtered signal y(t) and the time instants tₙ for L=3;

FIGS. 7A and 7B show examples of ƒ(t) and r(t) when the matrix A has large condition number, according to the present disclosure, wherein in FIG. 7A condition numbers of A is 30 and of B is 3, and in FIG. 7B condition numbers of A is 3000 and of B is 5.

FIG. 8 shows the average condition number of matrices A and B as a function of L, according to the present disclosure;

FIG. 9 shows a performance comparison of Algorithm 1 and Algorithm 2 in the presence of continuous-time white Gaussian noise with zero mean and variance 0.001, according to the present disclosure;

FIG. 10 shows a comparison of Algorithm 1 and Algorithm 2 with noisy input signal;

FIGS. 11A to 11D show a comparison of with zero (Algorithm 1, FIG. 11A), without zero (Algorithm 2, FIG. 11B), and estimation of signal parameters via rotational invariance technique (ESPRIT, FIG. 11C) approaches for off-grid time delays with perturbation in the time encodings, and FIG. 11D shows one-dimensional MSE plots for K=2 L+1 and K=5 L;

FIG. 12 shows a comparison of resolutions of the with zero (Algorithm 1) and without zero (Algorithm 2) approaches when the difference between the time delays, τ₂-τ₁, is varied and the time encodings are perturbed with σ=0.008 (low noise) and σ=0.014 (high noise);

FIG. 13 shows a comparison of firing rates, FR-A and FR-B denoting mean firing rates of with zero and without zero approaches, respectively. Maximum and minimum rates are denoted by maxFR and minFR, respectively; the rate of innovation (Rol) is shown with dashed line;

FIG. 14 is an illustration of intersection of a trigonometric polynomial ƒ(t) and a straight line r(t);

FIGS. 15 to 17 schematically present examples of IF-TEMs according to the present disclosure;

FIG. 18; schematically illustrates an ADC according to the present disclosure;

FIGS. 19A and 19B present an example of a perfect reconstruction of an FRI signal from IF-TEM measurements using sampling kernel without zero and partial summation, wherein FIG. 19A shows the input signal and its reconstruction for L=5, and FIG. 19B shows the filtered signal y(t) and the time instants tₙ;

FIG. 20 presents, according to a present disclosure, an average condition number of matrices B and C as a function of the number of FRI pulses L.

FIGS. 21A and 21B present, according to a present disclosure, a comparison of approaches in Algorithm 2 and Algorithm 3 for off-grid time delays with perturbation in the time encodings;

FIG. 22 presents, according to a present disclosure, a 1 MHz filter Bode plot, the filter being configured to remove the zeroth frequency, wherein the magnitude (in blue) and phase (on red) are plotted on a logarithmic frequency scale;

FIG. 23 presents, according to a present disclosure, the FRI-TEM hardware prototype containing a signal generator, a sampling kernel and an IF-TEM sampler;

FIG. 24 presents, according to a present disclosure, a block diagram of the analog board;

FIG. 25 presents an IF-TEM hardware board;

FIG. 26 schematically shows an example of an integrator circuit wherein the hardware implementation includes an operational amplifier, a resistor R and a capacitor C;

FIGS. 27A and 27B present, according to a present disclosure, an input signal x(t) (green), BPF output y(t) (yellow), and the IF-TEM output resulting in 19 samples (blue) (FIG. 27A) and sampling and reconstruction using IF-TEM hardware: the input signal x(t) (blue) and its reconstruction (red) (FIG. 27B);

FIGS. 28A and 28B present, according to a present disclosure an input analog signal x(t) (green), BPF output y(t) (yellow), and the IF-TEM output resulting in 19 samples (blue) (FIG. 28A) and sampling and reconstruction using IF-TEM hardware: the input signal x(t) (blue) and its reconstruction (red) (FIG. 28B);

FIGS. 29A and 29B present, according to a present disclosure, an input analog signal x(t) (yellow), BPF output y(t) (green), and the IF-TEM output resulting in 21 samples (blue) (FIG. 29A) and sampling and reconstruction using IF-TEM hardware: the input signal x(t) (blue) and its reconstruction (red) (FIG. 29B).

FIGS. 30A and 30B present, according to a present disclosure, an input analog signal x(t) (green), BPF output y(t) (yellow), and the IF-TEM output resulting in 22 samples (blue) (FIG. 30A) and sampling and reconstruction using IF-TEM hardware: the input signal x(t) (blue) and its reconstruction (red) (FIG. 30B);

FIG. 31 presents, according to a present disclosure, a comparison between the reconstruction using the hardware measurements and the simulation;

FIG. 32 presents, according to a present disclosure, a schematic illustration of a sampling and reconstruction setup for sampling and reconstruction of continuous-time ECG signals;

FIG. 33 presents, according to a present disclosure, an example of reconstruction results of a single ECG pulse from [6];

FIGS. 34A and 34B present, according to a present disclosure, IF-TEM sampling and reconstruction example, wherein FIG. 34A shows the sampling mechanism of a filtered ECG pulse by IF-TEM; and FIG. 34B shows reconstructed R waves of the ECG signal;

FIGS. 35A to 35C present an example of HR monitoring performance for SNR=2 [dB] using various techniques: VPW-FRI from [4](FIG. 35A), IF-TEM from [5](FIG. 35B), and ECG-TEM (FIG. 35C) according to the present disclosure;

FIGS. 36A to 36D present evaluation of HRM performance of various reconstruction techniques vs. SNR using various statistical metrics: HR RMSE (FIG. 36A), HR MAE (FIG. 36B), HR PCC (FIG. 36C), and HR Success Rate (FIG. 36D).

### DETAILED DESCRIPTION OF THE ASPECTS AND EMBODIMENTS

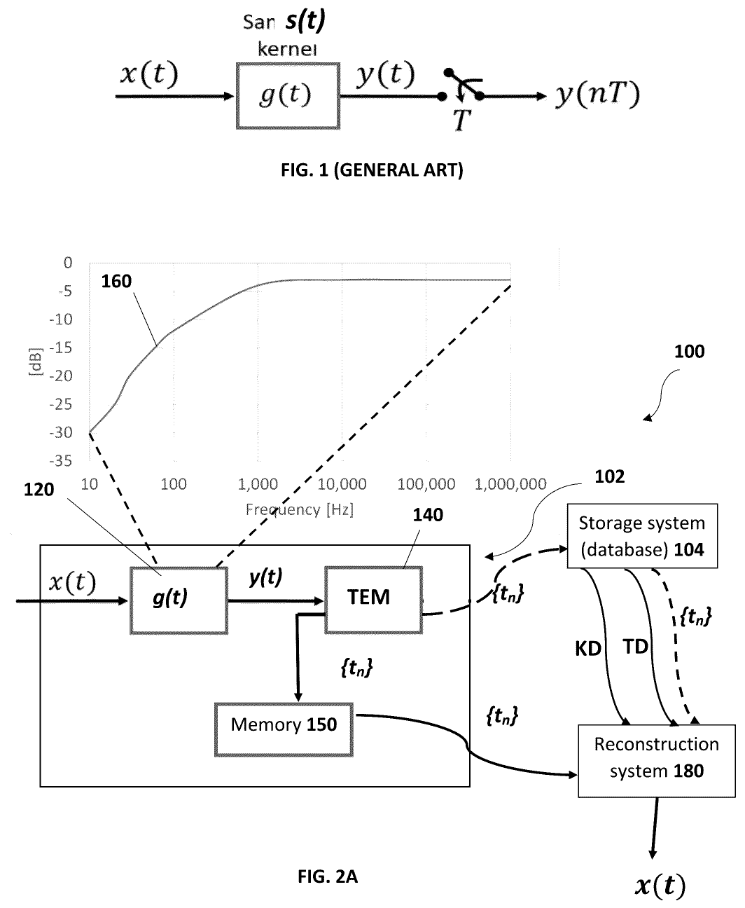

FIG. 1 illustrates the known in the art FRI sampling scheme in which the signal is first filtered by a sampling kernel to remove a redundancy, and then instantaneous samples are measured at a sub-Nyquist rate.

As described above, the technique of the present disclosure in one of its aspects provides a novel approach for sampling an input analog signal formed by a train of pulses of a predetermined shape. This approach is aimed at reducing the sampling rate (to the minimal rate enabling appropriate signal recovery) as well as reducing the power consumption. and also allowing robust signal reconstruction at noisy conditions during the sampling. In another aspect, the present disclosure provides a novel approach for the signal reconstructions technique, which enables robust reconstruction even for signals sampled under noisy conditions and provides high-quality (perfect) reconstruction while eliminating need for any simulation procedure.

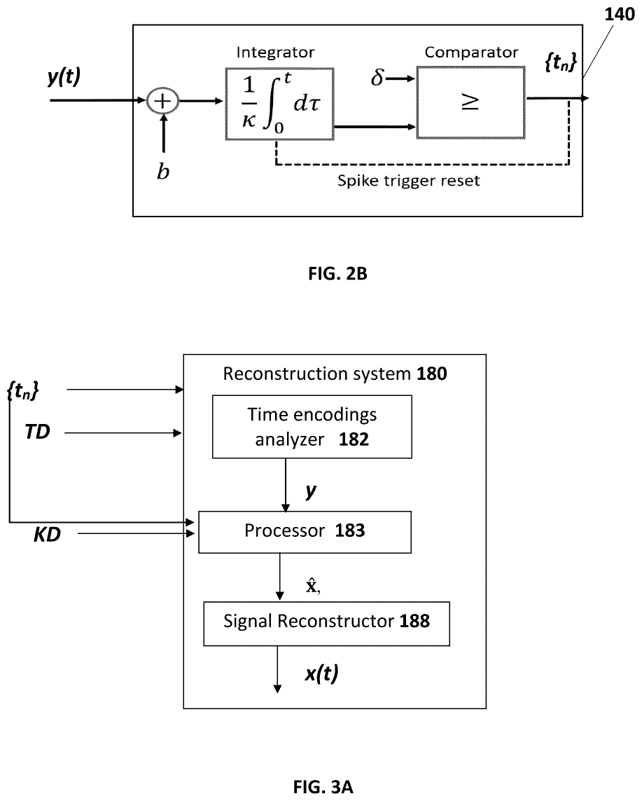

Reference is made to FIG. 2A schematically illustrating a signal processing system 100 of the present disclosure. The system 100 includes a sampling system 102 configured and operable for processing an input signal, x(t), being an analog signal (e.g., FRI signal or VPW signal) comprising a train of L pulses of a predetermined shape (e.g., fixed shape or variable shape).

As also shown in the figure, the sampling system 102 may be directly connected (via wires or wireless signal transmission using any known suitable communication technique and communication protocols) to a signal reconstruction system 180. Alternatively, or additionally, communication of the output of the sampling system to the reconstruction system may be via a remote storage device 104 which is connectable/accessible by the sampling system 102 and reconstruction system 180. Generally, the sampling and reconstruction systems 102 and 180 may be integral within a signal processing system 100.

The sampling system 102 receives an input analog signal x(t), applies the sampling procedure thereto and outputs data indicative of time-encodings data to of the sampled input signal (i.e., discrete time representation of the input signal). The data indicative of time-encodings data t_{z} (e.g., the time-encodings themselves or differences between each two consecutive time-encodings) is properly stored in a memory 150 of the system 102 and/or in the storage device 104, and this data is further processed by the reconstruction system 180 to restore the input signal.

The sampling system 102 includes a kernel (filter) 120 (represented by a function g(t)) characterized by a predetermined size of a kernel support set, [symbol] , and configured to receive the analog input signal x(t) and generate a kernel-filtered signal, y(t); and a sampler 140 configured as an integrate and fire time encoding machine, IF-TEM, which receives the kernel-filtered signal, y(t), and produces sampling data indicative of a series of time-encodings, {tₙ}, being discrete time representation of the analog signal x(t). The IF-TEM is parametrized by predetermined characteristic parameter(s) comprising one or more, e.g., at least three, positive real numbers. According to the present disclosure, the kernel is configured such that a size of the kernel support set is in a predetermined relation with a number F of degrees of freedom in the input signal.

The input analog signal is typically in the form of a series of L pulses with a known/predetermined shape and can thus be represented by a sum of up to L such pulses, presenting a parametric signal, uniquely defined by a known/predetermined number F of degrees of freedom which in turn is defined by characteristic parameters of the signal, e.g., amplitude and time delay of pulses; or amplitude and time parameters of symmetric and anti-symmetric parts of the pulses.

In some embodiments, the kernel 120 is further configured with a minimal transmission coefficient for zero frequency component of an input signal as compared to transmission coefficients for other frequency components to thereby substantially suppress transmission of the zero-frequency component of the input signal. This feature of zero suppression enables noise-resilient reconstruction of the input analog signal. This is also specifically shown in FIG. 2A exemplifying kernel function 160 being a band pass filter (BPF) function configured to suppress the zero-frequency component of the input signal.

As will be described further below, the reconstruction system 180 receives the data indicative of the time-encodings data tₙ, as well as kernel-related data KD and IF-TEM related data TD, and properly processes and analyses the time-encoded data utilizing the kernel- and TEM-related data to reconstruct the input signal x(t).

FIG. 2B shows an embodiment of the present disclosure where the IF-TEM 140 is employing an alternative sampling mechanism which does not require a global clock. Here, the samples are irregularly spaced threshold-based samples. In sampling with a TEM, an analog signal is represented by a set of time instants at which a specific phenomenon is observed; for example, the filtered input signal, or its function crosses a certain threshold. In the embodiment of FIG. 2B the TEM is parametrized by one or more or in some embodiments at least three positive real numbers comprising: a bias b satisfying a condition c<b<∞ where c is a maximum real value of the input signal, a scaling factor κ, and a threshold δ. In particular, in the IF-TEM embodiment described in the disclosure, the signal input into the IF-TEM is biased with b to make it positive.

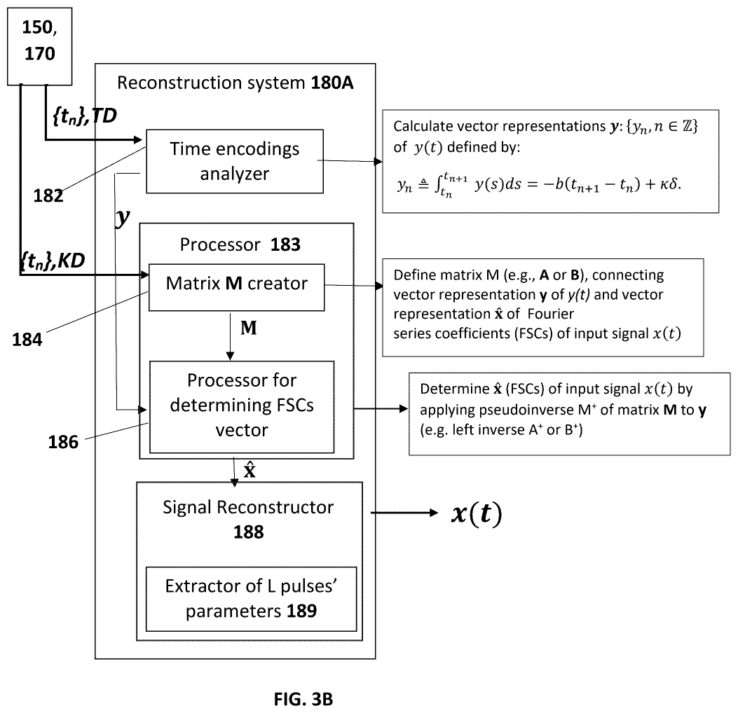

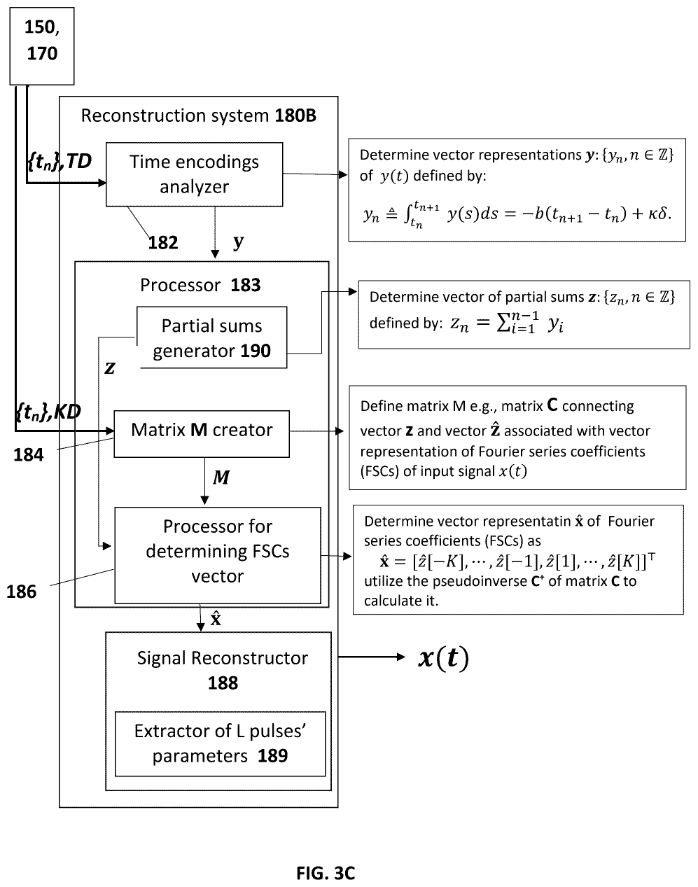

Reference is made to FIG. 3A showing a block diagram of the configuration and operation of the signal reconstruction system 180 according to the present disclosure. The system 180 includes an analyzer 182, processor 183 and signal reconstructor processor 188. The analyzer 182 is configured as a time-encoding analyzer, which analyzes the data indicative of the time-encodings {tₙ}(i.e., the time-encodings themselves and/or differences between two consecutive time-encodings) to generate data indicative of the vector representation, y, of the kernel-filtered signal of the kernel-filtered signal. This analyses utilize the data indicative of the characteristic parameters of the IF-TEM, TD, as will be described further below. The processor 183 is configured and operable to utilize the data indicative of the time-encodings {tₙ} and also the data indicative of the kernel support set, KD, and define a linear relation between the data indicative of the vector representation, y, of the kernel-filtered signal and vector representation, \hat{x}, of the Fourier series coefficients of the input signal x(t). The signal reconstructor 188 is configured and operable to utilize the linear relation to determine the vector representation, \hat{x}, of the Fourier series coefficients of the input signal from said data indicative of the vector representation, y, and by this reconstruct the analog signal x(t).

FIGS. 3A and 3B illustrate two examples of the configuration and operation of the above-described signal reconstruction system. The systems of FIGS. 3A and 3B are denoted 180A and 180B, respectively. To facilitate understanding, the same reference numbers are used to identify functionally similar components of the systems shown in all the examples.

Each of the reconstruction system 180A, 180B is configured to receive data indicative of the time-encodings tₙ of the kernel-filtered signal y(t) and process this data by utilizing the kernel-related data (i.e., data indicative of the kernel support set, [symbol] ,) and [symbol] data indicative of the characteristic parameter(s) of the IF-TEM (e.g., one or more of or three positive real numbers), to create the linear relation between y and \hat{x}, and by this reconstruct the analog signal x(t). In these specific examples, the linear relation is in the form of a characteristic matrix M having pseudoinverse representation thereof and describing a relation between the data indicative of vector representation, y, of the kernel-filtered signal y(t) and data indicative of the vector representation, \hat{x}, of Fourier series coefficients (FSCs) of the analog signal x(t). This enables reconstruction of the input analog signal, x(t), e.g. using spectral analysis.

As shown in FIG. 3B, the reconstruction system 180A includes analyzer 182; processor 183 including a matrix creator utility 184 and FCSs vector determinator 186; and signal reconstructor 188 including a pulse parameters' extractor utility 189. The analyzer 182 is configured and operable as described above to analyze the data indicative of the time-encodings tₙ of the kernel-filtered signal y(t) and utilize data indicative of the characteristic parameter(s) of the IF-TEM, TD, to generate data indicative of vector representation, y, of the kernel-filtered FRI signal. The matrix creator utility 184 is configured and operable to process the data indicative of the time encodings data tₙ of the kernel-filtered signal utilizing the data indicative of the kernel support set [symbol] , KD, to create the characteristic matrix M, e.g. matrix A or B having left-inverse matrices A^{†} or B^{†} as will be described further below. The processor 186 is configured and operable to utilize the so-created characteristic matrix to process the data indicative of the vector representation, y, of the kernel-filtered FRI signal by applying to this vector y pseudoinverse representation (e.g., left-inverse) of the characteristic matrix, A^{†} or B^{†} to obtain the vector representation, \hat{x}, of the FSCs of the input signal. The extractor utility 189 is configured and operable to process the vector representation, \hat{x}, of the Fourier series coefficients and extract parameters of the L pulses forming the input signal x(t).

More specifically, as shown in FIG. 3B, the reconstruction system 180A receives the sampling data comprising the series of time-encodings, {tₙ}, of the kernel-filtered signal y(t) being discrete time representation of the analog signal x(t). The time encoding analyzer 182 calculates the vector representation y of the kernel-filtered signal {yₙ, n∈ [symbol] } defined by

$${y}_{n} {=}^{△} {\int }_{{t}_{n}}^{{t}_{n + 1}} y ( s ) ds = - b ( {t}_{n + 1} - {t}_{n} ) + κδ .$$

Here, tₙ and tₙ₊₁ are respectively n-th and (n+1)-th time encodings, and b, κ and δ are characteristic parameters of the IF-TEM corresponding to, respectively, bias b (c<b<∞, where c is a maximum real value of the input signal), scaling factor κ, and threshold δ.

It should be noted that although in the description presented here the characteristic parameters of the IF-TEM are represented by three positive real numbers including bias b (c<b<∞, where c is a maximum real value of the input signal), scaling factor κ, and threshold δ, the principles of the technique of the present disclosure is not limited to this specific example. For example, if the signal being reconstructed is a positive signal, there is no need to use a bias b parameter for reconstruction.

It can be shown that each yₙ represents an average value of y(t) (in the following referred to as y(t) for clarity of presentation) in the interval between two consecutive times tₙ and tₙ₊₁. The matrix creator 184 utilizes the knowledge about the frequencies transmitted by the chosen sampling kernel (i.e., the kernel support set data contained in KD) to analyze the received data indicative of the time encodings and define a characteristic matrix M having inverse representation thereof M⁺ (e.g., matrix A having left-inverse representation), connecting/describing a relation between data indicative of the vector representation, y, of the kernel-filtered signal y(t) and data indicative of vector representation, \hat{x}, of FSCs of the analog signal. This matrix depends on the specific kernel and kernel support set as will be described in detail further below.

The processor 186 defines the FSCs vector as \hat{x} and utilizes the known properties of the sampling kernel allowing to write the relation between the IF-TEM measurements and the FSCs in a matrix form, e.g., y=A\hat{x}, and operates to determine the vector representation, \hat{x}, of the FSCs by applying the inverse representation (e.g., left-inverse) of the matrix, e.g., A^{†}, to the vector representation, y, of the kernel-filtered signal. Finally, the extractor utility 189 extracts the unknown parameters (e.g., L amplitudes and L delays) of the input signal from the vector representation, \hat{x}, of FSCs, thereby recovering the analog signal x(t). It is noted that several known techniques may be used for recovering the signal from its FSCs, spectral analysis method being one non-limiting example.

The reconstruction system 180B exemplified in FIG. 3C is configured generally similar to the above-described reconstruction system 180A, namely includes analyzer 182, matrix creator utility 184; processor 186; and signal reconstructor 188 including a pulse parameters' extractor utility 189. In the system 180B, the processor 183 also includes a partial sum generator 190.

The reconstruction system 180B receives the sampling data comprising the data indicative of the series of time-encodings, {tₙ}, of the kernel-filtered signal y(t) being discrete time representation of the analog signal x(t). The time encoding analyzer 182 analyzes the data indicative of the time-encodings tₙ of the kernel-filtered signal y(t), and utilizes data indicative of the characteristic parameter(s) of the IF-TEM, TD, to generate data indicative of the vector representation y of the kernel-filtered FRI signal {yₙ, n∈ [symbol] } defined by

$${y}_{n} {=}^{△} {\int }_{{t}_{n}}^{{t}_{n + 1}} y ( s ) ds = - b ( {t}_{n + 1} - {t}_{n} ) + κδ .$$

As noted above, each yₙ represents an average value of y(t) in the interval between two consecutive times tₙ and tₙ₊₁.

This vector representation y is processed by the partial sum generator 190 to determine a vector of partial sums z: {zₙ, n∈ [symbol] } defined by:

$${z}_{n} = {\sum }_{i = 1}^{n - 1} {y}_{i} .$$

The matrix creator 184 utilizes the knowledge about the frequencies transmitted by the chosen sampling kernel (i.e., the kernel support set, KD,) to analyze the received data indicative of the time encodings tₙ of the kernel-filtered signal and create the characteristic matrix M configured as described above. In this example, such matrix is denoted C and is configured as a Vandermonde type matrix having linearly independent columns, as will be described further below. This invertible matrix C describes the relation between partial sums vector z (constituting data indicative of vector representation y of the kernel-filtered signal) and a vector \hat{z} (constituting data indicative of vector representation, \hat{x}, of FSCs of the input signal x(t)), i.e., \hat{z}=C^{†}z.

The processor 186 operates to utilize the matrix inverse Ct to determine the vector \hat{z} and then determine the vector representation \hat{x} of FSCs as

$$\hat{x} = {[ \hat{z} [ - K ] , … , \hat{z} [ - 1 ] , \hat{z} [ 1 ] , … , \hat{z} [ K ] ]}^{T} ∈ {ℂ}^{2 K} .$$

The extractor utility 189 extracts the unknown parameters (e.g., L amplitudes and L delays) of the input signal from the vector representation, \hat{x}, of FSCs, thereby recovering the analog signal x(t). As noted above, several suitable known techniques may be used for recovering the analog signal from its FSCs, spectral analysis method being one non-limiting example.

FIG. 4 illustrates IF-TEM sampling using the system 102 of the present disclosure: the IF-TEM input signal y(t) generated by the kernel 120 (i.e., acted on by the kernel function g(t)) is denoted 140A and is drawn in blue, the integrator output denoted 140B is drawn in green, and the IF-TEM output time instances, {tₙ}, calculated from recorded differences between consecutive events (time-encodings) when the threshold is met, are denoted 140C and are pointed with red. The number of time instants (time-encodings) per unit time, N/T, also called a firing rate (T being a predetermined time characteristic of the input signals, as described below), is proportional to the local frequency content of such an IF-TEM input signal. For example, there are more firings in a time interval where the signal amplitude (after biasing) varies rapidly compared to time intervals with relatively slow variations.

To this end, the kernel 120 has a size of the kernel support set in a predetermined relation with the number F of degrees of freedom in the input signal defined by characteristic parameters of the input signal, and preferably has a minimal transmission coefficient for zero frequency component of the input signal as compared to transmission coefficients for other frequency components to thereby substantially suppress transmission of the zero frequency component while allowing passage of a number K of non-zero frequency components in the input signal. The number K is defined to allow determination of a minimum number of Fourier-series coefficients (FSC) of the input signal allowing a unique reconstruction of the input signal.

The size of the kernel support and transmission coefficient frequency dependence of the kernel 120 are arranged to provide an alias cancellation for the input signal. Examples of such kernels may be found in [2] and they can also be called annihilating kernels.

In general, the kernel 120 may comprise any one of the following: a sinc function kernel, a sum-of-sincs (SoS) kernel, a sum-of-modulated spline kernel, a polynomial-reproducing kernel, or an exponential-reproducing kernel. The exponential reproducing kernel may be of maximum-order and minimum support or satisfying at least one generalized Strang-Fix condition.

A crucial component of a sampling architecture is the sampling kernel. Generally, sampling kernels with compact support are preferable from a hardware implementation perspective. In some embodiments of the present disclosure, the kernel has a support set [symbol] of indices chosen to exclude zero and include integers symmetric around zero:

$$𝒦 = \{ - K , … , - 1 , 1 , … , K \} .$$

In some embodiments, the kernel is configured with the support set [symbol] of indices satisfying a condition that | [symbol] |≥2 L, where 2 L is a number of degrees of freedom in the input signal having L pulses of a predetermined shape defining L amplitudes and L time delays characterizing the input signal.

The input signal has a predetermined time characteristic T which may describe the period of a periodic input signal, the predetermined shape of the input signal defining the rate of innovation to be 2 L/T.

A periodic signal is assumed during the detailed description of the methods of the present disclosure, however, the same methods described in the disclosure, may be applied to nonperiodic signals which may be defined as a finite train of pulses having time delays restricted to lie in a finite time interval [0, T) and the nonperiodic signal having a finite support. It will be shown further below that all theorems regarding sampling and reconstruction of T-periodic signals are equally applicable to the nonperiodic case as well.

In the non-limiting example of L pulses of a predetermined shape defining L amplitudes and L time delays characterizing the input signal, the TEM 140 may be configured to sample a minimum number N, N≥2K+2, of the time-encodings {tₙ} within a period T of the input signal, wherein K satisfies a condition that K≥2 L, to thereby enable reconstruction of the L amplitudes and the L time delays of the L pulses.

The three positive real numbers parametrizing the TEM, {b, κ, δ}, are chosen such that

$$\frac{b - c}{κδ} \geq \frac{2 K + 2}{T} ,$$

where

$$\frac{2 K + 2}{T}$$

is a minimal required sampling rate of the TEM for a robust recovery of the input signal in presence of noise. This minimal required sampling rate of the TEM being more than twice the rate of innovation, 2 L/T.

As mentioned above, the reconstruction system 180 is configured to receive and process the series of time-encodings, {tₙ}, to reconstruct the input signal. The inventors show that with a proper choice of the sampling kernel, e.g., a sum-of-sincs kernel, the FSCs of the input signal can be uniquely identified from the IF-TEM sampling data comprising the time encodings {tₙ}. It should be noted that filter 120 may be understood as spreading the information of the FRI signal (since the purpose of the sampling kernel is to distribute the FRI signal information in such a way that the parameter-estimation block, i.e., the reconstruction system 180 would be enabled to estimate the time delays and amplitudes using a finite number of low-rate samples).

The authors in [1] aimed at investigating a supposition that by using sampling kernels that have a frequency-domain alias cancellation properties, FRI signals with 2 L degrees of freedom can be recovered from (2 L+2) IF-TEM firing instants. The influence of noise was not addressed. Also, perfect recovery is not established: rather, the reconstruction algorithm is based on an assumption that certain invertibility conditions for a matrix used for reconstruction are guaranteed; and in simulations the invertibility conditions were satisfied for a large number of experiments.

The inventors of the present disclosure have considered sampling analog signals using an IF-TEM, and more generally, TEM. They have found theoretical guarantees for the recovery (so-called perfect recovery, i.e., recovery in the absence of noise) of an input analog signal formed by a train of pulses of the predetermined shape, i.e., the lowest possible sampling rate, for the cases where the signal time delays are either on or off grid. That is, the inventors have designed a new sampling technique that can be used to ensure recovery in the noise-free setting, but that is also more robust in the presence of noise than some known techniques: it results in a lower error in the presence of noise for the same number of measurements. This allows for more easily producing, with lower costs, of more energy-efficient ADCs for signals.

Specifically, the reconstruction system 180 is further configured to perform consecutive partial summations of discrete representations of the input signal derived from the series of time-encodings and predetermined positive real number(s) parametrizing the IF-TEM comprising: a bias b satisfying a condition c<b<∞ where c is a maximum real value of the input signal and/or a scaling factor κ, and/or a threshold δ; and obtaining a vector of partial sums, to thereby provide noise-resilient reconstruction of the input signal.

Each successive component of the vector of partial sums, being a successive partial sum, is determined as a sum of a preceding partial sum and a linear transform, yₙ, of a respective difference between two consecutive time encodings tₙ₊₁ and tₙ defined as: yₙ=−b(tₙ₊₁−tₙ)+κδ.

As already noted above, the present disclosure provides methods for robust reconstruction of analog signals also in the presence of noise. Excluding the zero frequency from the sampling kernel was found by the inventors to enable robust recovery of signal in the presence of perturbations in the time encodings. However, the reconstruction method mentioned above requires the condition that K≥2 L resulting in an increased firing rate.

An alternative approach to reduce the firing rate is to assume that the time delays are arranged in accordance with a predetermined time grid. In this case the requirement on the kernel reduces to K≥L and further below the inventors provide the details of reconstructing the analog signal from the L values of FSCs. Thus, the kernel may be configured with the support set [symbol] of indices satisfying a condition that | [symbol] |≥L. In this case, the three positive real numbers parametrizing the IF-TEM, {b, K, (}, are chosen such that

$$\frac{b - c}{κδ} \geq \frac{2 K + 2}{T}$$

where

$$\frac{2 K + 2}{T}$$

is the minimal required sampling rate of the TEM for a robust recovery of the input signal in presence of noise, the minimal required sampling rate of the TEM being higher than once and lower than twice the rate of innovation.

In another embodiment of the present disclosure, the kernel 120 is configured with a support set [symbol] of indices satisfying a condition that | [symbol] |4 L+1, where 4 L is the number of degrees of freedom in the input signal having L ECG pulses, the pulses being variable-pulse-width (VPW) ECG pulses of a predetermined shape.

The ECG signal is an example of a nonperiodic signal in the form of a finite train of pulses having time delays restricted to lie in a finite time interval and the nonperiodic signal having a finite support, the finite time interval being [0, T). Thus, the rate of innovation of an ECG signal is defined as 4 L/T in the present disclosure.

Thus, the IF-TEM 140 of FIG. 3A is configured to sample a minimum number N, N≥8 L+2, of the time-encodings within a time interval T of the input signal, to thereby enable to reconstruct 4 L parameters of the L VPW ECG pulses. Specifically, the three positive real numbers parametrizing the TEM, {b, κ, δ}, are chosen such that

$$\frac{b - c}{κ δ} \geq \frac{8 L + 2}{T}$$

where

$$\frac{8 L + 2}{T}$$

is the minimal required sampling rate of the TEM for a robust recovery of the ECG signal.

Further, the inventors have built and tested hardware prototypes of respective samplers and ADCs.

Furthermore, the inventors have found a reconstruction technique which is more robust with respect to the hardware noise.

The usability of the specific variations of the sampling system 100 is supported by the theoretical guarantees, as developed by the inventors of the present disclosure, for perfect reconstruction of analog signals with arbitrary, but known pulse shapes. Also, the inventors have designed a sampling kernel and IF-TEM sampler with improved noise robustness. Specifically, since analog signals with F degrees of freedom can be perfectly reconstructed from F consecutive Fourier series coefficients (FSCs), the inventors have chosen sampling kernels with the alias-cancellation condition to annihilate the undesirable FSCs. The filtered signal, with fewer FSCs, is applied to an IF-TEM, and firing instants are measured. The inventors have found and shown that F+2 firing instants are sufficient to uniquely determine F FSCs from which the original signals can be recovered. Furthermore, the inventors have established conditions on the IF-TEM parameters that ensure that the minimum firing rate is achieved.

However, the inventors have then advanced much further. While the above sampling approach leads to perfect reconstruction of the signal in the absence of noise, the reconstruction can be highly sensitive to noise as the inventors have found via simulations. To address this issue, the inventors have designed a further modified sampling and reconstruction mechanism. In particular, the inventors have found that the zeroth Fourier coefficient of the filtered signal results in an unstable inverse matrix while computing the FSCs from the time instants in the presence of noise. To improve noise robustness, the inventors have modified the sampling kernel by removing the zero-frequency component. For this modified method, the inventors have found that 2F+2 time instants are sufficient for perfect recovery when the time-delays of the signal are off-grid, whereas F+2 firings are sufficient when the delays are on grid.

Through simulations, the inventors have shown that for the same number of firing rates (beyond F+2 firings), the mean squared error in the estimation of the on-grid time delays in the proposed approach is 2-6 dB lower compared to the one in [1]. In the case of off-grid time delays, the inventors have considered perturbations in the time encoding. The inventors have shown that their approach may bring more than 3-10 dB gain in terms of error compared to the method in [1] for the same number of measurements. In addition, the inventors have shown that their approach has better resolution ability in the presence of noise. Specifically, when the signal pulses are close to each other, their method is able to distinguish them.

In the following, the above embodiments, examples and developments are further explained, based on some specific examples presenting at times further suitable, but optional features, as well as their combinations and sub-combinations, which all have to be considered as disclosed:

The inventors have considered, as an example, an IF-TEM with the refractory period approximated as zero as shown in FIG. 2B. The input to the IF-TEM is a bounded signal y(t), and the output is a series of firing or time instants. An IF-TEM is parametrized by positive real numbers b, κ, and δ and works as follows: A bias b is added to a c-bounded signal y(t) where |y(t)|≤c<b<∞, and the sum is integrated and scaled by κ. When the resulting signal reaches the threshold δ, the time difference with such previous event is recorded in a memory (a hardware component) of the sampler or the ADC, and hence instant tₙ is calculated, and the integrator is reset. The process is repeated for subsequent time instants, i.e., if a time instant tₙ was obtained, the next time instant tₙ₊₁ satisfies:

$$\frac{1}{κ} {\int }_{{t}_{n}}^{{t}_{n + 1}} ( y ( s ) + b ) ds = δ . \qquad ( 1 )$$

The time encodings {tₙ, n∈ [symbol] } form a discrete representation yₙ of the analog kernel-filtered signal y(t) and the objective is to reconstruct y(t) from them and then reconstruct the analog input signal x(t) from its kernel-filtered analog signal y(t). Typically, reconstruction is performed by using an alternative set of discrete representations {yₙ, n∈ [symbol] } defined as

$${y}_{n} {=}^{△} {\int }_{{t}_{n}}^{{t}_{n + 1}} y ( s ) ds = - b ( {t}_{n + 1} - {t}_{n} ) + κδ . \qquad ( 2 )$$

The measurements {yₙ, n∈ [symbol] } are derived from the time encodings {tₙ, n∈ [symbol] } and IF-TEM parameters {b, κ, δ}.

Although reconstruction methods vary for different classes of signals, for perfect recovery of any signal, the firing rate is required to satisfy a lower bound that depends on the degrees of freedom of the signal. The firing rate of an IF-TEM is bounded both from above and below, where the bounds are a function of the IF-TEM parameters and an upper-bound on the signal amplitude. Using Eq. (2) and the fact that |y(t)|≤c, it can be shown that for any two consecutive time instants:

$$\frac{κ δ}{b + c} \leq {t}_{n + 1} - {t}_{n} \leq \frac{κ δ}{b - c} . \qquad ( 3 )$$

The inequalities in Eq. (3) imply that in any arbitrary, non-zero, observation interval T_{obs}, the maximum and minimum number of firings are

$${T}_{obs} \frac{b + c}{κ δ} and {T}_{obs} \frac{b - c}{κ δ} , \qquad ( 4 )$$

respectively. Thus, the firing rate of an IF-TEM F_{R} with parameters b, κ, and δ is upper and lower bounded as

$$\frac{b - c}{κ δ} \leq {F}_{R} \leq \frac{b + c}{κ δ} . \qquad ( 5 )$$

As an example, to demonstrate the techniques of the disclosure, the inventors recover a continuous-time FRI signal x(t) of the form of (Eq. (6) below, from the time instances {tₙ}.

It will be assumed in the following that the input signal is T-periodic, for simplicity of presentation only. However, the techniques of the disclosure are applicable to non-periodic FRI signals as well, as will be described further below. Thus, the inventors demonstrate their method with a T-periodic FRI signal of the form:

$$x ( t ) = {\sum }_{p ∈ ℤ} {\sum }_{ℓ = 1}^{L} {a}_{ℓ} h ( t - {τ}_{ℓ} - pT ) , \qquad ( 6 )$$

where h(t) is a known, real-valued pulse and the amplitudes and delays {( [symbol] )| [symbol] ∈[0, T),

$${{a}_{ℓ} ∈ ( 0 , {a}_{max} ] \}}_{ℓ = 1}^{L}$$

are unknown parameters. This signal model is used in applications such as radar, ultrasound, and more. In these applications, h(t) denotes a known transmit pulse which is reflected from L targets. The reflected signal is modeled as x(t) where [symbol] and [symbol] denote the amplitude and time-delay corresponding to the [symbol] -th target. It is noted that the signal form of Eq. (6) is a non-limiting example described here to exemplify the principles of the sampling and reconstruction techniques of the disclosure. Other signal forms will be considered further below.

In general, FRI signals have wide bandwidth due to short duration pulses h(t). However, by using the structure of the signal, FRI signals can be sampled at sub-Nyquist rates and with the knowledge of the pulse h(t) they can be reconstructed. The sampling is typically achieved by passing x(t) through a designed sampling kernel, e.g., s(t) and then measuring low-rate samples y(nT) of the filtered signal y(t) as shown in FIG. 1. The kernel is designed such that the FRI parameters

$${\{ {a}_{ℓ} , {τ}_{ℓ} \}}_{ℓ = 1}^{L}$$

are computed accurately from the samples. In particular, it was shown that 2 L samples of y(t) in an interval of length T, that are measured either uniformly or non-uniformly, are sufficient to determine

$${\{ {a}_{ℓ} , {τ}_{ℓ} \}}_{ℓ = 1}^{L}$$

uniquely. The reconstruction or determination of the parameters from the samples is achieved by applying spectral analysis methods such as the annihilating filter (in other words, alias-cancellation filter).

As discussed above, a conventional FRI sampling scheme, such as in FIG. 1, has a sampler which is controlled by a global clock that operates at the rate of innovation

$$\frac{2 L}{T}$$

Hz. For a large L or a small T, the sampling rate increases, and the global clock requires high power. In this case, according to the present disclosure, an IF-TEM sampler is well suited as it does not require a global clock.

The inventors have considered the problem of perfect recovery of the FRI parameters

$${\{ {a}_{ℓ} , {τ}_{ℓ} \}}_{ℓ = 1}^{L}$$

using an IF-TEM sampling scheme as, for example shown in FIG. 2A. Specifically, they have considered designing the sampling kernel g(t) and an IF-TEM such that the FRI parameters are uniquely determined from the time-encodings by keeping the firing rate close to the rate of innovation.

In the following it is shown that, according to the present disclosure, in the noiseless case, perfect recovery is guaranteed using as few as 2 L+2 firings in an interval of length T. Further below, an alternative approach that is more robust to noise is presented.

The inventors have used the fact that the FRI signal x(t) in Eq. (6) can be perfectly reconstructed from its 2 L FSCs. The inventors have derived conditions on the IF-TEM parameters and the sampling kernel g(t) such that 2 L FSCs of the input FRI signal can be uniquely recovered from the IF-TEM output.

The inventors have begun by explicitly relating the input signal x(t) of Eq. (6) to its FSCs (cf. Eq. (10)) following [2].

Since x(t) is a T-periodic signal it has a Fourier series representation

$$x ( t ) = {\sum }_{k ∈ ℤ} \hat{x} [ k ] {e}^{jk {ω}_{0} t} , \qquad ( 7 )$$

where

$${ω}_{0} = \frac{2 π}{T} .$$

The Fourier-series coefficients \hat{x}[k] are given by

$$\hat{x} [ k ] = \frac{1}{T} \hat{h} ( k {ω}_{0} ) {\sum }_{ℓ = 1}^{L} {a}_{ℓ} {e}^{- jk {ω}_{0} {τ}_{ℓ}} , \qquad ( 8 )$$

where, ĥ(ω) is the continuous-time Fourier transform of h(t) and the inventors have assumed that ĥ(kω₀)≠0 for k∈ [symbol] where [symbol] is a given set of indices. Since x(t) is real-valued, its FSCs \hat{x}[k] are complex conjugate pairs, that is,

$${\hat{x}}^{*} [ - k ] = \hat{x} [ k ] . \qquad ( 9 )$$

The sequence

$$\frac{\hat{x} [ k ]}{\hat{h} ( k {ω}_{0} )} = \frac{1}{T} {\sum }_{ℓ = 1}^{L} {a}_{ℓ} {e}^{- jk {ω}_{0} {τ}_{ℓ}} , \qquad ( 10 )$$

consists of a sum of L complex exponentials. From the theory of high-resolution spectral estimation, it is well known that 2 L consecutive samples of

$$\frac{\hat{x} [ k ]}{\hat{h} ( k {ω}_{0} )}$$

are sufficient to determine

$${\{ {a}_{ℓ} , {τ}_{ℓ} \}}_{ℓ = 1}^{L} .$$

For example, one can apply a well-known annihilating filter method to compute

$${\{ {a}_{ℓ} , {τ}_{ℓ} \}}_{ℓ = 1}^{L} .$$

In practice, the pulse h(t) has short-duration and wide bandwidth. Hence, there always exist 2 L or more non-vanishing Fourier samples ĥ(kω₀) that are computed a priori. To determine the FRI parameters, it is needed to compute 2 L consecutive values of \hat{x}[k]. The problem is then reduced to that of uniquely determining the desired number of FSCs from the signal measurements. Since x(t) typically consists of a large number of FSCs, a sampling kernel design which removes unnecessary FSCs and thus reduces the sampling rate is discussed in the following.

Since a minimum of 2 L FSCs are sufficient for uniquely recovering the FRI signal, the sampling kernel g(t) is designed to remove or annihilate any additional FSCs. The filtered signal y(t) is given by

$$\begin{matrix}y ( t ) = ( x * g ) ( t ) = {\int }_{- ∞}^{∞} x ( τ ) g ( t - τ ) d τ \\ = {\sum }_{k ∈ ℤ} \hat{x} [ k ] {\int }_{- ∞}^{∞} g ( t - τ ) {e}^{jk {ω}_{0} τ} d τ \\ = {\sum }_{k ∈ ℤ} \hat{x} [ k ] \hat{g} ( k {ω}_{o} ) {e}^{jk {ω}_{0} t} .\end{matrix} \qquad ( 11 )$$

To restrict the summation to a finite number of terms and annihilate the unwanted FSCs the inventors have defined the filter to satisfy the following condition in the Fourier domain:

$$\hat{g} ( k {ω}_{0} ) = \{ \begin{matrix}1 & if k ∈ 𝒦 , \\ 0 & otherwise ,\end{matrix} \qquad ( 12 )$$

where [symbol] is a set of integers such that ∥ [symbol] |≥2 L.

One particular choice of the sampling kernel, in this example, is a sum-of-sincs (SoS) kernel [2] generated by

$$\hat{g} ( ω ) = {\sum }_{k ∈ 𝒦} sin c ( \frac{ω}{{ω}_{0}} - k ) , \qquad ( 13 )$$

$$and$$

$$g ( t ) = \{ \begin{matrix}{\sum }_{k ∈ 𝒦} {e}^{jk {ω}_{0} t} , & t ∈ ( - \frac{T}{2} , \frac{T}{2} ] \\ 0 & elsewhere ,\end{matrix} \qquad ( 14 )$$

The sampling kernel g(t) is designed to pass the coefficients \hat{x}[k], k∈ [symbol] while suppressing all other coefficients \hat{x}[k], k∉ [symbol] . Note that one can also apply a lowpass filter (e.g., substantially or approximately ideal) with an appropriate cutoff frequency to remove the FSCs. However, the impulse response of an ideal lowpass filter has infinite support, whereas the SoS kernel has compact support.

Using a SoS kernel, the filtered signal y(t) is

$$y ( t ) = {\sum }_{k ∈ 𝒦} \hat{x} [ k ] \hat{g} ( k {ω}_{0} ) {e}^{jk {ω}_{0} t} = {\sum }_{k ∈ 𝒦} \hat{x} [ k ] {e}^{jk {ω}_{0} t} . \qquad ( 15 )$$

The filtered signal y(t) is sampled by an IF-TEM which requires its input to be real-valued and bounded. Since \hat{x}[k] are conjugate symmetric, to ensure that y(t) is real-valued, the support set [symbol] is chosen to be symmetric around zero, that is, [symbol] is, for example, given as

$$𝒦 = \{ - K , … , K \} \qquad ( 16 )$$

where K≥L to ensure that there are at-least 2 L FSCs of x(t) retained in y(t). From Eq. (6) and y(t)=(x*g)(t), it can be shown that

$$c {=}^{Δ} {max}_{t} \vert y ( t ) \vert \leq {La}_{max} {‖ ( h * g ) ‖}_{∞} \qquad ( 17 )$$

$${La}_{max} {‖ g ‖}_{∞} {‖ h ‖}_{1} , \qquad ( 18 )$$

where Young's convolution inequality is used. Since |g(t)|≤ [symbol] | and [symbol] is a finite set, g(t) is bounded. Hence y(t) is bounded provided that the maximal amplitude αₘₐₓ<∞ and the pulse h(t) is absolutely integrable. In the remaining sections, both these conditions are considered as held.

The IF-TEM input is the filtered signal y(t), which is the T-periodic signal defined in Eq. (15). The output of the IF-TEM is a set of time instants [symbol] Given {tₙ} one can determine the measurements {yₙ} by using Eq. (2).

In order to express the relation between the measurements yₙ and the FSCs (that are to be determined) in a matrix form (defined by kernel and the time encodings), a matrix A is defined:

$$A = [ \begin{matrix}{e}^{- jK {ω}_{0} {t}_{2}} - {e}^{- jK {ω}_{0} {t}_{1}} & ⋯ & {t}_{2} - {t}_{1} & ⋯ & {e}^{jK {ω}_{0} {t}_{2}} - {e}^{jK {ω}_{0} {t}_{1}} \\ {e}^{- jK {ω}_{0} {t}_{2}} - {e}^{- jK {ω}_{0} {t}_{2}} & ⋯ & {t}_{3} - {t}_{2} & ⋯ & {e}^{jK {ω}_{0} {t}_{3}} - {e}^{jK {ω}_{0} {t}_{2}} \\ ⋮ & & ⋮ & & ⋮ \\ {e}^{- jK {ω}_{0} {t}_{N}} - {e}^{- jK {ω}_{0} {t}_{N - 1}} & ⋯ & {t}_{N} - {t}_{N - 1} & ⋯ & {e}^{jK {ω}_{0} {t}_{N}} - {e}^{jK {ω}_{0} {t}_{N - 1}}\end{matrix} ] \qquad ( 19 )$$

The relation between the measurements yₙ and the desired FSCs is given by [1]:

$$\begin{matrix}{y}_{n} = {\int }_{{t}_{n}}^{{t}_{n + 1}} y ( t ) dt \\ = {\int }_{{t}_{n}}^{{t}_{n + 1}} {\sum }_{k ∈ 𝒦 ∖ \{ 0 \}} \hat{x} [ k ] {e}^{jk {ω}_{0} t} dt + {\int }_{{t}_{n}}^{{t}_{n + 1}} \hat{x} [ 0 ] dt \\ = {\sum }_{k ∈ 𝒦 ∖ \{ 0 \}} \hat{x} [ k ] \frac{( {e}^{jk {ω}_{0} {t}_{n + 1}} - {e}^{jk {ω}_{0} {t}_{n}} )}{jk {ω}_{0}} + \hat{x} [ 0 ] ( {t}_{n + 1} - {t}_{n} )\end{matrix} \qquad ( 20 )$$

To extract the desired FSCs from Eq. (20), the vector

$${[ {\int }_{{t}_{1}}^{{t}_{2}} y ( t ) dt , {\int }_{{t}_{2}}^{{t}_{3}} y ( t ) dt , … , {\int }_{{t}_{N - 1}}^{{t}_{N}} y ( t ) dt ]}^{T}$$

is denoted by, where N is the number of time instants in the interval T; and \hat{x} is defined:

$$\hat{x} = {[ - \frac{\hat{x} [ - K ]}{j K {ω}_{0}} , … , \hat{x} [ 0 ] , … , \frac{\hat{x} [ K ]}{j K {ω}_{0}} ]}^{T} . \qquad ( 21 )$$

With this notation, Eq. (20) can be written in the following matrix form:

$$y = A \hat{x} , \qquad ( 22 )$$

where A is given in Eq. (19). Hence, this equation describes the relation between the IF-TEM measurements and the FSCs.

The goal is to determine these FSCs embedded in \hat{x} from which a perfect recovery of the FRI parameters may be performed. If the matrix A has full column rank, then the Fourier coefficients vector can be computed as

$$\hat{x} = {A}^{†} y , \qquad ( 23 )$$

where A^{†} denotes the Moore-Penrose inverse.

In [1], the matrix is assumed to be uniquely left-invertible. The authors showed via simulations that the matrix has full column rank, however, a proof is not presented. In the following, the inventors show that for an adequate number of firings, the matrix A is indeed uniquely left-invertible, that is, has full column rank.

In the following, some main results are presented: it is shown that for the sampling kernel choice Eq. (14), it is possible to uniquely identify the FSCs from the IF-TEM time instants. Specifically, it is shown that for a particular choice of the IF-TEM parameters, the matrix A defined in Eq. (19) is left-invertible. The results are summarized in the following theorems.

Theorem 1: Consider a positive integer K and a number T≥0. Let 0≤t₁<t₂< . . . <t_{N}<T for an integer N, and

$${ω}_{0} = \frac{2 π}{T} .$$

Then the matrix A defined in Eq. (19) is left-invertible provided that N≥2K+2.

The proof is described further below Appendix.

Theorem 1 implies that there should be a minimum of 2K+2 IF-TEM time instants within an interval of T to enable recovery of the FSCs, and subsequent reconstruction of the FRI signal. To ensure this, the minimum firing rate

$$\frac{b - c}{κ δ} \qquad ( cf . Eq . ( 5 ) )$$

should be chosen such that

$$\frac{b - c}{κ δ} \geq \frac{2 K + 2}{T} . \qquad ( 24 )$$

By combining Theorem 1, the result in Eq. (24), and the fact that 2 L FSCs are sufficient to recover the FRI parameters, the inventors have formulated the sampling and reconstruction of FRI signals using IF-TEM in the following theorem.

Theorem 2: Let x(t) be a T-periodic FRI signal of the following form

$$x ( t ) = {\sum }_{p ∈ ℤ} {\sum }_{ℓ = 1}^{L} {a}_{ℓ} h ( t - {τ}_{ℓ} - p T ) ,$$

where [symbol] ∈[0, T), | [symbol] |<∞, and L is known. It is assumed that the amplitudes

$${\{ {a}_{ℓ} \}}_{ℓ = 1}^{L}$$

are finite, and the pulse h(t) is known and absolutely integrable. Consider the sampling mechanism shown in FIG. 2A. Let the sampling kernel g(t) satisfy

$$\hat{g} ( k {ω}_{0} ) = \{ \begin{matrix}1 & if k ∈ 𝒦 = \{ - K , … , K \} , \\ 0 & otherwise ,\end{matrix}$$

and maxₜ|(h*g)(t)|<∞. Choose the real positive TEM parameters {b, κ, δ} such that c<b<∞, where c is defined in (Eq. A-18), and

$$\frac{b - c}{κ δ} \geq \frac{2 K + 2}{T} . \qquad ( 25 )$$

Then, the parameters

$${\{ {a}_{ℓ} , {τ}_{ℓ} \}}_{ℓ = 1}^{L}$$

can be perfectly recovered from the TEM outputs if K≥L.

Based on Theorem 2, a reconstruction algorithm to compute the FRI parameters from TEM firings is presented in Algorithm 1.

Algorithm 1: Reconstruction of a T-Periodic FRI Signal Using Theorem 2.

$Input \text{:} N \geq 2 K + 2 spike times {\{ {t}_{n} \}}_{n - 1}^{N} in a period T .$

| | |
|---|---|
| 1: | Let n ← 1 |
| 2: | while n ≤ N − 1 do |
| 3: | Compute yₙ = − b(tₙ₊₁ − tₙ) + κδ |
| 4: | n := n + 1. |
| 5: | end while |
| 6: | Compute Fourier coefficients vector \hat{x} =A^{†}y in Eq. (23). |
| 7: | $Estimate {\{ ( {a}_{ℓ ,} {τ}_{ℓ} ) \}}_{ℓ - 1}^{L} using a spectral analysis method .$ |

$Output \text{:} {\{ ( {a}_{ℓ ,} {τ}_{ℓ} ) \}}_{ℓ - {1}^{*}}^{L}$

It should be noted that not all steps of this algorithm have to be implemented to be useful. For example, step (7) could be performed with a different method than a spectral analysis method, or not performed at all by a certain device, for example, a unit of ADC. Also, even one iteration calculation according to step (3) leads to a useful data.

The IF-TEM parameters may be selected such that there is a minimum of N≥2 L+2 time instants

$${\{ {t}_{n} \}}_{n = 1}^{N}$$

within a time interval T. Thus, the minimum firing rate that enables accurate reconstruction is

$$\frac{2 L + 2}{T} .$$

The maximum firing rate is bounded by

$$\frac{b + c}{κ δ} .$$

While the threshold δ, which is a parameter of the comparator, is easier to control, the integrator constant κ is a parameter of the integrator, and it is usually fixed. Thus, assuming a fixed value of b and κ, choosing small δ results in a large firing rate above the minimum desirable value of

$$\frac{2 L + 2}{T} .$$

In practice, both b and δ may be generated through a DC voltage source, and therefore large values of bias and threshold require high power. Hence, to minimize the power requirements, it is desirable for b and δ to be as small as possible.

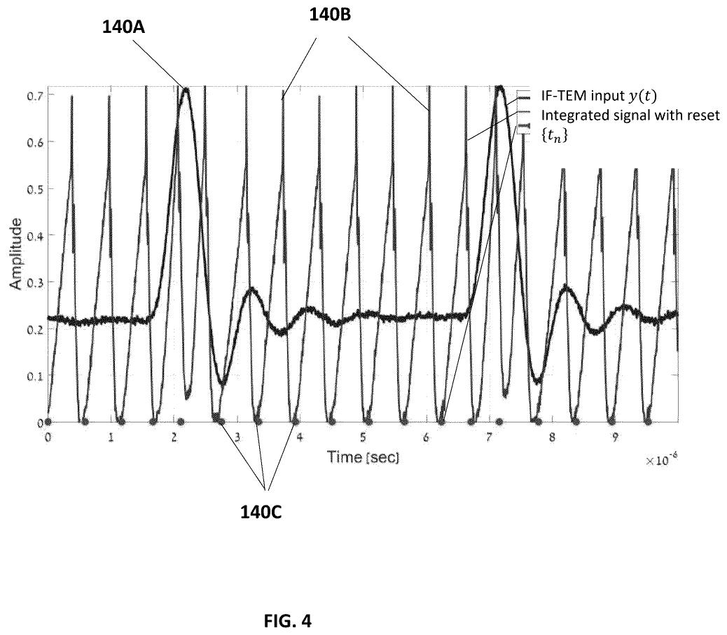

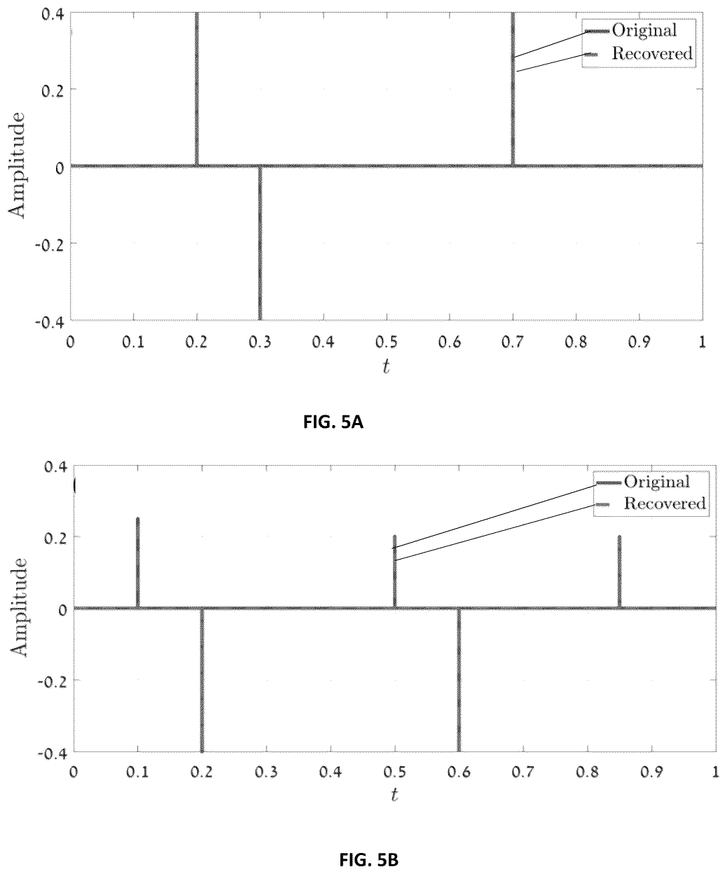

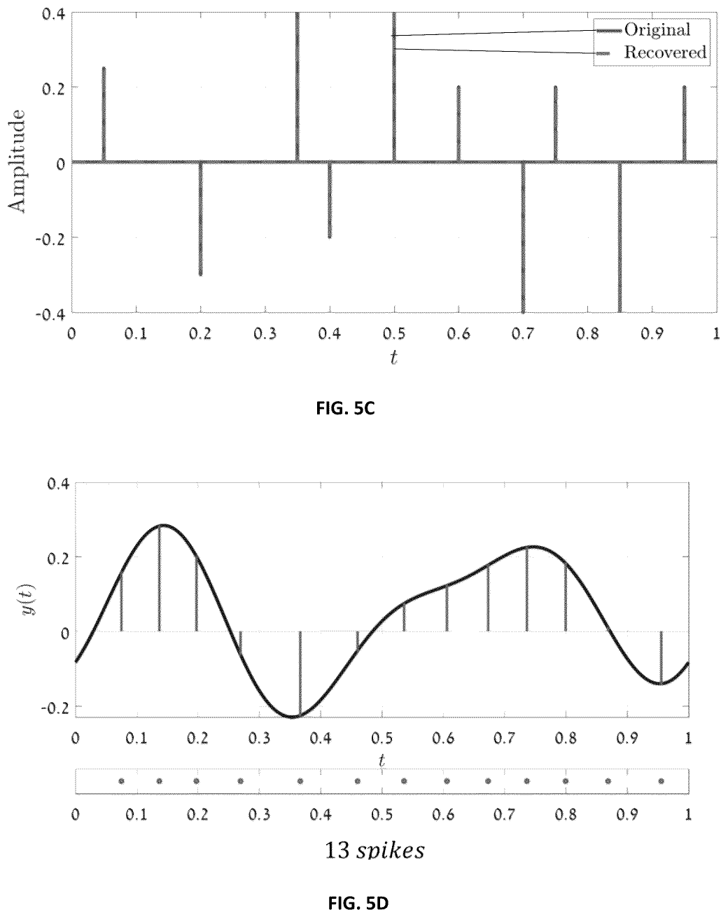

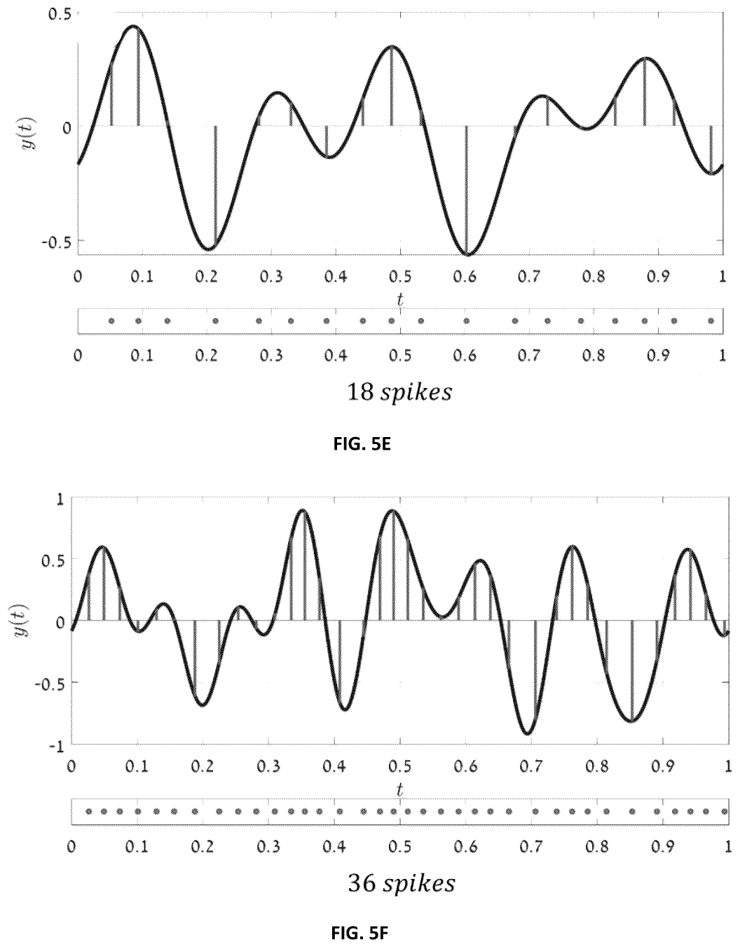

Next, the inventors have numerically validated Theorem 2. FIGS. 5A-5F illustrate sampling and reconstruction of a stream of Dirac impulses using TEM by applying the SoS kernel, according to the present disclosure. Here, both [symbol] and [symbol] are chosen uniformly at random over (0,1). FIGS. 5A-5C show the input signal and its reconstruction for L=3, L=5, and L=10 respectively, and FIGS. 5D-5F show the filtered signal y(t) and the time instants tₙ for L=3, L=5, and L=10 respectively. In FIGS. 5A-5F, h(t) is considered as a Dirac impulse with time period T=1 seconds. Simulations for L=3, 5, and 10 have been performed. The time delays and amplitudes were selected uniformly at random over (0,1). The input signal x(t) was filtered using an SoS sampling kernel with [symbol] ={−K, . . . , K}, where K=L. The filtered output y(t) was sampled using an IF-TEM which has a threshold δ=0.07 and κ=1. The bias of the IF-TEM was set as b=0.9, 1.3, and 2.5 for L=3, 5, and 10 respectively. The parameters are chosen to satisfy the inequality in Eq. (25), and resulted in 13, 18, and 36 samples per period for L=3, 5, and 10. Per Theorem 2, 8, 12, and 22 samples per period were sufficient. The reconstruction was found to be stable even for a larger number of impulses. The choice of IF-TEM parameters and the resulting firing rate are presented in Table 1:

TABLE 1

| L | b | δ | κ | ω₀ | F_{R} (samples/s) |
|---|---|---|---|---|---|
| 3 | 0.9 | 0.07 | 1 | 2π | 13 |
| 5 | 1.3 | 0.07 | 1 | 2π | 18 |
| 10 | 2.5 | 0.07 | 1 | 2π | 36 |

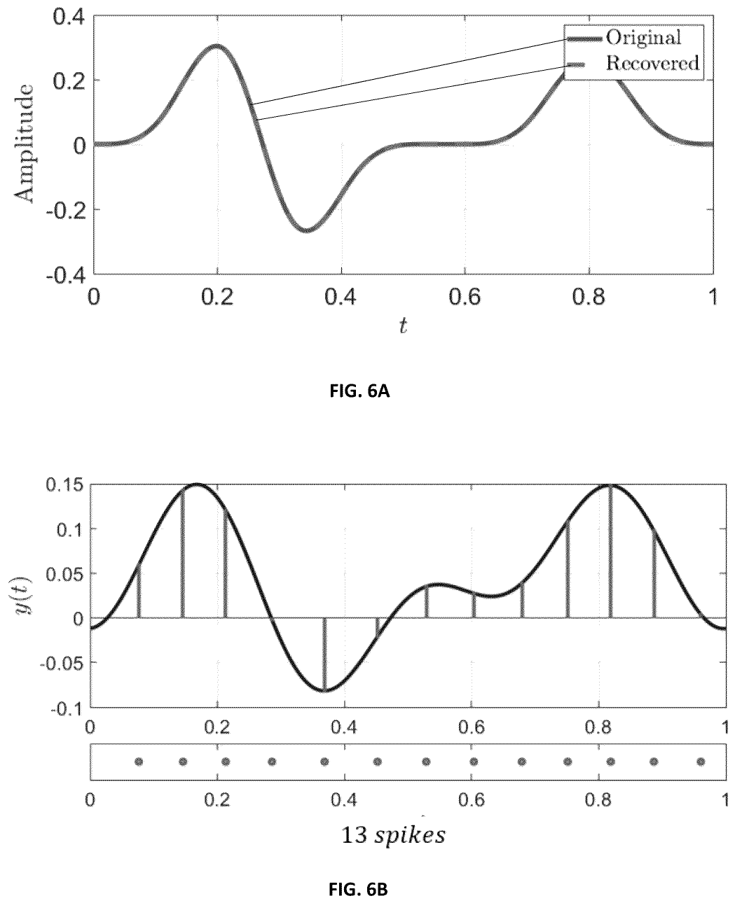

FIGS. 6A to 6B illustrate sampling and reconstruction of stream of pulses using TEM by applying the SoS kernel, according to the present disclosure, showing the input signal and its reconstruction for L=3 (FIG. 6A)), and the filtered signal y(t) and the time instants tₙ for L=3 (FIG. 6B). In FIGS. 6A to 6B, the estimation, using the same filter, of a stream of pulses is depicted with L=3, { [symbol] }={0.5, −0.45, 0.4}, and { [symbol] }={0.2, 0.33, 0.8}. The IF-TEM b, δ, κ which satisfy the inequality in Eq. (25), are 0.9, 0.07, 1 respectively. The resulting firing rate is as few as 13 samples/s.

The results in [1] and the previous section were based on the approximation that there is no measurement noise. However, in practice, the signals are contaminated by noise. In the presence of noise, the IF-TEM outputs or time instants are perturbed. While using Algorithm 1, this results in a perturbation in the matrix A as well as the measurements y in Eq. (22). In this case, when computing the FSCs using Eq. (22), the stability of A, which is measured by the condition number of the matrix, impacts the results. Next, it is shown that, according to the present disclosure, by excluding zero from [symbol] , perfect recovery is possible, and in the noisy scenario, the resulting method is more robust.

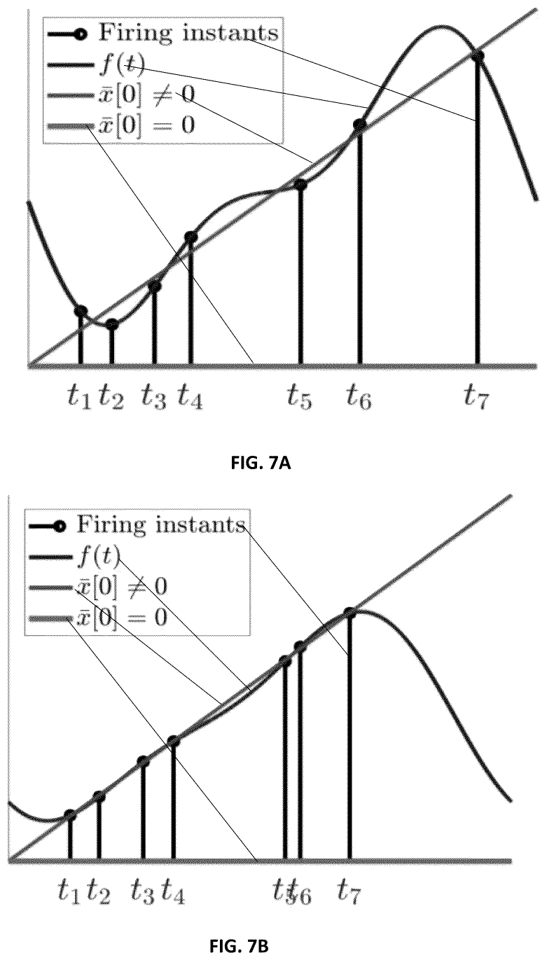

As it is shown below, when excluding the zero vector, a recovery problem becomes similar to Eq. (23) but with the matrix B defined in Eq. (29) replacing A. This matrix has a better condition number than A. To gain intuition as to why this is the case, the intersection of a function ƒ(t) and a straight line r(t) as shown in FIGS. 7A and 7B is considered. The function ƒ(t) is a K-th order trigonometric polynomial whose coefficients are FSCs of the FRI signal and the slope of r(t) is equal to x̅[0]=\hat{x}[0](see the Appendix for more details). As it is discussed in detail in the Appendix, the closer the values of ƒ(t) to r(t) at the time encoding instants, the poorer the condition number of the corresponding matrices.

As shown in the Appendix, the matrices A and B have full column rank provided that the straight line r(t)≠ƒ(t) at all time-encoding instants

$${\{ {t}_{n} \}}_{n = 1}^{N} ,$$

and this condition holds for N>2K+1. Note that x̅[0]≠0 when we consider matrix A and x̅[0]=0 in the context of matrix B. Furthermore, it can be shown that the smaller the values of

$${\{ \vert r ( t ) - f ( t ) \vert \}}_{{t}_{n} = 1}^{N}$$

the poorer the condition number. For N>2K+1 and x̅[0]≠0, it is possible that there exists a set of time encodings

$${\{ {t}_{n} \}}_{n = 1}^{N}$$

such that the straight line r(t) is close to the trigonometric polynomial ƒ(t) at

$${\{ {t}_{n} \}}_{n = 1}^{N} .$$

In such a case, from Eq. (44), a set of Fourier coefficients can be determined such that A\hat{x}≈0_{N}, where 0_{N} is a zero vector of length N. Hence for that particular set of

$${\{ {t}_{n} \}}_{n = 1}^{N} ,$$

A becomes ill-conditioned. However, when x̅[0]=0, the inventors have observed that it is less likely that r(t) with zero-slope becomes close to ƒ(t) at the time-encoding instants.

Several illustrative examples depicting this intuition are shown in FIGS. 7A to 7B where K=2 and N=7. In FIG. 7A, the condition number of matrices A and B are 30 and 3, respectively. The condition number of A is ten times higher than that of B. This is because the straight line corresponding to A (shown in red) is closer to the trigonometric polynomial at the time-encodings than that of B (in magenta). In the example shown in FIG. 7B, the condition number of A is 3000 as |r(t)−ƒ(t) is small for

$$t ∈ {\{ {t}_{n} \}}_{n = 1}^{N} ,$$

whereas |r(t)−ƒ(t) is relatively large for x̅[0]=0 and consequently B has lower condition number.

Next, a perfect recovery guarantee for FRI signals is presented by using IF-TEM without the zero frequency in the SoS kernel.

In the following, it is shown that by excluding the zero frequency in [symbol] the inventors have achieved perfect reconstruction for FRI signals of the form of Eq. (6). In this case, the resulting matrix has a much more stable structure compared to A of Eq. (19). Suppose k=0 is removed; then, following Eq. (20)

$$\begin{matrix}{y}_{n} = {\int }_{{t}_{n}}^{{t}_{n + 1}} y ( t ) dt \\ = {\int }_{{t}_{n}}^{{t}_{n + 1}} {\sum }_{k ∈ 𝒦 ∖ \{ 0 \}} \hat{x} [ k ] {e}^{j k {ω}_{0} t} dt \\ = {\sum }_{k ∈ 𝒦 ∖ \{ 0 \}} \hat{x} [ k ] \frac{( {e}^{jk {ω}_{0} {t}_{n + 1}} - {e}^{jk {ω}_{0} {t}_{n}} )}{jk {ω}_{0}}\end{matrix} . \qquad ( 26 )$$

To extract the FSCs from Eq. (26), by y₀ the vector

$${[ {\int }_{{t}_{1}}^{{t}_{2}} y ( t ) dt , {\int }_{{t}_{2}}^{{t}_{3}} y ( t ) dt , ... , {\int }_{{t}_{N - 1}}^{{t}_{N}} y ( t ) dt ]}^{T}$$

is denoted, where N is the number of time instants in the interval T. The measurements y₀ and the FSCs

$${\hat{x}}_{0} = {[ - \frac{\hat{x} [ - K ]}{jK {ω}_{0}} , ... , - \frac{\hat{x} [ - 1 ]}{j {ω}_{0}} , \frac{\hat{x} [ 1 ]}{j {ω}_{0}} , ... , \frac{\hat{x} [ K ]}{jK {ω}_{0}} ]}^{T} \qquad ( 27 )$$

are now related as

$${y}_{0} = B {\hat{x}}_{0} , \qquad ( 28 )$$

where B is given as in Eq. (29). Next, it is shown that the matrix B has full column rank and is uniquely left invertible (and Eq. (29) is shown below).
Theorem 3: Consider a positive integer K and a number T>0. Let 0≤t₁<t₂< . . . <t_{N}<T for an integer N, and

$${ω}_{0} = \frac{2 π}{T} .$$

Then the matrix B defined in Eq. (29) is left-invertible provided that N>2K+1.

Proof: The proof follows the same line as that of Theorem 1 with the constraint \hat{x}[0]=0 as detailed in Case-1 in the Appendix.

$$B = [ \text{} \begin{matrix}{e}^{- jK {ω}_{0} {t}_{2}} - {e}^{- jK {ω}_{0} {t}_{1}} & … & {e}^{- j {ω}_{0} {t}_{2}} - {e}^{- j {ω}_{0} {t}_{1}} & {e}^{j {ω}_{0} {t}_{2}} - {e}^{j {ω}_{0} {t}_{1}} & … & {e}^{jK {ω}_{0} {t}_{2}} - {e}^{jK {ω}_{0} {t}_{1}} \\ {e}^{- jK {ω}_{0} {t}_{3}} - {e}^{- jK {ω}_{0} {t}_{2}} & … & {e}^{- j {ω}_{0} {t}_{3}} - {e}^{- j {ω}_{0} {t}_{2}} & {e}^{j {ω}_{0} {t}_{3}} - {e}^{j {ω}_{0} {t}_{2}} & … & {e}^{jK {ω}_{0} {t}_{3}} - {e}^{jK {ω}_{0} {t}_{2}} \\ ⋮ & & ⋮ & ⋮ & & ⋮ \\ {e}^{- jK {ω}_{0} {t}_{N}} - {e}^{- jK {ω}_{0} {t}_{N - 1}} & … & {e}^{- j {ω}_{0} {t}_{N}} - {e}^{- j {ω}_{0} {t}_{N - 1}} & {e}^{j {ω}_{0} {t}_{N}} - {e}^{j {ω}_{0} {t}_{N - 1}} & … & {e}^{jK {ω}_{0} {t}_{N}} - {e}^{jK {ω}_{0} {t}_{N - 1}}\end{matrix} \text{} ] \qquad ( 29 )$$

Since the left-inverse of B exists, the Fourier coefficients vector is computed as

$${\hat{x}}_{0} = {B}^{†} {y}_{0} . \qquad ( 30 )$$

Although the FSCs are computed uniquely, they are not consecutive unlike the FSCs computed in Theorem 2. Since high resolution spectral estimation techniques such as the annihilating filter requires 2 L consecutive FSCs, to uniquely determine the FRI parameters, it is needed that K≥2 L. This results in twice the firing rate compared to that in Theorem 2.

An alternative approach to reduce the firing rate is to assume that the time-delays are on a grid. In this case, determination of time-delays and amplitudes of the FRI signal from FSCs is cast as a compressive sensing problem [3]. This problem is efficiently solved from 2 L FSCs, that are not necessarily consecutive, by using sparse recovery approaches such as orthogonal matching pursuit (OMP). Hence, by assuming that the time-delays of the FRI signal are on a grid, it is required that K≥L.

The minimum firing rate for the IF-TEM is

$$\frac{b - c}{κ δ} \geq \frac{2 K + 2}{T} , \qquad ( 31 )$$

where K≥2 L for off-grid time-delays and K≥L for time-delays on-grid. By combining Theorem 3 with the result in Eq. (31), the sampling and reconstruction of FRI signals using IF-TEM is described in the following theorem.
Theorem 4: Let x(t) be a T-periodic FRI signal of the following form

$$x ( t ) = {\sum }_{p ∈ ℤ} {\sum }_{ℓ = 1}^{L} {a}_{ℓ} h ( t - {τ}_{ℓ} - p T ) ,$$

where the number of FRI signals L is known, and h(t) is a signal with known pulse shape. Consider the sampling mechanism shown in FIG. 2A. Let the sampling kernel g(t) satisfy

$$\hat{g} ( k {ω}_{0} ) = \{ \begin{matrix}1 & if k ∈ 𝒦 = \{ - 𝒦 , … , - 1 , 1 , … , 𝒦 \} \\ 0 & otherwise\end{matrix} ,$$

and maxₜ|(h*g)(t)|<∞. Choose the real positive TEM parameters {b, κ, δ} such that c<b<∞, where c is defined in (Eq. A-18), and

$$\frac{b - c}{κ δ} \geq \frac{2 K + 2}{T} . \qquad ( 32 )$$

Then, the parameters

$${\{ {a}_{ℓ} , {τ}_{ℓ} \}}_{ℓ = 1}^{L}$$

can be perfectly recovered from the TEM outputs if
1) K≥2 L when

$${\{ {τ}_{ℓ} \}}_{ℓ = 1}^{L}$$

are off-grid,
2) K≥L when

$${\{ {τ}_{ℓ} \}}_{ℓ = 1}^{L}$$

are on-grid.
Since the time delays and amplitudes, of the FRI signals are estimated uniquely, without any constant offset, from any set of 2 L or more consecutive FSCs, excluding the zero frequency does not result in any offset in the reconstruction. An algorithm to perfectly recover the FRI parameters from IF-TEM samples is summarized in Algorithm 2.

Algorithm 2: Reconstruction of a T-Periodic FRI Signal.

| | |
|---|---|
| | $Input : N \geq 2 K + 2 spike times {\{ {t}_{n} \}}_{n = 1}^{N} in a period T .$ |
| 1: | Let n ← 1 |
| 2: | while n ≤ N − 1 do |
| 3: | Compute yₙ = − b(tₙ₊₁ − tₙ) + κδ |
| 4: | n := n + 1. |
| 5: | end while |
| 6: | Compute Fourier coefficients vector \hat{x}₀ = B^{†}y₀ in Eq. (30). |
| 7: | $Estimate {\{ ( {a}_{ℓ} , {τ}_{ℓ} ) \}}_{ℓ = 1}^{L} from {x}_{0} by using CS methods for K \geq L$ |
| | $Output : {\{ ( {a}_{ℓ} , {τ}_{ℓ} ) \}}_{ℓ = 1}^{L} .$ |

It should be noted that not all steps of this algorithm have to be implemented to be useful. For example, step (7) could be performed with a different method than a CS method, or not performed at all by a certain device, for example, a unit of ADC. Also, even one iteration calculation according to step (3) leads to a useful data.

In many practical systems, the time instants can only be recorded with finite precision, i.e., in practical circumstances, the recorded times are effective time instances

$$\{ {t}_{n}^{′} \}$$

which differ from the real-time instances {tₙ}, and perfect reconstruction may no longer be possible.

The inventors have compared the robustness of the Algorithms 1 and 2 in the presence of perturbation to the measured time instants. Algorithm 2 has provided better recovery than Algorithm 1.

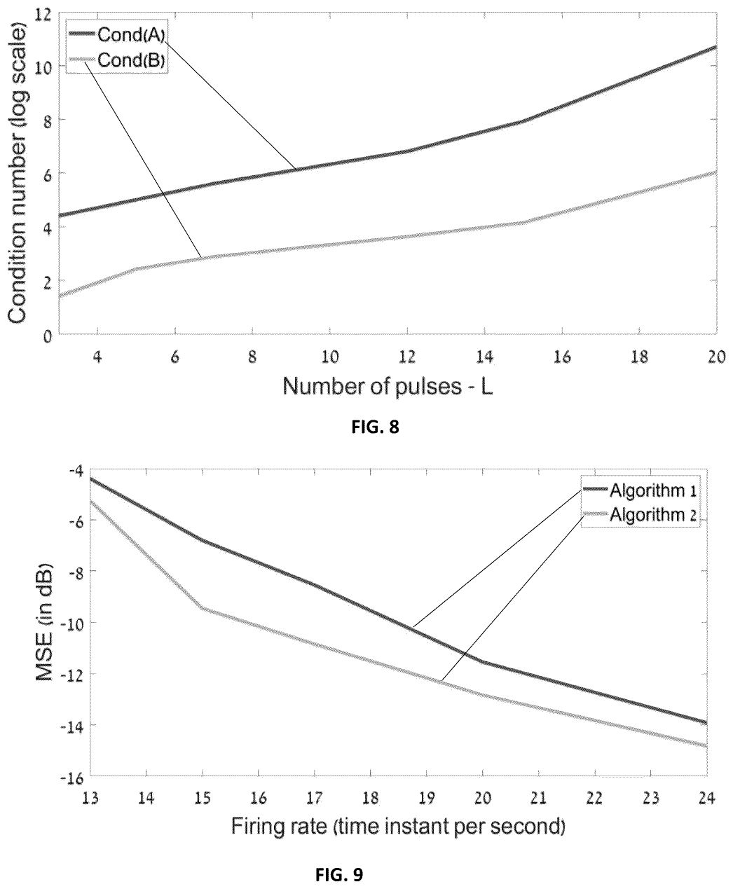

In the above Algorithms, the first step is to estimate the Fourier samples from the TEM measurements by taking pseudo inverses of A (cf. Eq. (22)) and B (cf. Eq. (28)), respectively. Both the matrices are functions of the measured time instants and the sampling kernel. In FIG. 8, the condition numbers of the matrices with perturbed firing instants are compared, as a function of the number of FRI signals L. To that aim, 5000 random sets of monotonic sequences

$${\{ {t}_{n} ∈ [ 0 , T ) \}}_{n = 1}^{N}$$

were used. As shown in FIG. 8, the condition number of the matrix B∈ [symbol] ^{(4L+2)×(2L)} is substantially smaller than the condition number of the matrix A∈ [symbol] ^{(4L+2)×(2L+1)}.

Next, the inventors have performed the reconstruction of a T-periodic FRI signal from non-uniform noisy samples (time instants) using the two reconstruction algorithms of Theorems 2 and 4. A periodic FRI signal x(t) of the form of Eq. (6) was created. The signal x(t) with period T=1 consists of L=3 pulses with h(t)=β⁽³⁾(20t), where β⁽³⁾(t) is a third-order cubic B-spline, with

$${\{ {a}_{ℓ} \}}_{ℓ = 1}^{3} = \{ 0 \text{.5} , - 0.45 , 0.4 \} ,$$

and

$${\{ {τ}_{ℓ} \}}_{ℓ = 1}^{3} = \{ 0.2 , 0.4 , 0.8 \} .$$

The TEM parameters are b=1.2, κ=1, and δ changes from 0.04 to 0.09 resulting in 13 to 24 time samples. The parameters are chosen to satisfy the condition of Eq. (32). We consider a sum-of-sincs kernel with [symbol] ={−K, . . . ,0, . . . , K} for Theorem 2, and [symbol] ={−K, . . . , −1,1, . . . , K} for Theorem 4. For both kernels, the time instances {tₙ} were perturbed by a zero-mean white Gaussian noise with variance 0.001. For both the methods it was set K=2 L, and OMP was applied to recover the time-delays and amplitudes.

The reconstruction accuracy of the two algorithms is compared in terms of relative mean square error (MSE), given by

$$M S E = \frac{{‖ x ( t ) - \overline{x} ( t ) ‖}_{{L}_{2} [ 0 , T ]}}{{‖ x ( t ) ‖}_{{L}_{2} [ 0 , T ]}} , \qquad ( 33 )$$

where x̅(t) is the reconstructed signal. In FIG. 9, the MSE of the two algorithms is shown as a function of the number of noisy time instances. The MSE of Algorithm 2 is 2-6 dB lower compared to that of Algorithm 1 for different firing rates.

Next, the inventors have compared the two frameworks when the input FRI signal has noise. To simulate a continuous-time noise effect on the input to IF-TEM, perturbation to the FSCs at the output of the SoS filter was added. In the noisy case, the output of the SoS filter is given by

$${γ}^{′} ( t ) = {\sum }_{k ∈ 𝒦} ( \hat{x} [ k ] + ξ [ k ] ) {e}^{j k {ω}_{0} t} , \qquad ( 34 )$$

where [symbol] are independent and identically distributed circular complex Gaussian random variables with zero mean and variance σ_{\hat{x}}. In this simulation, SNR was defined as

$$10 {log}_{10} ( \frac{{\sum }_{k ∈ 𝒦} {\vert \hat{x} [ k ] \vert}^{2}}{\vert 𝒦 \vert {σ}_{\hat{x}}^{2}} ) . \qquad ( 35 )$$

The inventors have compared Algorithm 1 and 2 in terms of MSE in the estimation of time delays as:

$$M S E = 10 log ( {\sum }_{ℓ = 1}^{L} {( {τ}_{ℓ} - {\hat{τ}}_{ℓ} )}^{2} ) . \qquad ( 36 )$$

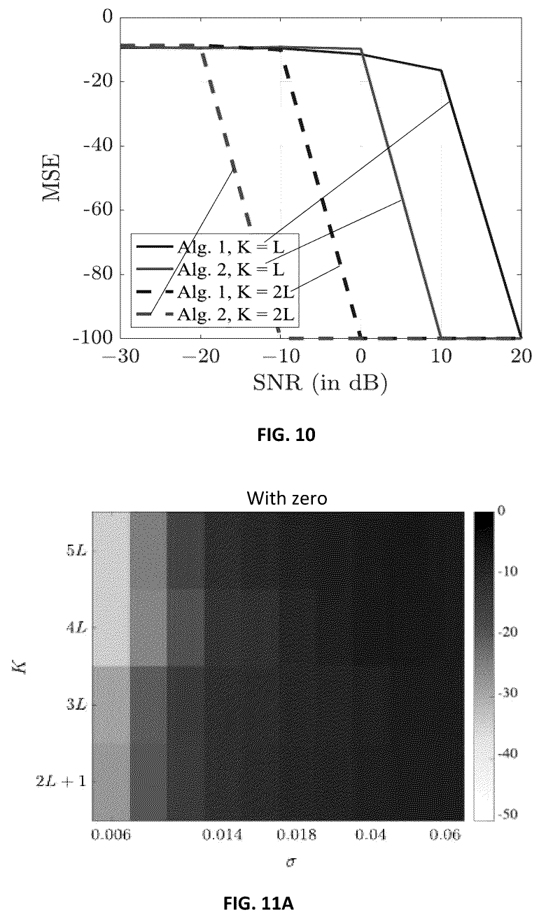

For both approaches, the inventors have used the same number of firing rates and measurements. The time delays were estimated by the OMP algorithm. The MSEs in the time delay estimation are shown in FIG. 10 for different SNRs and for K=L, 2 L. The inventors have observed that for SNR>−20 dB, Algorithm 2 has lower error compared to Algorithm 1.

The following experiments consider off-grid time-delays with h(t) as a third-order cubic B-spline. The inventors have considered L=3 pulses where time-delays and amplitudes are generated uniformly at random over intervals (0, T] and [1,5], respectively. For IFTEM, t κ=1 and b=2.5c were set where c is computed as in Eq. (18). The threshold δ is chosen to satisfy Eq. (24). To compare the methods with zero and without-zero frequency, the inventors have considered sampling SoS kernels with [symbol] ={−K, . . . , K} and {−K, . . . , −1,1, . . . , K}, respectively. The inventors have used an annihilating filter with Cadzow denoising to estimate the time-delays in the presence of noise. Since Cadzow denoising requires more than 2 L consecutive samples of FSCs, the inventors have considered K≥2 L+1 while excluding the zero. Based on the fact that Algorithm 2 estimates

$${\{ \hat{x} [ k ] \}}_{k = - K}^{- 1} and {\{ \hat{x} [ k ] \}}_{k = 1}^{K} ,$$

Cadzow denoising on each of these sequences independently was applied; and then block annihilation to determine the time-delays jointly was applied. In addition, the inventors have shown results for estimation of signal parameters via rotational invariance technique (ESPRIT) for with zero approach as well as for without zero approach.

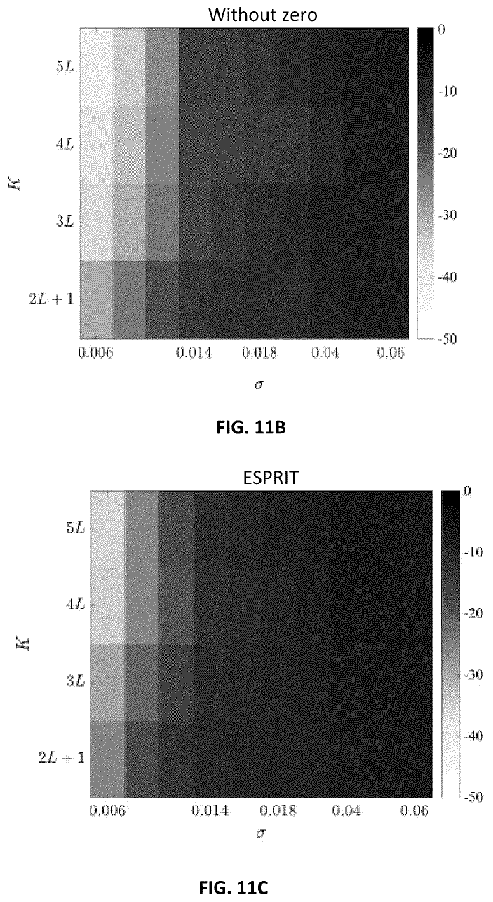

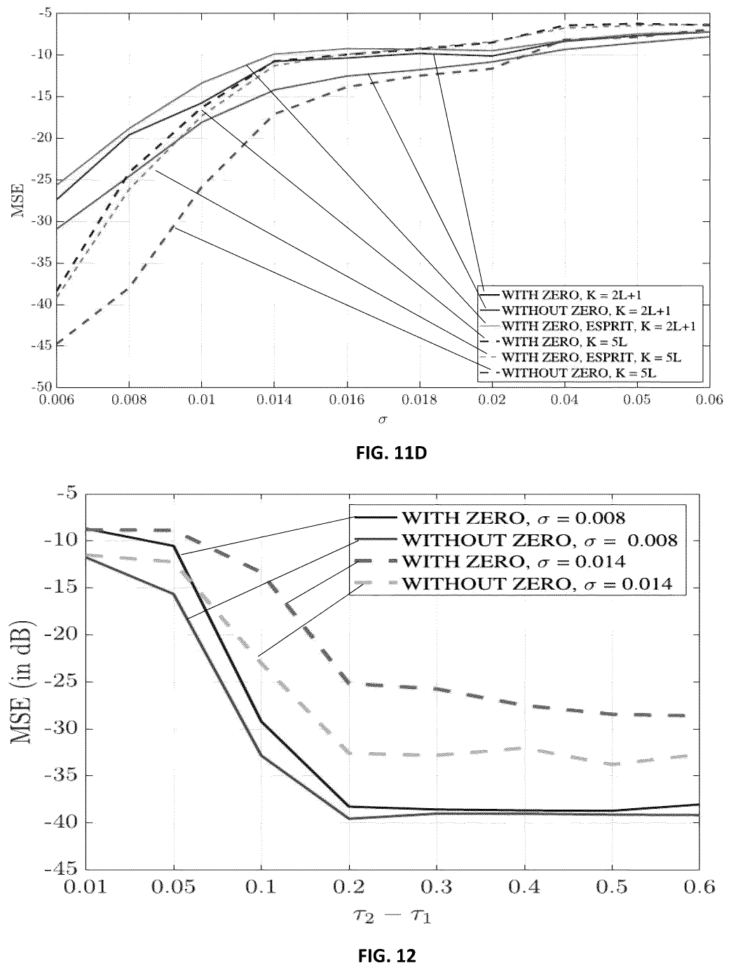

In this simulation, the inventors have compared the two approaches in terms of MSEs (cf. Eq. (36)) when the time encodings are perturbed. The perturbed time encodings are given as

$${t}_{n}^{′} = {t}_{n} + {ϵ}_{n}$$

where t₀ is the actual time encoding and En is a random variable uniformly distributed over [−σ/2, σ/2]. The MSEs in the estimation of time-delays for different numbers of FSCs and perturbation levels are shown in FIGS. 11A to 11D illustrating comparison of with zero (Algorithm 1) and without zero (Algorithm 2) approaches for off-grid time delays with perturbation in the time encodings. The inventors used 500 independent noise and FRI signal realizations to compute each MSE value. In FIGS. 11A, 11B, and 11C MSEs for with zero, without zero, and ESPRIT approaches are shown. In FIG. 11D, one-dimensional MSE plots for K=2 L+1 and 5 L are shown for further clarity. In these experimental settings, the time encodings had values between [0, T] where T=1 sec. In this case, adding a perturbation with σ≥0.04 had severe effect on the recovery with MSE in the range of −5 dB for all the approaches. The inventors have observed that the zero approach and ESPRIT have similar MSEs. While comparing these two approaches with the proposed without zero approach, the inventors have noted a gain of 3-10 dB for σ<0.04. Since perturbation in the time encoding is also equivalent to quantization noise, a lower MSE indicates that the proposed without zero approach can operate at lower bits compared to with zero method.

The accuracy of time-delay estimations of any FRI recovery approach is strongly dependent on the minimum distance between two consecutive FRI pulses in the presence of noise. To analyze the resolution abilities of the two approaches, an FRI signal with two pulses of equal amplitudes has been considered. By treating the difference between the time delays, τ₂−τ₁, the inventors have computed MSEs (as in Eq. (36)) in their estimation when the time encodings are perturbed with σ=0.008 (low noise) and σ=0.014 (high noise). The results are shown in FIG. 12. For both the noise levels without zero approach has a lower MSE compared to the with zero approach. The gain in the MSE is more prominent (up to 5 dB) for the high noise level. The results show that without zero approach has better resolution compared to the with zero approach.

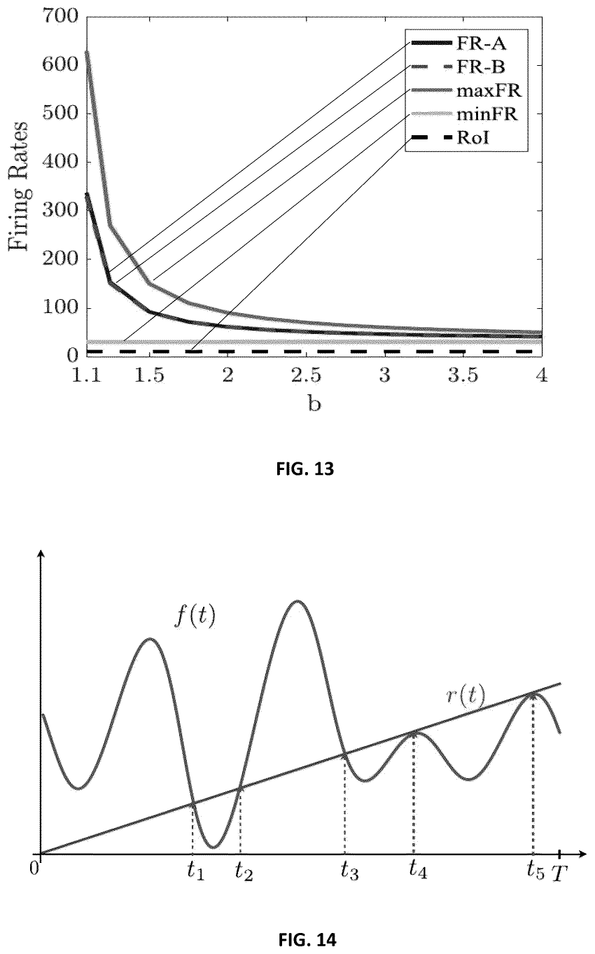

Unlike conventional sampling, the number of measurements per unit time in the IF-TEM is not fixed. For a class of c-bounded FRI signals, parameters {K, b, (} were chosen to achieve a desired minimum firing rate. However, the firing rate may vary from signal to signal in the class considered. The bias b plays an important role in designing the rate as it should always be kept above c (which is maximum amplitude of x in absolute value, i.e., |x(t)|≤c). In this experiment, the inventors have analyzed the effect of b on the firing rate for a fixed c. To this end, it was set c=1; and b was varied. For each b, the inventors have generated 100 FRI signals with randomly chosen amplitudes and time-delays such that the signals are bounded by c. The average firing rates for both with zero (denoted as FR-A) and without zero (denoted as FR-B) approaches were computed and are shown in FIG. 13. Also the maximum firing (maxFR) and minimum firing (minFR) rates,

$$\frac{b + c}{κ δ} and \frac{b - c}{κ δ}$$

together with the rate of innovation (Rol) 2 L are plotted. Here L=5 was chosen and it was kept fixed for all b. For each b, κ was set to be 1 and δ was selected to satisfy Eq. (24). For both methods, the inventors have had identical mean firing rates.

The inventors have observed that for small values of b, the firing rates are large, and they reduce as b increases. For large values of b, the gap between maxFR and min FR reduces, and IF-TEM operates at a rate closer to Rol (i.e., the rate of innovation). However, a large b amounts to high power consumption. Hence, there is a trade-off between power consumption and the optimum firing rate.

Consider a nonperiodic FRI signal of the form

$$\tilde{x} ( t ) = {\sum }_{ℓ = 1}^{L} {a}_{ℓ} h ( t - {τ}_{ℓ} ) , \qquad ( 37 )$$

where h(t) is a known pulse and the amplitudes and delays {( [symbol] )| [symbol] ∈[0, T),

$${{a}_{ℓ} ∈ ℝ \}}_{ℓ = 1}^{L}$$

are unknown parameters. It is assumed that the pulse h(t) has finite support R, namely

$$h ( t ) = 0 , ∀ \vert t \vert \geq \frac{R}{2} . \qquad ( 38 )$$

Given that according to the present disclosure the interest is in pulses with a very wide or even infinite spectrum, i.e. very short pulses, traditional sampling techniques are expected to be ineffective in this case (see [2]).

The inventors have designed a sampling kernel g(t) such that

$$\tilde{y} ( t ) = \tilde{x} ( t ) * \tilde{g} ( t ) = y ( t ) , ∀ t ∈ [ 0 , T ) , \qquad ( 39 )$$

where y(t) defined in Eq. (11). Specifically, g(t) is compactly supported and defined by

$$\tilde{g} ( t ) = {\sum }_{s = - S}^{S} g ( t + sT ) , \qquad ( 40 )$$

where S is determined by R and T (more details are available in [2]). Since both time instants and the time delays of the FRI signals are within the interval [0, T), i.e., tₙ∈[0, T) and [symbol] ∈[0, T), [symbol] =1, . . . , L, the time instants taken in the nonperiodic case using IF-TEM are the same as in the periodic case. Therefore, the recovery guarantees developed for the periodic case in Theorems 4 and 2 are applicable to the non-periodic case as well.

### APPENDIX

In this Appendix Theorems 1 and 3 are proven. The inventors have considered a unified approach to prove both theorems by using the fact that the proof of Theorem 3 is a special case of that of Theorem 1 with \hat{x}[0]=0.

Proof: The matrix A in (Eq. A-22) is decomposed as

$$A = DV , \qquad ( 41 )$$

$$where$$

$$D = ( \begin{matrix}- 1 & 1 & 0 & … & 0 \\ 0 & - 1 & 1 & … & 0 \\ 0 & 0 & - 1 & … & 0 \\ ⋮ & ⋮ & ⋮ & ⋱ & ⋮ \\ 0 & 0 & 0 & … & 1\end{matrix} ) ∈ {ℝ}^{( N - 1 ) \times N} \qquad ( 42 )$$

and V is given as in (Eq. A-43). To determine \hat{x} uniquely from y=DV \hat{x}, the matrix A should not have a non-zero null space vector. The matrix D is a difference operator which has null space vector C1_{N} where c∈ [symbol] \{0}. Hence, if there exists a non-zero vector x as in Eq. A(21) whose components satisfy Eq. (9), such that Vx=C1_{N} for some arbitrary c, then there does not exist a unique solution. However, according to the present disclosure, it can be shown that for N≥2K+2≥2 L+1, uniqueness is guaranteed. Specifically, it can be shown that there does not exist an x satisfying Eq. (9), a set

$${\{ {t}_{n} \}}_{n = 1}^{N} ,$$

and c≠0 such that Vx=c1_{N} for N>2K+1, Eq. (43), and Eq. (44).

$$V = ( \begin{matrix}{e}^{- jK {ω}_{0} {t}_{1}} & … & {e}^{- j {ω}_{0} {t}_{1}} & {t}_{1} & {e}^{j {ω}_{0} {t}_{1}} & … & {e}^{jK {ω}_{0} {t}_{1}} \\ {e}^{- jK {ω}_{0} {t}_{2}} & … & {e}^{- j {ω}_{0} {t}_{2}} & {t}_{2} & {e}^{j {ω}_{0} {t}_{2}} & … & {e}^{jK {ω}_{0} {t}_{2}} \\ ⋮ & ⋱ & ⋮ & ⋮ & ⋮ & ⋱ & ⋮ \\ {e}^{- jK {ω}_{0} {t}_{N}} & … & {e}^{- j {ω}_{0} {t}_{N}} & {t}_{N} & {e}^{j {ω}_{0} {t}_{N}} & … & {e}^{jK {ω}_{0} {t}_{N}}\end{matrix} ) ∈ \text{} {ℂ}^{N \times 2 K + 1} \qquad ( 43 )$$

$${\underbrace{( \begin{matrix}{e}^{- jK {ω}_{0} {t}_{1}} & … & {e}^{- j {ω}_{0} {t}_{1}} & 1 & {e}^{j {ω}_{0} {t}_{1}} & … & {e}^{jK {ω}_{0} {t}_{1}} \\ {e}^{- jK {ω}_{0} {t}_{2}} & … & {e}^{- j {ω}_{0} {t}_{2}} & 1 & {e}^{j {ω}_{0} {t}_{2}} & … & {e}^{jK {ω}_{0} {t}_{2}} \\ ⋮ & ⋱ & ⋮ & ⋮ & ⋮ & ⋱ & ⋮ \\ {e}^{- jK {ω}_{0} {t}_{N}} & … & {e}^{- j {ω}_{0} {t}_{N}} & 1 & {e}^{j {ω}_{0} {t}_{N}} & … & {e}^{jK {ω}_{0} {t}_{N}}\end{matrix} )}}_{w} {( \begin{matrix}\overline{x} [ - K ] \\ ⋮ \\ \overline{x} [ - 1 ] \\ - c \\ \overline{x} [ 1 ] \\ ⋮ \\ \overline{x} [ K ]\end{matrix} )}_{\underbrace{\overline{x}}} {\underbrace{( \begin{matrix}{t}_{1} \\ {t}_{2} \\ ⋮ \\ {t}_{N}\end{matrix} )}}_{t} \qquad ( 44 )$$

For simplicity of discussion, it is defined:

$$\overline{x} [ k ] = \frac{\hat{x} [ k ]}{jk {ω}_{0}}$$

for k≠0 and x̅[0]=\hat{x}[0]. The modulus and angle of the complex-valued coefficient x[k] is denoted by |x[k]| and <x[k], respectively. The equation Vx=C1_{N} is re-written as in Eq. (44) or alternatively as

$$f ( t ) = r ( t ) , for t = {t}_{1} , ... , {t}_{N} , \qquad ( 45 )$$

$$where$$

$$f ( t ) = c - 2 {\sum }_{k = 1}^{K} \vert \overline{x} [ k ] \vert cos ( k {ω}_{0} t + ∠ \overline{x} [ k ] ) \qquad ( 46 )$$

is a K-th order trigonometric polynomial and r(t)=x̅[0]t is a straight line with slope x̅[0]. If there exist a c and

$${\{ \overline{x} [ k ] \}}_{k = 0}^{K}$$

such that ƒ(t) and r(t) intersect each other N-times within an interval [0,T), that is, there exist a set [symbol] ={tₙ∈[0,T),n=1, . . . , N} satisfying ƒ(t)=r(t) then uniqueness is not guaranteed.

Two mutually exclusive cases can be considered: (1) x̅[0]=\hat{x}[0]=0 and (2) x̅[0]=\hat{x}[0]≠0.

Case-1: For x̅[0]=0, the slope of the straight line r(t) is zero and hence, Eq. (45) is equivalent to determining zeros of ƒ(t) in the interval [0, T). Since ƒ(t) is a trigonometric polynomial of order K with

$${ω}_{0} = \frac{2 π}{T} ,$$

it will have a maximum of 2K zeros within the interval [0, T). Hence, for N>2K, there does not exist a c≠0 and a feasible

$${\{ \overline{x} [ k ] \}}_{k = 0}^{K}$$

such that Eq. (45) holds true.

Case-2: Consider the case when x̅[0]≠0. It is possible to determine the maximum number of intersections of a trigonometric polynomial of order K with a straight line. To this end, let t₁ be the first intersection point. Further, it can be assumed that the slope of ƒ(t) at t=t₁ is positive (or negative), that is, ƒ′(t₁)>0 (or ƒ′(t₁)<0) where ƒ′(t) denotes derivative of ƒ(t). This implies that there may exist a minimum (or maximum) of ƒ(t) for t∈[0, t₁) and a maximum (or minimum) for t∈(t₁, T). An illustrative example is shown in FIG. 14. Since r(t) is a monotone function, to have a second intersection t₂, it is necessary that ƒ′(t) changes its sign. In essence, if there exist a t₂∈ [symbol] , then there should be a maximum (or minimum) of ƒ(t) in the interval (t₁, t₂). Applying this argument to the remaining intersection points in [symbol] it is inferred that for N intersection points there should be at least N−1 extrema. Alternatively; a function with N−1 extrema can intersect a monotone function at a maximum of N points. As ƒ′(t) too is a K-th order trigonometric polynomial, it has a maximum of 2K zeros. This implies that ƒ(t) can have a maximum of 2K extrema. Hence, ƒ(t) can intersect r(t) at a maximum of 2K+1 points within interval [0, T). This implies that for N>2K+1, the equation ƒ(t)=r(t) can not have any solution and hence, matrix A does not have a non-zero null-vector and uniqueness is guaranteed.

Hence, in the above sampling and reconstruction frameworks for periodic FRI signals by using IF-TEMs have been described. A robust recovery approach has been provided with the sampling kernel different than in [1]. In the presence of perturbations of time encodings, the modified approach outperforms the method in [1] for the same number of measurements. Compared to conventional amplitude-based sampling for FRI signals the proposed TEM-based method is less power consuming and hence, more cost effective.

Furthermore, as it was mentioned in the background, ADC are used also in neuromorphic-based hardware. Building neuromorphic computing systems usually requires the ability to efficiently emulate brain capabilities in hardware. Several types of neuro-mimetic devices were researched, but it still has been desirable to develop a compact device that can simulate spiking neurons.

In the conventional ADC system, the hardware cost and size increase with the sampling rate. To allow for low-rate sampling, the inventors again have considered using sub-Nyquist signal architectures, for FRI signals. Sub-Nyquist systems operate at lower sampling rates and hence can reduce the hardware cost and complexity.

Asynchronous ADCs (AADCs) present an alternative to conventional ADCs. An output sample is generated only when the signal characteristics change, resulting in considerable power and bandwidth savings. Since AADCs lack a global clock and a steady output data rate, they may outperform traditional clock-based ADCs and be used in the sub-Nyquist systems.

Time encoding, an event-driven approach, allows switching from acquiring the values of the observed signals to storing informative time. This is achieved by recording time instances in which a specific phenomenon is observed as the digital representation of the analog signal. As above, no global clock is then required; and the change in the sampling rate is signal dependent. Furthermore, compared to its amplitude-based homonyms, TEMs have simple and perhaps entirely analogue encoder stages that consume very little power and have smaller die sizes.

There is a similarity between how neurons encode information and TEM or IF-TEM. TEM-based systems that prioritize acquisition times are the basis of neuromorphic computing. In an effort to boost energy efficiency and resource requirements by orders of magnitude, neuromorphic computing seeks to create novel computational frameworks that mimic the brain's operation. The IF-TEM mechanism can be used to interpret the spike times of spiking neural networks (SNNs), leading to a better knowledge of how to utilize neuromorphic hardware and replace power hungry ADCs.

The inventors have prepared a hardware prototype demonstrating the applicability of efficiently emulating an integrate-and-fire (IF) neuron, that is have designed an ADC which encodes the data using an IF-TEM and allows the data to be obtained without using a global clock. Such time encoding hardware, mainly due to its asynchronous mechanism, has an advantage compared to traditional ADCs in that the circuit does not need to be synchronized to a global clock which entails high engineering and other costs. The inventors have implemented possibly the first sub-Nyquist time-based sampler using IF-TEM.

Also, the present disclosure relates to robust recovery of FRI signals. The inventors also have found that in practice, the IF-TEM circuit introduces noise into the signal, which can affect the time instances {tₙ}. Even in the absence of noise, it is only possible to determine time instances with limited precision. Hence, the IF-TEM hardware needs a robust nonlinear recovery technique.

The inventors have developed a robust reconstruction algorithm to recover the FRI parameters more accurately. The hardware prototype can accurately recover the FRI signals for FRI pulses with a minimum separation of 4 μs between them. The tested hardware and reconstruction method can recover the FRI parameters at up to −25 dB SNR while operating at 10-12 times less than the Nyquist rate. This novel reconstruction method is more noise-resistant than Algorithms 1 and 2 to the noise in the hardware-measured data.

Thus, in this disclosure, a robust reconstruction technique is introduced for the sub-Nyquist sampling technique disclosed above, as well as the first analog time-based hardware implementation of sub-Nyquist sampling of FRI signals. Prior to acquiring timing information with the IF-TEM, the signal is prefiltered using the sampling kernel. As above, the sampling kernel eliminates the zeroth frequency component of the signal for robust recovery. However, during recovery, in view of the noise in the hardware data, a different forward model with a T-periodic bandlimited function is utilized than in Algorithm 2: a partial summation is used so that the noise in each element of matrix C from Eq. (53) below is expected to be smaller than in matrix B of Eq. (29).

As for the FRI-TEM hardware prototype, it can be employed in low-power time-of-flight applications. It has been used to demonstrate the accurate reconstruction of FRI signals using the novel algorithm.

To this end, the hardware components have been designed or selected to accommodate a broad spectrum of FRI signal frequencies without modification, assuming a minimum separation of 4 μs between FRI pulses. The separation was assumed just based on the specific filter used, it could be reduced by choosing a different filter. In particular, before the IF-TEM sampler, a bandpass filter (BPF) has been utilized as the sampling kernel. The filter removes unnecessary information from the signal and allows sampling below the Nyquist rate. For robust recovery, the sampling kernel eliminates the signal's zeroth frequency component. The IF-TEM hardware generates a sequence of spike timings by sampling the filtered signal each time the threshold is reached. As an immediate, i.e., very quick, reset mechanism is desired, the inventors have built an integrator and a reset function in which the integrator's capacitor operates in its linear region and discharges rapidly and substantially fully. Then, it is possible to accurately recover the FRI parameters using sub-Nyquist samples using the novel robust reconstruction method. In particular, an example of the system functions at eight times the rate of innovation, which is significantly lower than the Nyquist rate of the signal.

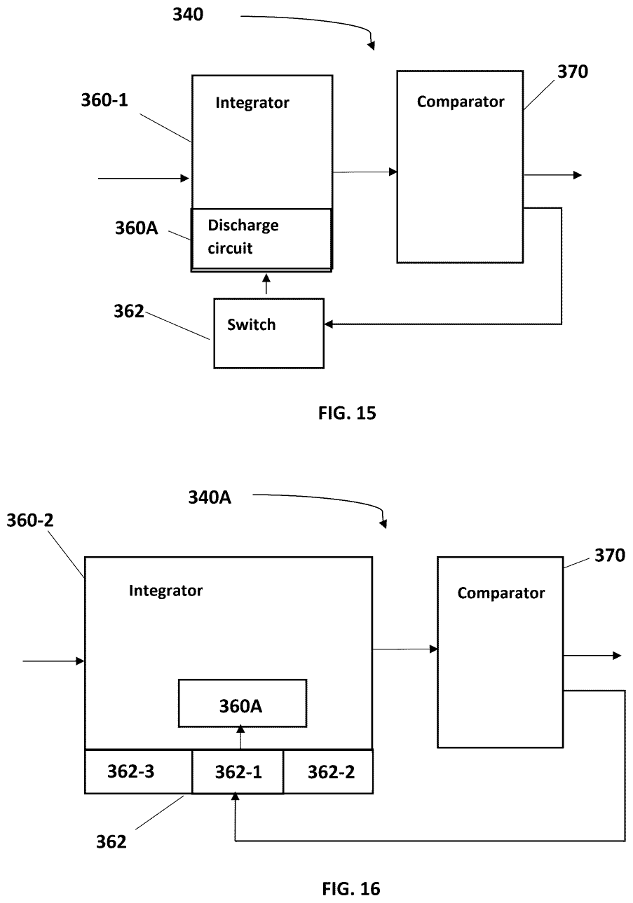

Referring to FIG. 15, it schematically shows an example of IF-TEM according to the present disclosure. IF-TEM 340 includes an integrator 360-1 with a discharge circuit 360A, a comparator 370, and a switch 362 (which in general may be a part of the integrator 360-1 or a component external to integrator 360-1). The switch 362 is positioned to receive a signal, transmitted from the comparator, for initiating reset of the integrator 360-1, and for switching on the discharge circuit 360A. The discharge circuit 360A includes a capacitor configured to operate in its linear zone to provide rapid and complete discharge of the integrator 360-1.

Referring to FIG. 16, it schematically shows another example of IF-TEM according to the present disclosure. IF-TEM 340A includes an integrator 360-2 with a discharge circuit 360A, a comparator 370, and a switch 362, which is positioned to receive a signal, transmitted from the comparator, for initiating reset of the integrator 360-2 and transmitted from the comparator 370, and to switch on the discharge circuit 360A.

In some examples, as in FIG. 16, the switch 362 includes at least three terminals, 362-1, 362-2, and 362-3, and is configured to receive a control signal for initiating reset of the integrator 360-2 at a first terminal 362-1, and to switch on the discharge circuit 360A by allowing a current flow between the second (362-2) and third (362-3) terminals.

The switch 362 may be presented by or include a FET. The first terminal 362-1 may be a gate of the FET.

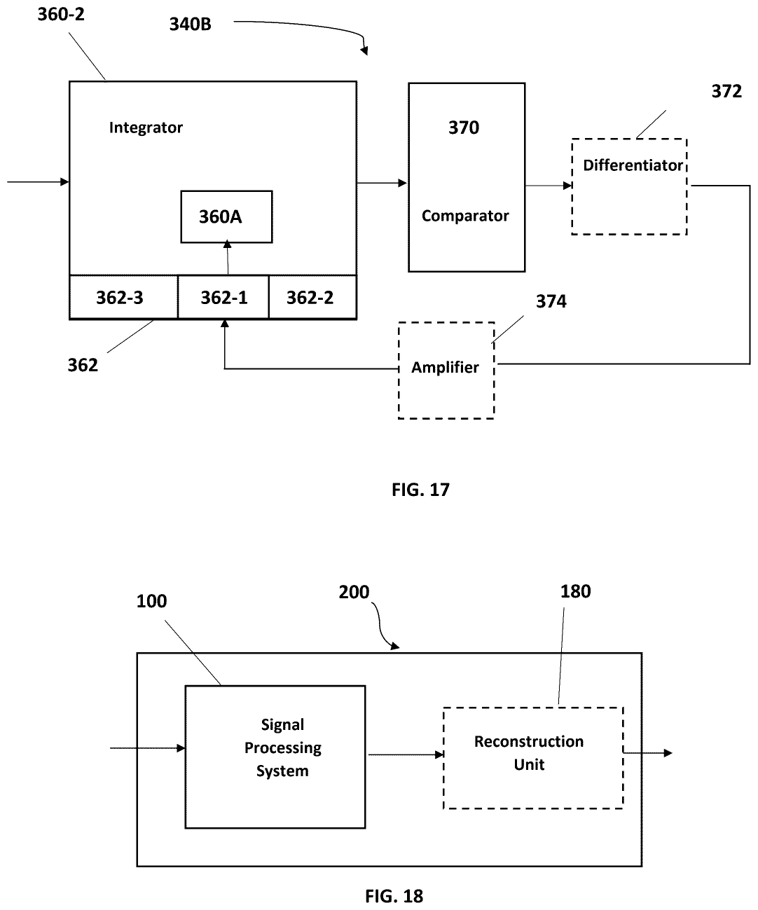

In a further example, schematically shown in FIG. 17, an IF-TEM 340B, according to the present disclosure, includes at least one of a differentiator 372 located on a path from the comparator 370 to the switch 362 and an amplifier 374 located on a path from the differentiator 372 and upstream of the switch 362. The differentiator 372, which is optional, generates spikes at time instances {tₙ}. The amplifier 374 allows matching the output of the differentiator 372 (or, when it is absent, the output of the comparator 370) with the switch 362 input and resetting through a discharge the integrator 360-2. The differentiator may be before the amplifier.

The discharge circuit 360A in any example or modification of the integrator 360-2 may include a resistor and a capacitor. An equivalent resistance of the discharge circuit may be selected in a range 1-10 kOhm and an equivalent capacitance of the discharge circuit 360A may be selected to make an RC parameter of the discharge circuit to be in a range 1-10 nF.

IF-TEMs of FIGS. 16 and 17 present examples also of IF-TEMs including a comparator 370 and a differentiator 372, positioned to receive a signal from an output of the comparator 370.

IF-TEMs of FIGS. 15 to 17 and their modifications may be used to implement IF-TEM 140 of FIG. 3A. Consequently, any of the sampling systems according to the present disclosure may be adapted to use the TEM as the IF-TEM described with reference to FIGS. 15 to 17. An ADC, for example the ADC 200 of FIG. 18, may include such a sampling system and a reconstruction system 180.

FIG. 18 schematically presents an ADC 200 including the signal processing system 100 according to any of the above examples. The ADC 200 may also include a reconstruction unit/system 180 (which may be configured as system 180A or 180B) for reconstructing a signal being a continuous time, finite rate of innovation signal sampled by the signal processing system 100 according to any of the above-described methods.

In general, the reconstruction unit 180 is configured as described above to receive and process the data indicative of the series of time-encodings provided by the signal processing system 100 (sampling system) to reconstruct the input signal by defining the linear relation between the vector representation y of the kernel-filtered signal and vector representation of the FSCs.

As exemplified above, this can be implemented by the configuration of the reconstruction system 180B (described above with reference to FIG. 3C) which creates the characteristic matrix C via performing the consecutive partial summations of discrete representations of the input signal, as described in detail above. The partial summations are derived from the series of time-encodings and at least three predetermined positive real numbers parametrizing the TEM of system 100 comprising: a bias b satisfying a condition c<b<∞ where c is a maximum real value of the input signal, a scaling factor x, and a threshold δ; to thereby provide noise-resilient reconstruction of the input signal.

The reconstruction unit 180 may include a hardware and may implement any one of Algorithm 1, Algorithm 2, or Algorithm 3 as described above, or another reconstruction or recovery algorithm.

In the following the above embodiments, examples and developments are further explained, based on some specific examples presenting at times further suitable, but optional features, as well as their combinations and sub-combinations, which all have to be considered as disclosed.

An unstable recovery occurred when Algorithm 2 described above, associated with matrix B (see Eq. (29) was utilized in the process of reconstructing the data from the hardware measurements. Therefore, a reconstruction strategy that is more robust to noise is desired.

Consider a T-periodic FRI signal of the form of Eq. (6) and a sampling mechanism as shown in FIG. 2A. The signal x(t) is passed through the sampling kernel g(t) as defined in Eq. (13) and the resulting signal y(t) is sampled using an IF-TEM. Both the time encodings

$${[ {t}_{n} \}}_{n = 1}^{N}$$

and the amplitude measurements

$${\{ {y}_{n} \}}_{n = 1}^{N}$$

correspond to a discrete representation of y(t)=(x*g)(t). In other words, {tₙ} encodes information of the FRI signal. As the objective is to create robust hardware, the FRI parameters

$${\{ {a}_{ℓ} , {τ}_{ℓ} \}}_{ℓ = 1}^{L}$$

need to be accurately estimated from the IF-TEM firings. To this end, together with the hardware implementation, a robust recovery algorithm is needed. In the following, the robust recovery mechanism of the present disclosure is introduced, that perfectly recovers the Fourier series coefficients [symbol] from IF-TEM observations in the absence of noise with as few as 4 L+2 pulses inside an interval T. Then, the resilience of this method is illustrated in the presence of noise and it is demonstrated that it outperforms Algorithm 2 described above.

The IF-TEM circuit can introduce noise into the signal, which in turn can perturbs the time instances {tₙ}. Even in the absence of noise, the time instances can only be determined with limited precision. The modeled jittered time instances are expressed as

$${t}_{n}^{′} = {t}_{n} + {ϵ}_{n} \qquad ( 47 )$$

where tₙ are the ideal time instances and

$${ϵ}_{n} {\sim}^{iid} 𝒰 [ - \frac{σ}{2} , \frac{σ}{2} ]$$

is the noise jitter. The hardware experiments performed by the inventors have shown that noise level σ fluctuates up to 70 ms. However, when an attempt was made to reconstruct FRI signals from IF-TEM measurements using the method presented above, inconsistent recovery was observed with hardware data. Therefore, in the following, the inventors propose a more noise-tolerant reconstruction method that addresses this limitation.

To assess the effectiveness of the new noise-tolerant reconstruction method, the inventors compare it with the approach presented above, under the presence of perturbations in the measured time instances. Both methods use a sample kernel without the zeroth frequency. However, while the method presented above employs the forward equation specified in Eq. (26), the new algorithm utilizes an alternative formulation introduced in Eq. (50) below.

In the following a method for determining the Fourier coefficients of the FRI signal that is more robust and improves recovery is presented. The recovery approach described above is based on computing the FSCs \hat{x} of the FRI signal x(t) using Eq. (30). In the case of noise, this leads to a perturbation in the measurements yₙ as well as the matrix B defined in Eq. (26) and Eq. (29), respectively. In this case, while computing the FSCs, the stability of B, which is measured by the condition number of the matrix, impacts the results. Next, it is shown that by utilizing a partial summation of yₙ, perfect recovery is achieved similarly to Theorem 2. In the noisy scenario, the resulting method is more robust. As is shown further below, when employing a partial summation of yₙ, a recovery problem similar to Eq. (30) is obtained, but with the matrix C defined in Eq. (53) replacing B. This matrix has a better condition number than B.

To gain intuition as to why this is the case, the inventors demonstrate that for every k∈ [symbol] , utilizing the partial summation for the measurements reduces the noise in each element of C by half compared to its corresponding element in B. This result is summarized in the following lemma.

Lemma 1. Let [B]ₙₖ=e^{jkω}₀tₙ₊₁-e^{jkω}₀tₙ be the entries of matrix B, where n=1, . . . , N−1, k∈ [symbol] . Let [C]ₙₖ=e^{jkω}₀tₙ₊₁ be the entries of matrix C, where n=1, . . . , N−1, k∈ [symbol] ∪{0}. The jittered time instances are modeled as

$${t}_{n}^{′} = {t}_{n} + {ϵ}_{n} ,$$

where to are the ideal time instances and the jitter noise is modeled as

$${ϵ}_{n} {\sim}^{iid} 𝒰 [ - \frac{σ}{2} , \frac{σ}{2} ] ,$$

i.i.d. uniformly distributed. For every [symbol] and k∈ [symbol] ,

$$var ( {[ B ]}_{n k} ) = 2 var ( {[ C ]}_{n k} ) , \qquad ( 48 )$$

where var is the variance.
Proof By utilizing the fact that

$${t}_{n}^{′} = {t}_{n} + {ϵ}_{n} ,$$

and using Eq. (29) and Eq. (53), it follows that,

$$\begin{matrix}var ( {[ B ]}_{n k} ) = ( {e}^{j k {ω}_{0} ( {t}_{n + 1} + {ϵ}_{n + 1} )} - {e}^{j k {ω}_{0} ( {t}_{n} + {ϵ}_{n} )} ) \\ = {\vert {e}^{j k {ω}_{0} {t}_{n + 1}} \vert}^{2} var ( {e}^{j k {ω}_{0} {ϵ}_{n + 1}} ) + \\ {\vert {e}^{j k {ω}_{0} {t}_{n}} \vert}^{2} var ( {e}^{j k {ω}_{0} {ϵ}_{n}} ) \\ = 2 var ( {e}^{j k {ω}_{0} {ϵ}_{n}} ) \\ = 2 var ( {[ C ]}_{n k} ) ,\end{matrix} \qquad ( 49 )$$

establishing the lemma.

It can be intuitively inferred that by utilizing the partial summation, the noise in each element of [C]ₙₖ becomes smaller than the corresponding noise in [B]ₙₖ. Consequently, the matrix C has a better condition number than B. This can be explained by the fact that the condition number of a matrix is a measure of the sensitivity of the matrix to small perturbations in its elements, and a smaller condition number indicates that the matrix is less sensitive to such perturbations. Therefore, by reducing the noise in the elements of C using the partial summation, the inventors improve its condition number.

In the next step, the inventors employ the partial summation of yₙ to present a perfect recovery guarantee for FRI signals by using IF-TEM. Instead of recovering the FSCs from yₙ through the forward model Eq. (26) with [symbol] in Eq. (16), which defines the relation between yₙ and the FSCs \hat{x}[k], the inventors propose an alternative model that is based on zₙ. These are the partial sums of the measurements yₙ defined as

$${z}_{n} = {\sum }_{i = 1}^{n - 1} {y}_{i} = {\sum }_{k ∈ 𝒦} \frac{\hat{x} [ k ]}{j k {ω}_{0}} ( {e}^{j k {ω}_{0} {t}_{n}} - {e}^{j k {ω}_{0} {t}_{1}} ) , \qquad ( 50 )$$

where n=2, . . . , N. Note that (20) can be written as

$${z}_{n} = {\sum }_{k ∈ 𝒦} \frac{\hat{x} [ k ]}{j k {ω}_{0}} {e}^{j k {ω}_{0} {t}_{n}} + c \qquad ( 51 )$$

$$c = - {\sum }_{k ∈ 𝒦} \frac{\hat{x} [ k ]}{j k {ω}_{0}} {e}^{j k {ω}_{0} {t}_{1}} . \qquad ( 52 )$$

Let z=[z₂, . . . , Z_{N}]^{T}∈ [symbol] ^{N-1} be the vector of partial sums,

$$\hat{z} = {[ - \frac{\hat{x} [ - K ]}{j K {ω}_{0}} , ⋯ , - \frac{\hat{x} [ - 1 ]}{j {ω}_{0}} , c , \frac{\hat{x} [ 1 ]}{j {ω}_{0}} , ⋯ , \frac{\hat{x} [ K ]}{j K {ω}_{0}} ]}^{T} ∈ {ℂ}^{( 2 K + 1 )}$$

be the vector of FSCs with c in the zeroth place, and C∈ [symbol] ^{(N-1)×(2K+1)} be the matrix defined as

$$C = [ \begin{matrix}{e}^{- jK {ω}_{0} {t}_{2}} & ⋯ 1 ⋯ & {e}^{jK {ω}_{0} {t}_{2}} \\ {e}^{- jK {ω}_{0} {t}_{3}} & ⋯ 1 ⋯ & {e}^{jK {ω}_{0} {t}_{3}} \\ ⋮ & ⋱ & ⋮ \\ {e}^{- jK {ω}_{0} {t}_{N}} & ⋯ 1 ⋯ & {e}^{jK {ω}_{0} {t}_{N}}\end{matrix} ] \qquad ( 53 )$$

Then, Eq. (51) can be expressed in matrix form as follows:

$$z = C \hat{z} . \qquad ( 54 )$$

Since the set of time instants

$${\{ {t}_{n} \}}_{n = 2}^{N}$$

are distinct, and C is a Vandermonde matrix, it has full column rank provided that N−1≥2K+1. This means that the matrix C has linearly independent columns. Therefore, the vector of FSCs \hat{z} can be perfectly recovered via

$$\hat{z} = {C}^{†} z \qquad ( 55 )$$

where C^{†} denotes the Moore-Penrose inverse of C. Once \hat{z} is obtained, the FSCs \hat{x}[k] can be uniquely determined. Using

$$\hat{z} [ k ] = \{ \begin{matrix}\frac{\hat{x} [ k ]}{j {ω}_{0} k} , & if k ∈ 𝒦 , \\ - {\sum }_{{k}^{′} ∈ 𝒦} ( \frac{\hat{x} [ {k}^{′} ]}{j {k}^{′} {ω}_{0}} ) {e}^{{jk}^{′} {ω}_{0} {t}_{1}} & if k = 0\end{matrix} . \qquad ( 56 )$$

The vector of FSCs z and the vector of FSCs \hat{x} are related y:

$$\hat{x} = {[ \hat{z} [ - K ] , … , \hat{z} [ - 1 ] , \hat{z} [ 1 ] , … , \hat{z} [ K ] ]}^{T} ∈ {ℂ}^{2 K} . \qquad ( 57 )$$

This equation allows one to obtain \hat{x} by selecting the appropriate elements of \hat{z}, which is the vector obtained from the partial sums of the measurements. Note that the resulting vector \hat{x} has dimensions 2K, which implies that it only contains the FSCs for positive and negative frequencies.

Using the vector \hat{z} and Eq. (57), the vector of FSCs \hat{x} is uniquely determined. This indicates that, in the modified kernel setup, without zero frequency, the set of FSCs \hat{x}[k] can be uniquely determined from time encodings if N−1≥2K+1. This condition implies that there should be a minimum of 2K+2 firing instants within an interval T. For an IF-TEM, the minimum firing rate is given as

$$\frac{b - c}{κδ}$$

(see e.g., Eq. (5). Hence, for uniqueness recovery, the IF-TEM parameters must satisfy the inequality

$$\frac{b - c}{κδ} \geq \frac{2 K + 2}{T} .$$

A reconstruction algorithm to compute the FRI parameters from IF-TEM firings is presented in Algorithm 3. Compared to the technique presented above, the method described here requires the same number of FSCs in the absence of noise. However, in the presence of noise, as is typically the case in real-world hardware, the proposed approach yields a lower error for the same number of measurements.

Algorithm 3: Reconstruction of a T-periodic FRI signal.

$Input : N \geq 2 K + 2 spike times {\{ {t}_{n} \}}_{n = 1}^{N} in a period T .$

| | |
|---|---|
| 1. | 1: Let n ← 1 |
| 2. | while n ≤ N − 1 do |
| 3. | Compute yₙ = − b(tₙ₊₁ − tₙ) + κδ |
| 4. | $Compute {z}_{n + 1} = {Σ}_{i = 1}^{n} {y}_{i}$ |
| 5. | n := n + 1. |
| 6. | end while |
| 7. | Compute the vector \hat{z} = C^{†}z, where C is defined in Eq. (53). |
| 8. | Compute the Fourier coefficients vector \hat{x} from \hat{z} using Eq. (57). |
| 9. | $Estimate {\{ ( {a}_{ℓ} , {τ}_{ℓ} ) \}}_{ℓ = 1}^{L} using a spectral analysis method for K \geq 2 L .$ |

$Output : {\{ ( {a}_{ℓ} , {τ}_{ℓ} ) \}}_{ℓ = 1}^{L} .$

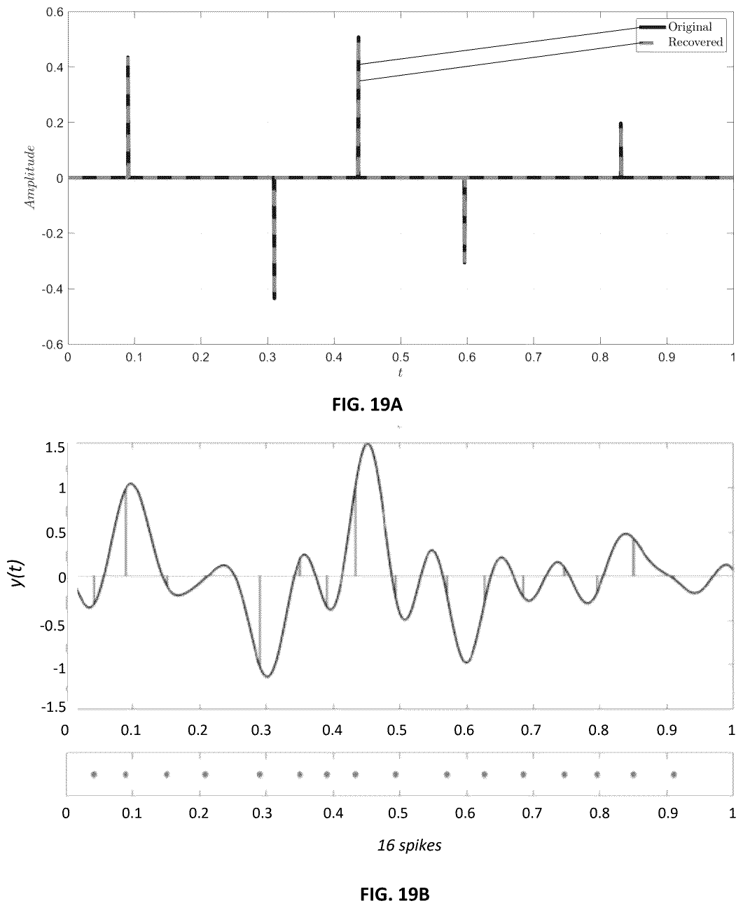

In this section, the inventors provide numerical evidence of the validity of Algorithm 3 through simulations. It is also shown that the proposed reconstruction technique improves the conditioning of the forward transformation, leading to a significant reconstruction improvement necessary for precise recovery using real hardware. To validate Theorem 4, the inventors consider h(t) as a Dirac impulse with a time period of T=1 second, and L=5. The amplitudes are selected randomly over the range [−1,1]. The time delays are chosen randomly between (0,1) such that they lie on a grid with a resolution of 0.05. The input signal x(t) is filtered using an SoS sampling kernel with [symbol] =−K, . . . −1,1, . . . , K, where K=L. The filtered output y(t) is sampled using an IF-TEM where the IF-TEM parameters are chosen to satisfy the inequality Eq. (24). In this particular case, the IF-TEM sampler resulted in 16 firing instants in one time period, as shown in FIG. 19B. It can be seen in FIG. 19A that the inventors achieve perfect recovery of the FRI signal by using a kernel without zero frequency.

As the IF-TEM circuit produces noise that perturbs the time instances tₙ, the jittered time instances:

$${t}_{n}^{′} = {t}_{n} + {ϵ}_{n}$$

are considered, as defined in Eq. (47). The inventors compare the proposed recovery method with the reconstruction algorithm described in above (Algorithm 2) in the presence of perturbations to the measured time instances. Each approach employs a sample kernel lacking a zeroth frequency. While the reconstruction approach proposed in Algorithm 2 uses the forward method defined in Eq. (26), the method described here uses a different forward method defined in Eq. (50).

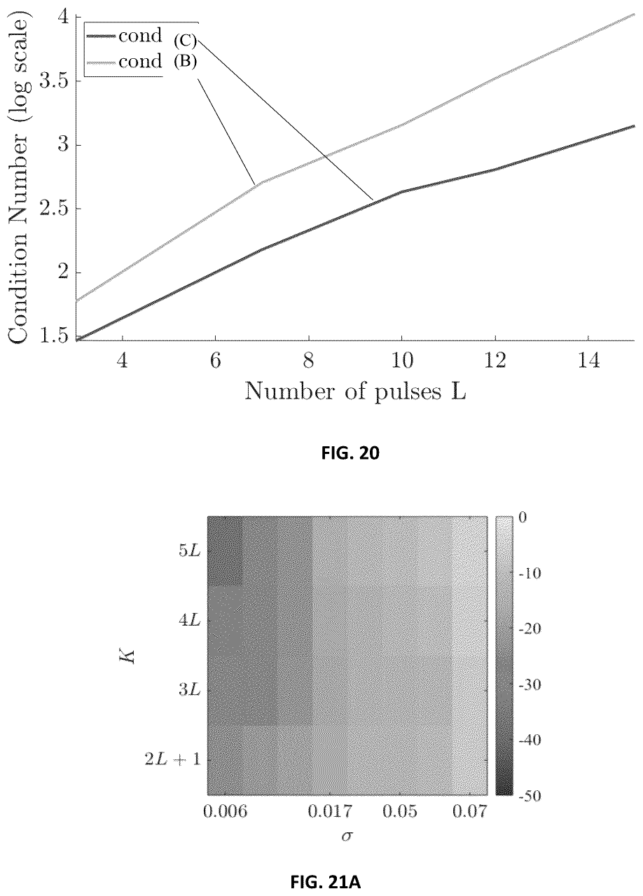

The inventors use the forward operators or matrices B and C (see Eq. (28) and Eq. (54)) to recover the FRI signals in each of the previously discussed methods. The matrices B and C are functions of the measured time instants and sampling kernel. In FIG. 20, the condition numbers of matrices with the same number of 4 L+2 perturbed firing instants are compared as a function of the number of FRI signals L. To this aim, 5000 random sets of monotonic sequences

$${{t}_{n} ∈ [ 0 , T )}_{n = 1}^{N}$$

were generated. As depicted in FIG. 20, the condition number of matrix C is smaller than that of matrix B. This demonstrates that the reconstruction algorithm (Algorithm 3) enhances stability and noise resilience.

The inventors have evaluated and compared the relative mean square error (MSE) in the estimation of time delays performance for the reconstruction accuracy of the presented algorithm (Algorithm 3) with Algorithm 2 presented above, where the MSE is given by

$$M S E = 10 log ( {\sum }_{ℓ = 1}^{L} {( {τ}_{ℓ} - {\hat{τ}}_{ℓ} )}^{2} ) , \qquad ( 58 )$$

where [symbol] is the estimated time delay. Specifically, the signal x(t) as in Eq. (6) has been considered, with period T 1 seconds consisting of L=3 pulses with h(t) as a third-order cubic B-spline. The off-grid time-delays

$${\{ {τ}_{ℓ} \}}_{ℓ = 1}^{3}$$

and amplitudes

$${\{ {a}_{ℓ} \}}_{ℓ = 1}^{3}$$

are generated at random over intervals (0, T] and [1,5], respectively. The IF-TEM parameters are κ=1, b=2.5c where c=maxₜ|y(t)|, and δ is chosen to satisfy Eq. (24). The inventors have considered a sum-of-sincs kernel with [symbol] ={−K, . . . , −1,1 . . . , K} for the calculation of the Fourier coefficients \hat{x}[k]. The time instance {tₙ} were perturbed as

$${t}_{n}^{′} = {t}_{n} + {ϵ}_{n}$$

where tₙ is the actual time encoding and ∈ₙ is a random variable uniformly distributed over [−σ/2, σ/2]. The inventors have used an annihilating filter with Cadzow denoising to estimate the time-delays in the presence of noise. Since Cadzow denoising requires more than 2 L consecutive samples of FSCs, the inventors have considered K≥2 L+1 while excluding the zero. Based on the fact that the proposed recovery where 0∉ [symbol] estimates

$${\{ \hat{x} [ k ] \}}_{k = - K}^{- 1} and {\{ \hat{x} [ k ] \}}_{k = 1}^{K} ,$$

the inventors have applied Cadzow denoising on each of these sequences independently and then applied block annihilation to determine the time-delays jointly.

The MSEs in the estimation of time-delays for different numbers of FSCs and perturbation levels are shown in FIGS. 21A and 21B which present a comparison of approaches in Algorithm 2 and Algorithm 3 for off-grid time delays with perturbation in the time encodings. The inventors have used 500 independent noise and FRI signal realizations to compute each MSE value. In FIGS. 21A and 21B the inventors have shown MSEs for Algorithm 2 and Algorithm 3, both without zero in the sampling kernel, for K=2 L+1 up to 5 L. The inventors have observed that comparing the approaches, there appeared a gain of up to 10 dB. Since perturbation in the time encoding is also equivalent to quantization noise, a lower MSE indicates that the approach of Algorithm 3 can operate at lower bits compared to Algorithm 2 and thus leads to robustness.

In the following FRI-TEM hardware prototype specifications, followed by the circuit parameters, are described.

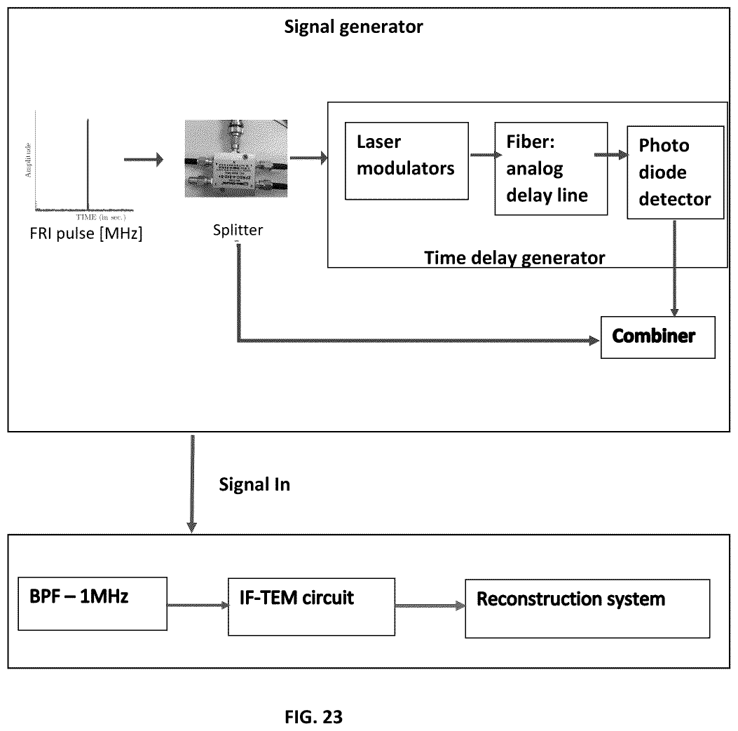

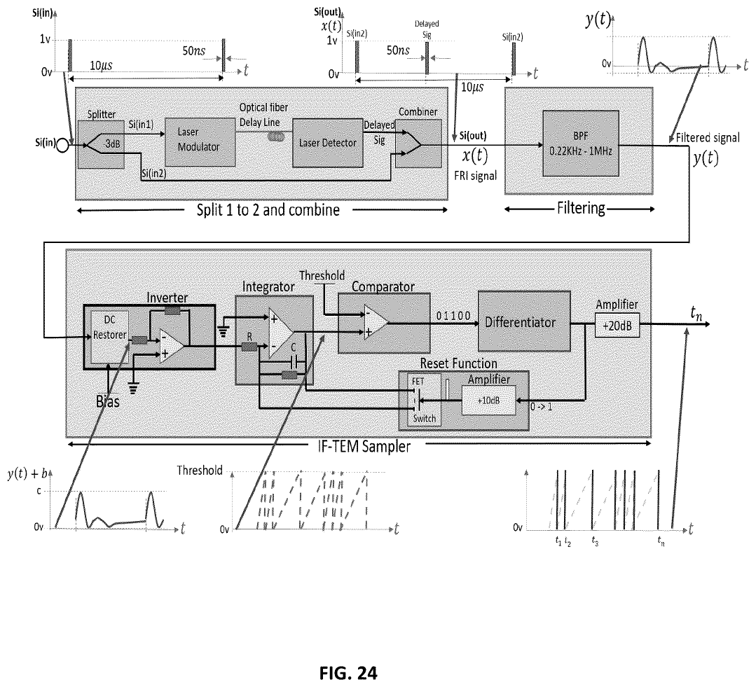

First, the components of the FRI-TEM hardware implementation, as well as various circuit design aspects are discussed. As shown in FIGS. 23 and 24, the analog board comprises three sequential stages: the generation of a FRI signal, band-pass filtering, and an IF-TEM sampler.

The FRI signal production technique is analog, which is renowned for introducing low digital noise and simulating real-world applications such as radar and ultrasound more accurately. The process of signal production involves several components working together to generate and process a signal. One possible configuration for a signal generator is a scope, a splitter, an analog delay generator, and a passive radio frequency (RF) combiner. Specifically, the scope generates an FRI pulse (10-500 ns wide), that is transmitted through the splitter. The splitter receives the pulse and sends it to both the delay generator and the combiner (see FIG. 23). The delay generator comprises a fiber optic cable, a photodiode encoder, and a photo-diode detector. Encoding the signal with the photodiode encoder is the initial step of the delay generator. The signal then travels through the fiber optic line, causing a delay of at least 4 μs. The significance of the fiber optic delay implementation originates from its known benefits, such as the introduction of low digital noise, which more accurately simulates practical applications; however, another signal generator may be used. In order to decode the delayed input signal, a photo-diode detector is used to transform the signal into an analog electric signal with the same frequency as the original FRI input pulse. In FIG. 23, for example, the FRI signal x(t) Eq. (6) consists of two 20 MHz pulses separated by a relative delay of 4 μs. The output of the combiner, x(t), is then sent as input to the sampling kernel.

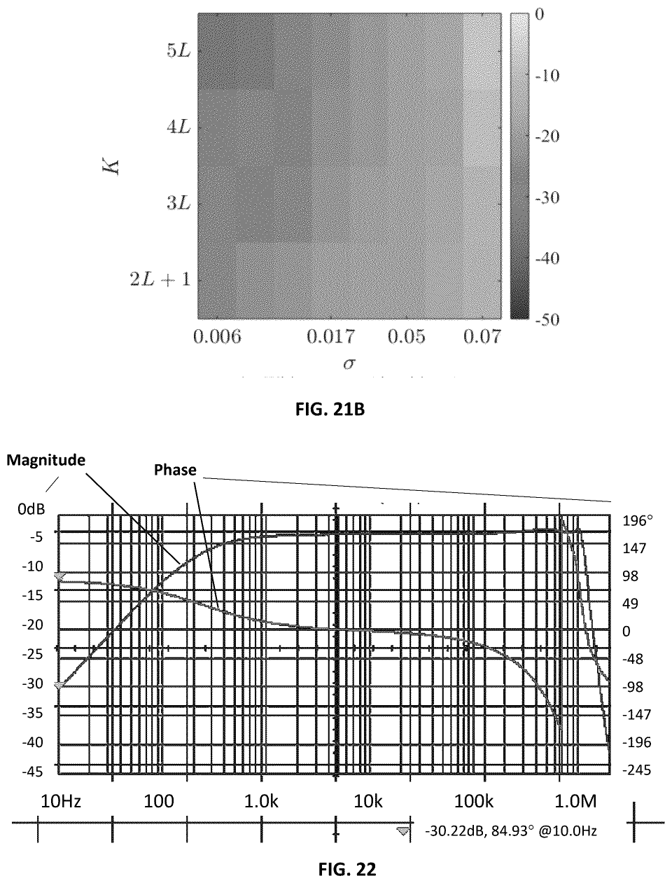

The filter, also known as the sampling kernel, removes the zeroth frequency component. FIG. 22 shows a 1 MHz filter Bode plot. The sampling kernel removes the zeroth frequency, and the magnitude (in blue) and phase (in red) are plotted on a logarithmic frequency scale). It can be seen that if the frequency of the signal is 10 Hz, the magnitude of the zeroth frequency component is suppressed to −30 dB. The positioning of the sampling kernel, which in this case is presented by a band-pass filter (BPF), is tailored for the sub-Nyquist sampling and reconstruction of FRI signals with an IF-TEM. Theoretically, 0.4 MHz is the minimum sampling rate required to recover two FRI pulses in a period of 10 μs. To facilitate such a fast reconstruction, a 1 MHz filter was chosen. Here, an eight-order 1 MHz BPF is employed, enabling a suitable trade-off between energy usage and reconstruction performance.

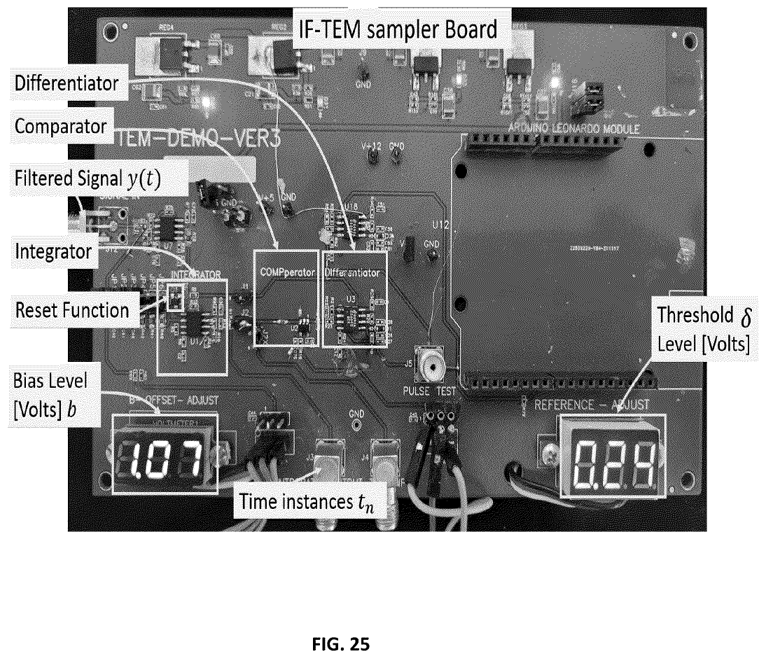

The filter output, y(t) (Eq. (15 is then transmitted to the IF-TEM sampler. The block diagram of the IF-TEM circuit is presented in FIG. 24, and Table 2 lists the specific components of the IF-TEM circuit. A prototype of the IFTEM sampler is shown in FIG. 25.

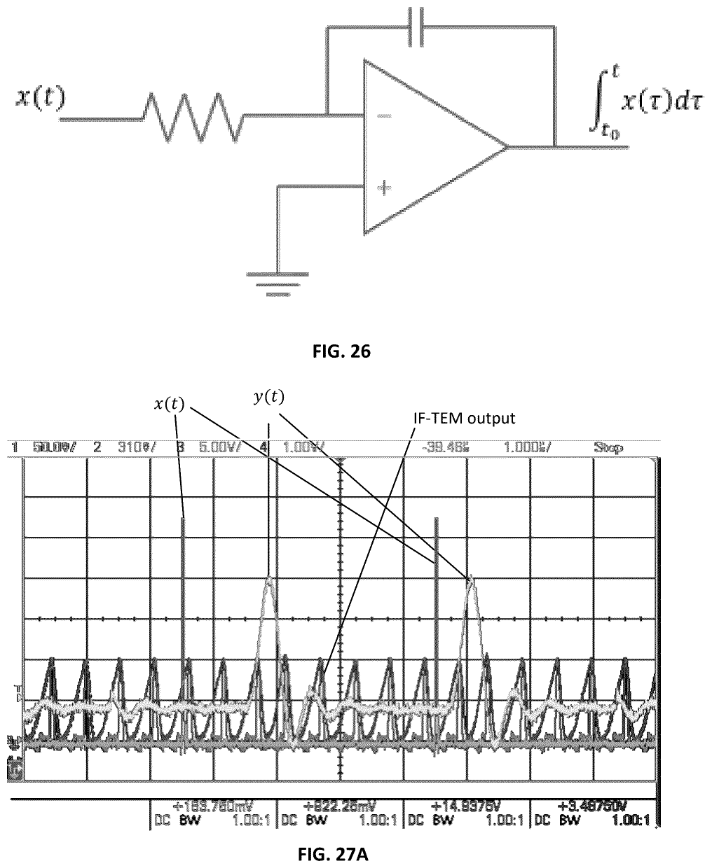

The primary IF-TEM components in these specific tests included the bias b, integrator, comparator, differentiator, and reset function. An example of an integrator circuit is schematically shown in FIG. 26. The hardware implementation of the integrator is comprised of an operational amplifier, a capacitor C and resistors R₁ and R₂. The integrator constant κ is determined from the integrator circuit hardware implementation as demonstrated in FIG. 26.

To guarantee sufficient samples for reconstruction, the inventors ensured that the δ threshold is achieved at least as many times as the desired sample amount. By adding the bias b to the input y(t), the integrator obtains a signal that is always not negative. In this case, integration over a non-negative signal is a positive function, and the threshold is always attained. For an FRI signal x(t) with L pulses, it can be shown that the sampler input filtered signal y(t) is also constrained as in Eq. (18):

$$\vert y ( t ) \vert \leq c = {La}_{max} {‖ g ‖}_{∞} {‖ h ‖}_{1} , \qquad ( 59 )$$

where g and h are the known filer and pulse shape, respectively. Consequently, the bias b>c, which is effectively a constant DC voltage, is selected manually using a potentiometer.

The output of the integrator is sent to the comparator, which compares the integrator voltage to a predefined threshold δ. The threshold is a constant DC voltage that is implemented in the hardware utilizing a potentiometer that is manually regulated and adjustable. The comparator is responsible for comparing the voltage produced by the integrator to a predefined threshold value. When the integrator voltage reaches or exceeds the threshold, the comparator's logical value changes. When the comparator's input is below the threshold, it outputs ‘0’, and when it is above the threshold, it outputs ‘1’. Thus, the comparator produces a sequence of logical ‘1’ values when the integrator voltage hits the threshold. This change in the comparator's output signal indicates that the threshold has been reached and triggers the next stage in the IF-TEM process.

The output of the comparator is provided to the differentiator, which generates a short pulse that activates the fast reset function and enables the capture of the time instances tₙ. The reset function consists of an amplifier and a FET in order to discharge the integrator capacitor quickly and completely. In greater detail, the FET functions as a switch, and is controlled by the pulse produced by the differentiator, which determines the duration of time that the FET is active. This allows the integrator capacitor to be fully discharged. The FET has three terminals: source, gate, and drain. By providing a voltage of ‘1’ to the gate terminal, FETs modify the conductivity between the drain and source terminals to regulate current flow. This results in a rapid and complete discharge of the integrator capacitor.

TABLE 2

| Device | Reference | Manufacturer |
|---|---|---|
| Buffer | AD899 | Mini-Circuits |
| Integrator | LT1364 | Analog Devices |
| Comparator | TLV3201 | Texas Instruments |
| Differentiator | LT1364 | Analog Devices |

To implement an IF-TEM circuit, an integrator operating according to Eq. (2) is employed. Specifically, it is desirable that the integrator capacitor operates in its linear domain, which is continuously charged or rising, as long as the input signal is positive. In addition, it is desirable for the IF-TEM thresholding to have a quick reset mechanism. Consequently, the inventors have sought to develop an integrator and reset function in which the capacitor of the integrator operates in its linear zone and discharges rapidly and completely (or substantially completely). The inventors succeeded in selecting parameters and implementing IF-TEM integrator capacitor supporting a wide range of input signals without circuit modification. By utilizing the differentiator and a FET in the reset function, both the entire discharge and rapid discharge of the capacitor are accomplished for a variety of FRI signals. In the following, results using the hardware of the present disclosure are provided and compared to the theoretical result from Theorem 4.

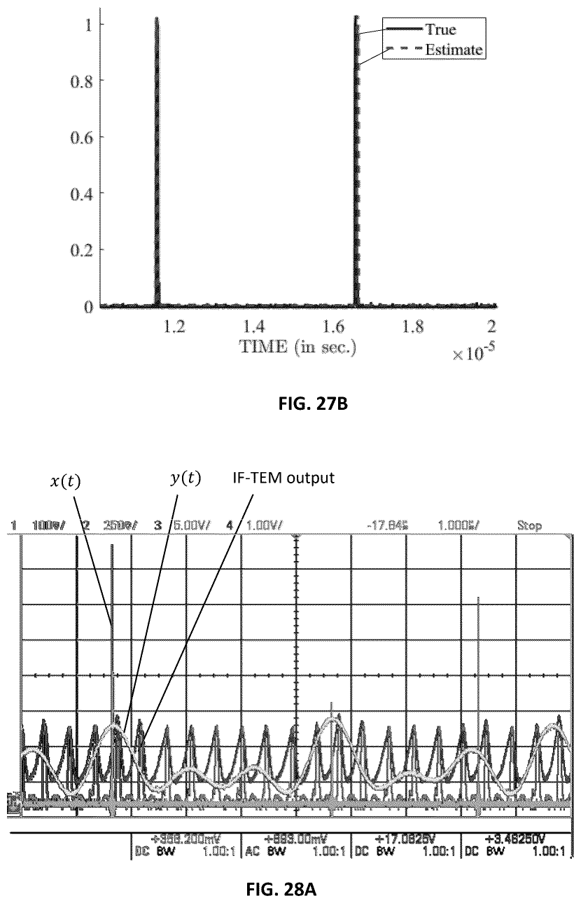

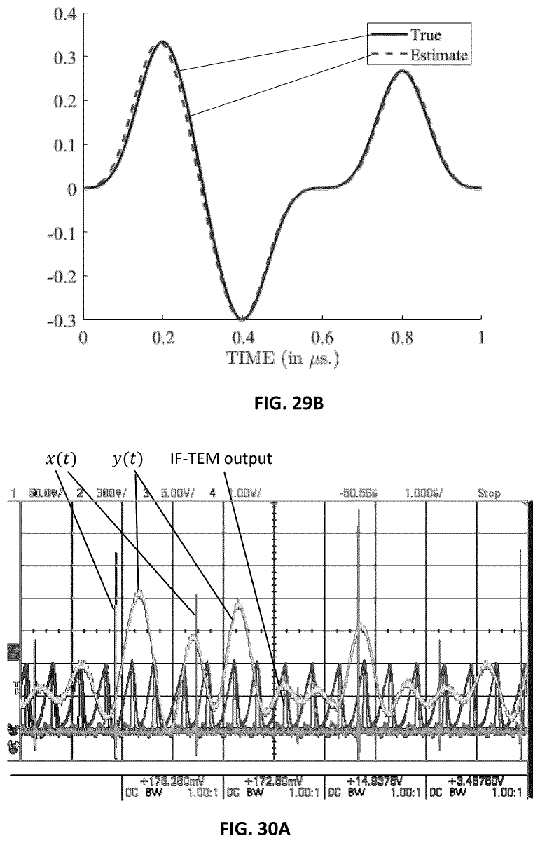

The inventors have first conducted measurements on their designed FRI-TEM hardware system to evaluate the potential and feasibility of the system. Reference is made to FIGS. 27A and 27B, wherein FIG. 27A shows the FRI input signal x(t) (yellow), BPF output y(t) (green), and the IF-TEM output resulting in 19 samples (blue); and FIG. 29B shows the results of sampling and reconstruction using IF-TEM hardware (the input signal x(t) (blue) and its reconstruction (red)). As shown in FIG. 27A, an FRI input signal x(t) consisted of two 100 ns wide pulses with a delay of 5 μs between them. The sampling kernel as discussed above was used. The IF-TEM circuit parameters were set to a value of κ=3·10⁻⁸, with a bias of b=3V and threshold was 8=1.5 V. The specific time delays and amplitudes used in this input signal were chosen arbitrarily and the IF-TEM parameters were selected to adhere to the constraints outlined in Eq. (32). As demonstrated in FIG. 27A, the filtered signal y(t) was transmitted to an IF-TEM sampler, which produced 19 time instances tₙ, resulting in a firing rate of 1.9 MHz, which is 4.75 times the rate of innovation and nearly 11 times lower than the Nyquist rate. Note that at least 4 L+2=10 time instances are needed for off-grid reconstruction. The original input and the estimated signal are shown in FIG. 27B. The close fit between the input and reconstructed signals demonstrates that the parameters of the FRI system can be robustly estimated while operating at a rate that is 10 times lower than the Nyquist rate.

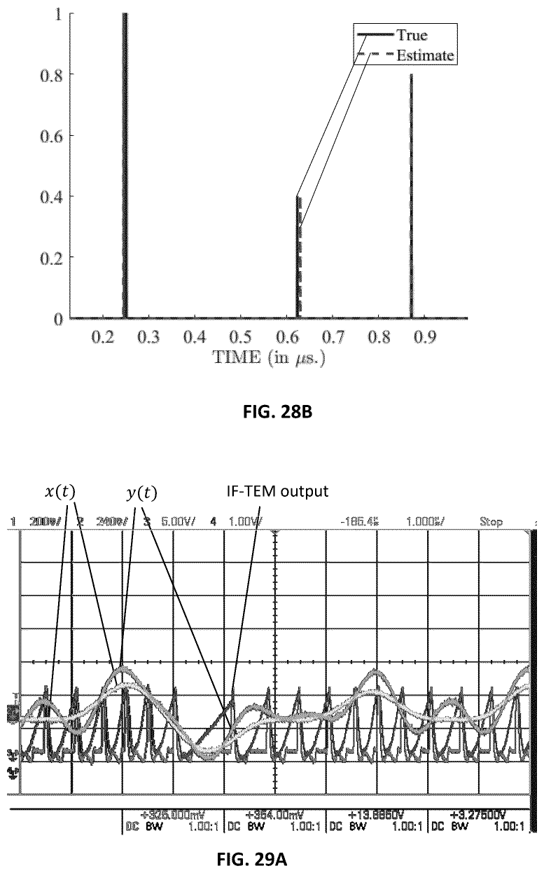

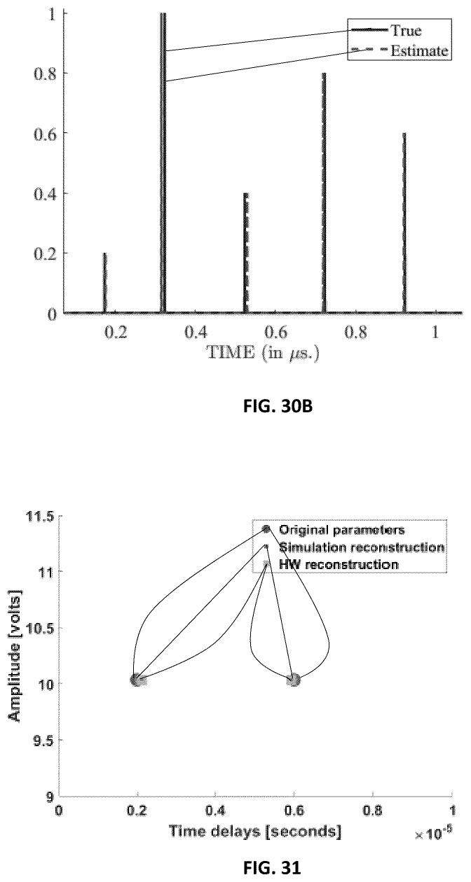

FIGS. 28A-28B, FIGS. 29A-29B, and FIG. 30A-30B, demonstrate sampling and reconstruction of FRI signals with L=3,5 for h(t) as a Dirac impulse and stream of pulses. In FIGS. 28A, 29A, and 30A the FRI signal is represented by the green curve, the filtered signal y(t) is shown in yellow, and the time instances tₙ produced by the IF-TEM sampler are depicted in blue. In each of these figures, the number of time instances produced is 19, 21, and 22, respectively, resulting in firing rates of 1.9 MHz, 2.1 MHz, and 2.2 MHz, which are all between 9.5 and 10.5 times lower than the Nyquist rate. The reconstructed FRI signals are shown in FIGS. 28B, 29B, and 30B. The maximum error in time delay estimation is −25 dB. These results indicate that the proposed sampling and reconstruction method is suitable for use in radar and ultrasonic imaging applications.

FIG. 31 shows a comparison between the reconstruction using the hardware measurements and the simulation for the amplitudes and time delays of the FRI signals with two pulses. This comparison is used to evaluate the performance of the proposed hardware prototype and reconstruction method by comparing the results obtained from the hardware measurements with those obtained from the simulation. The evaluation involves calculating the error between the reconstructed signals obtained from the hardware and simulation, as well as comparing the estimated FRI parameters. This comparison provides insight into the accuracy and reliability of the hardware and reconstruction approach. The error in the estimation of the time delay is found to be −25 dB, and this result is consistent with the findings when using L=3 or L=5 pulses.

Overall, the inventors demonstrated FRI signal recovery using an IF-TEM sampler and disclosed a hardware prototype of a sub-Nyquist IF-TEM ADC. A robust reconstruction approach was created to accurately retrieve the FRI parameters. In contrast to conventional ADCs, the tested prototype is an asynchronous energy-efficient ADC that estimates parameters using a sub-Nyquist framework. The system of the inventors can accurately recover FRI signals assuming a minimum interval of 4 μs between FRI pulses. The proposed hardware and reconstruction method retrieve the FRI parameters while operating at 10-12 times lower than the Nyquist rate with an SNR of up to −25 dB.

Heart rate monitoring (HRM) based on electrocardiogram (ECG) is an important diagnostic technique for numerous cardiovascular conditions. To provide continuous, portable HRM, and rapid data transfer for instantaneous intervention, wireless technology is necessary, with limitations on system power, bandwidth, and resolution. Recent studies have demonstrated that ECG signals can be modeled as variable pulse width finite rate of innovation (VPW-FRI). The inventors developed a time-based VPW-FRI framework, using the power-efficient integrate-and-fire time encoding machine (IF-TEM) sampler of the present disclosure. A novel method for time-based sub-Nyquist sampling and reconstruction of ECG signals is introduced in the following, with application to HRM. Unlike standard sampling systems, the TEM-based sampler of the present disclosure is asynchronous and does not require a power-consuming clock. Therefore, it can be exploited for medical applications, such as an energy-efficient pacemaker that may consume less space and power than conventional devices.

The World Health Organization estimates that heart disease is the world's leading cause of death, responsible for 16% of total deaths worldwide. Despite the possibility of preventing a high percentage of heart diseases, the present prevention efforts are insufficient. It is therefore crucial to warn patients of potentially life-threatening cardiovascular symptoms as soon as possible. In an era where ECG and heart rate monitoring (HRM) are key to detecting and treating fatal cardiovascular signs, the need for a personalized and customized device for HIRM is vital. Such devices must use batteries with long service duration, and low power consumption.

Analog to digital converters (ADCs) play a key role in these devices. They convert the signals into samples which are then transmitted and processed for signal monitoring. There are two basic classes of ADCs: synchronous and asynchronous, where the former is the most prevalent. There are several drawbacks to synchronous ADCs, including the use of a global clock, which increases power consumption and device size. Other problems include clock skew, metastable behavior, and electromagnetic interference. Asynchronous ADCs, such as the one described in the present disclosure, lack a global clock and a constant output data rate, resulting in substantial power and bandwidth savings.

As described in detail above, the Integrate-and-fire time encoding machine (IF-TEM) operates asynchronously and does not require a global clock. An analog signal is first integrated and compared with a threshold, and whenever the threshold is crossed, the time instances recorded encode the information contained in the analog signal. The IF-TEM's ability to capture informative time instances when neurons encode information with time, rather than merely over time, can be instrumental in comprehending their functioning and constraints. The IFTEM's low-power, high-resolution, and compact ADC also makes it a promising tool for developing and utilizing neuromorphic hardware. Moreover, the IF-TEM's ADC has the potential to be applied to continuous, ambulatory long-term monitoring.

The authors in [4] demonstrated the sampling and accurate reconstruction of Lorentzian pulses with variable width, applied their method to ECG compression, and sampled the signal at the Nyquist rate before compressing it. The authors in [5] extended upon the variable pulse width (VPW) model proposed in [4] by modeling the ECG signal with the differentiated VPW model to reduce the model mismatch error. For ECG signals, they proposed a sub-Nyquist sampling and reconstruction approach. However, as their method relies on signal differentiation, it is not noise-resistant.

In this disclosure, the inventors introduce a robust time-based sub-Nyquist sampling and recovery algorithm of an analog ECG signal utilizing an IF-TEM ADC. To the best of inventors' knowledge, this is the first work to utilize an energy-efficient IF-TEM ADC for ECG sampling and reconstruction at a sub-Nyquist rate which is only twice the minimal theoretical rate. The inventors employ a sampling kernel with enhanced noise resilience and apply a signal reconstruction method in the frequency domain, based on the techniques described above. The method is applied to HIRM which is calculated from the recovered ECG signal, showing high accuracy results with respect to (w.r.t.) known HIRM evaluation using synchronous ADCs, and compared to [4] and [5]. Explicitly, the considered sampling rate is only twice higher than the minimal theoretical rate [4], and 66.66 times less than the Nyquist rate of 2000 Hz synchronous ADC [6]. The method of the disclosure demonstrates higher precision for HIRM as a result of enhanced ECG reconstruction when compared to other ECG reconstruction techniques proposed by [4] and [5] using several statistical metrics.

The inventors consider an ECG signal which is presented by a T-periodic VPW-FRI signal of the form [4]:

$$x ( t ) = {\sum }_{l = 0}^{L - 1} {x}_{l} ( t ) , where , {x}_{l} ( t ) = {x}_{l}^{s} ( t ) + {x}_{l}^{a} ( t ) , \qquad ( 60 )$$

$${x}_{l}^{s} ( t ) = {c}_{l} {\sum }_{p ∈ ℤ} \frac{{r}_{l}}{π ( {r}_{l}^{2} + {( t - {t}_{l} - pT )}^{2} )} , \qquad ( 61 )$$

$${x}_{l}^{a} ( t ) = {d}_{l} {\sum }_{p ∈ ℤ} \frac{t - {t}_{l} - pT}{π ( {r}_{l}^{2} + {( t - {t}_{l} - pT )}^{2} )} . \qquad ( 62 )$$

The signal components

$${x}_{l}^{s} ( t ) , {x}_{l}^{a} ( t )$$

are the symmetric and antisymmetric parts of the pulse, respectively. To sample x(t) at a sub-Nyquist rate, the inventors first pass it through a designed sampling kernel g(t) and then measure low-rate samples of the filtered signal y(t). The kernel should be designed such that the VPW-FRI parameters

$${\{ {t}_{l} , {r}_{l} , {c}_{l} , {d}_{l} \}}_{l = 0}^{L - 1}$$

can be computed accurately from the IF-TEM samples. In particular, it has been shown that using a classical clock-based uniform sampler, 4 L+1 samples of x(t) in an interval T are sufficient to determine uniquely [4]. The inventors consider the problem of perfect recovery of the ECG signal's parameters

$${\{ {t}_{l} , {r}_{l} , {c}_{l} , {d}_{l} \}}_{l = 0}^{L - 1}$$

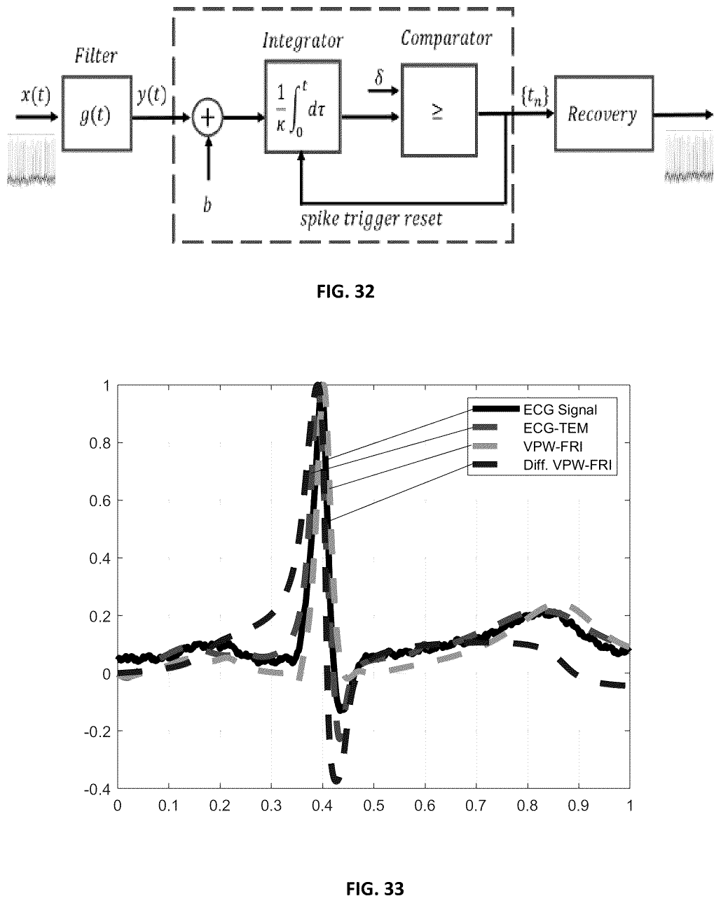

using an IF-TEM sampling scheme as shown in FIG. 32. Specifically, the inventors consider designing the sampling kernel g(t) and an IF-TEM with parameters {b, κ, δ} such that the VPW-FRI parameters are uniquely determined from the time-encodings.

Given that the ECG signal is parameterized by 4 L parameters during a time period T, the theoretical rate of innovation is 4 L/T [4]. The IF-TEM sampler is used to acquire the 4 L+1 Fourier coefficients of the ECG signal in an interval T based on the method described above, and then the Fourier-based reconstruction established by [4] is used. In the following, the inventors derive conditions for the IF-TEM parameters and sampling kernel g (t) under which 4 L+1 IF-TEM samples in an interval T are sufficient to recover the ECG signal uniquely.

Similar to the method described above, the inventors define the sampling kernel g(t) to remove the zeroth Fourier coefficient of the filtered signal:

$$g ( t ) = \{ \begin{matrix}{\sum }_{k ∈ 𝒦} & {e}^{jk {ω}_{0} t} , t ∈ ( - T / 2 , T / 2 ] \\ 0 , & elsewhere .\end{matrix} \qquad ( 63 )$$

One particular choice of the sampling kernel is a sum-of-sincs (SoS) kernel generated by

$$\hat{g} ( ω ) = {\sum }_{k ∈ 𝒦} sin c ( \frac{ω}{{ω}_{0}} - k ) .$$

The sampling kernel g(t) is designed to pass the Fourier coefficients X[k], k∈ [symbol] while suppressing all other coefficients X[k], k∉ [symbol] where [symbol] ={−K, . . . , −1,1, . . . , K}. In the following, the inventors show that for the sampling kernel choice of Eq. (63), they can uniquely identify an ECG signal described as a VPW-FRI signal, from the IF-TEM time instances. Since it was already demonstrated in [4] that the ECG signal can be recovered using the signal's Fourier coefficients, if the FSCs are estimated from IF-TEM according to the technique of the present disclosure, the ECG signal can be perfectly reconstructed. The results are summarized in the following theorem.
Theorem 5. Let x(t) be an ECG signal, described by a T-periodic VPW-FRI model of the form

$$x ( t ) = {\sum }_{l = 0}^{L - 1} {x}_{k} ( t ) ,$$

as defined in Eq. (60)-Eq. (62). Consider the sampling mechanism shown in FIG. 32. Let the sampling kernel g(t) satisfy:

$$\hat{g} ( k {ω}_{0} ) = \{ \begin{matrix}1 & if k ∈ 𝒦 = \{ - K , ⋯ , - 1 , 1 , ⋯ , K \} , \\ 0 & otherwise\end{matrix}$$

Choose the real positive TEM parameters {b, κ, δ} such that <b<∞, and

$$\frac{b - c}{κδ} \geq \frac{8 L + 2}{T} \qquad ( 64 )$$

Then, the ECG parameters

$${\{ {t}_{l} , {r}_{l} , {c}_{l} , {d}_{l} \}}_{l = 0}^{L - 1}$$

can be perfectly recovered from the IF-TEM outputs if K≥4 L+1.
Proof. Consider a positive integer K and a number T>0. Let 0≤t₁<t₂< . . . <t_{N}<T for an integer N, and

$${ω}_{0} = \frac{2 π}{T} .$$

The IF-TEM input is the filtered signal y(t), which is the T-periodic signal defined as

$$y ( t ) = {\sum }_{k ∈ 𝕫} X [ k ] \hat{g} ( k {ω}_{0} ) {e}^{jk {ω}_{0} t} = {\sum }_{k ∈ 𝒦} X [ k ] {e}^{jk {ω}_{0} t} . \qquad ( 65 )$$

The output of the IF-TEM is a set of time instances [symbol] Given {tₙ} one can determine the measurements {yₙ} by using Eq. (2). The relation between the measurements yₙ and the desired FSCs is as given in Eq. (26) above:

$${y}_{n} = {\int }_{{t}_{n}}^{{t}_{n + 1}} y ( t ) dt = {\sum }_{k ∈ 𝒦} X [ k ] \frac{( {e}^{jk {ω}_{0} {t}_{n + 1}} - {e}^{jk {ω}_{0} {t}_{n}} )}{jk {ω}_{0}} . \qquad ( 66 )$$

It was shown above that the Fourier coefficients [symbol] can be uniquely determined provided that there are at least N≥2K+2 time instances

$${\{ {t}_{n} \}}_{n = 1}^{N}$$

in an interval T, where K should be at least the number of degrees of freedom of the signal x(t). This implies that K≥4 L and there should be a minimum of 8 L+2 IF-TEM time instances within an interval of T to enable recovery of the FSCs, and subsequent reconstruction of the FRI signal. To ensure this, the IF-TEM parameters are chosen such that:

$$\frac{b - c}{κδ} \geq \frac{8 L + 2}{T} \qquad ( 67 )$$

After computing the FSCs, the VPW-FRI reconstruction described in [4] is used to recover the ECG signal x(t) (see Algorithm 4).

Based on Theorem 5, a reconstruction algorithm to compute the FRI parameters from IF-TEM firings is presented in Algorithm 4.

Algorithm 4 Reconstruction of an ECG signal using an IF-TEM sampler.

| | |
|---|---|
| | $Input : N \geq 8 L + 2 spike times {\{ {t}_{n} \}}_{n = 1}^{N} in a period T .$ |
| 1: | Let n ← 1 |
| 2: | while n ≤ N − 1 do |
| 3: | Compute yₙ = − b(tₙ₊₁ − tₙ) + κδ |
| 4: | n := n + 1. |
| 5: | end while |
| 6: | Compute B using Eq. (29) |
| 7: | $Compute y = {[ {\int }_{{t}_{1}}^{{t}_{2}} y ( t ) dt , {\int }_{{t}_{2}}^{{t}_{3}} y ( t ) dt , … , {\int }_{{t}_{N - 1}}^{{t}_{N}} y ( t ) dt ]}^{T} using Eq . ( 66 )$ |
| 8: | Compute the Fourier coefficients vector x = B^{†}y |
| 9: | Build the Toeplitz matrix S from X[k] for the positive part of the spectrum |
| 10: | Denoise S or X[k] using a denoising method of [7] |
| 11: | Find the annihilating filter coefficients by solving Sh = 0 |
| 12: | Compute uₗ the roots of h |
| 13: | $Compute {t}_{l} = - \frac{T ∠ {u}_{l}}{2 π}$ |
| 14: | $Compute {r}_{l} = \frac{T log \vert {u}_{l} \vert}{2 π}$ |
| 15: | Build the Vandermonde matrix V from the roots uₗ |
| 16: | $Solve \frac{1}{T} Vc = x where x contains the Fourier coefficients X [ k ] and c ∈ ℂ the$ |
| | amplitudes cₗ |
| 17: | $return {\{ {t}_{l} , {r}_{l} , {c}_{l} \}}_{l = 0}^{L - 1}$ |
| 18: | $Calculate {d}_{l} = {c}_{l}^{*} , the hermitian conjugate of {c}_{l}$ |
| | $Output : {\{ {t}_{l} , {r}_{l} , {c}_{l} , {d}_{l} \}}_{l = 0}^{L - 1} .$ |

In the following, the performance of the proposed approach for both ECG reconstruction and HRM is evaluated and compared to existing techniques using real ECG recordings of 30 subjects from [6]. Specifically, the inventors examined the resting scenario of [6], in which the participants were lying on a table wired to several monitoring devices and were told to breath calmly and avoid large movements for at least 10 minutes.

First, the inventors considered the problem of sampling and reconstructing ECG signals by modeling them as VPW-FRI pulses using the model in Eq. (60), with K=10 (which as described by [4] and [5] results in the best recovery). An example of a single ECG pulse reconstruction can be seen in FIG. 33. The ECG pulse is taken from [6] and the reconstruction is performed using 82 samples for each approach. As shown in Table 3 the method of the disclosure provides the best reconstruction quality in terms of Root-Mean-Square Error (RMSE), compared to [4] and [5].

TABLE 3

| Method | RMSE |
|---|---|
| ECG-TEM | 0.005 |
| VPW-FRI Ref. 4 | 0.029 |
| Differential VPW-FRI Ref. 5 | 0.14 |

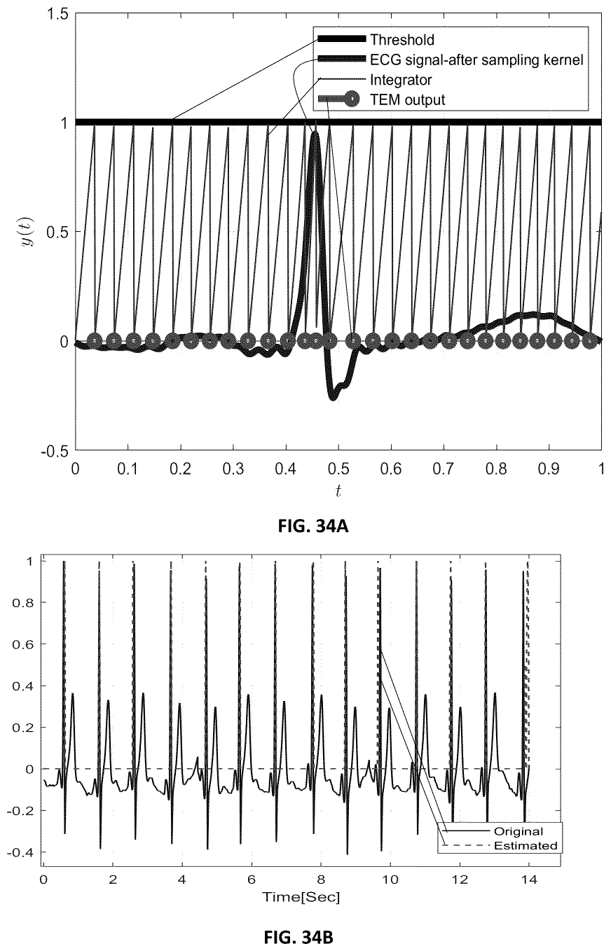

The ECG reconstruction is then utilized to conduct HIRM and compare to one calculated from a known synchronously sampled ECG at 2000 [Hz][6], which is considered as the ground-truth. In order to perform HIRM, the inventors first sample the ECG signal using IF-TEM and reconstruct the ECG's R-waves. Then, each half a second, an FFT-based peak selection is performed on the R-peaks obtained from the last 40 seconds, based on a resting heartbeat frequency band. It is noted that these settings for 10-minute monitoring led to 450 points for comparison to ground-truth, for each participant. FIGS. 34A and 34B show an example of IF-TEM sampling and reconstruction example, wherein FIG. 34A shows the sampling mechanism of a filtered ECG pulse by IF-TEM and FIG. 34B shows the reconstructed R waves of the ECG signal.

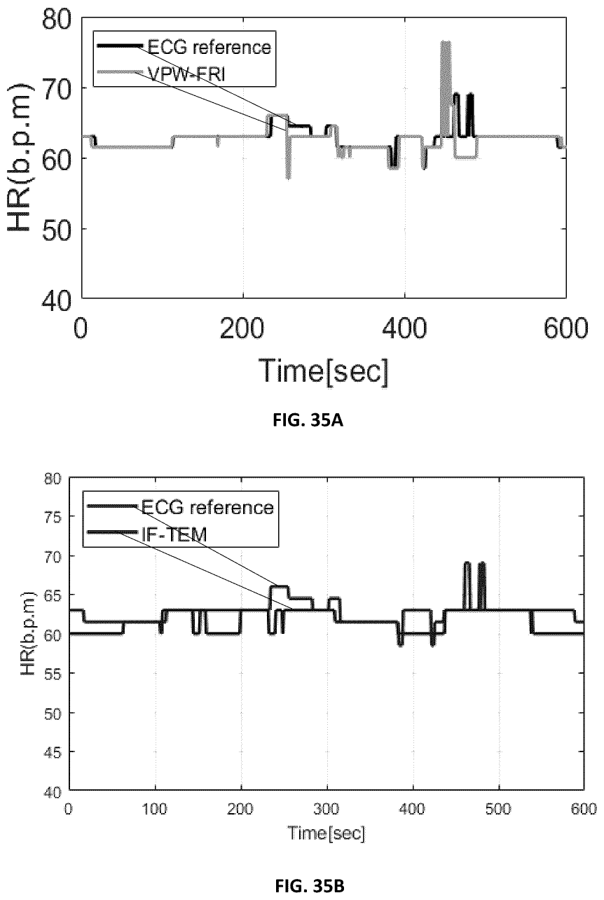

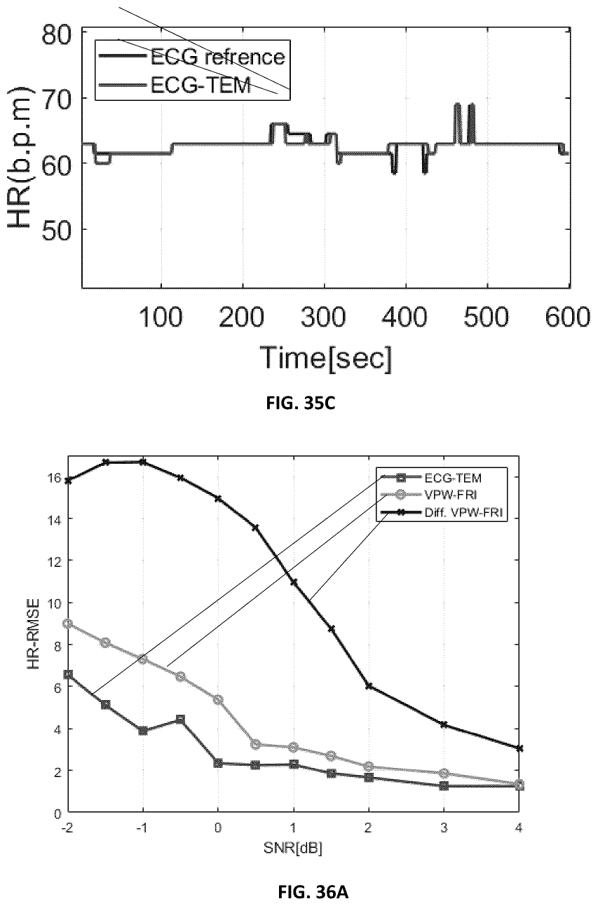

FIGS. 35A to 35C show HR monitoring performance for SNR=2 [dB] using VPW-FRI [4] (FIG. 35A), Differentiated VPW-FRI [5] (FIG. 35B), and ECG-TEM (FIG. 35C). One can see in FIG. 35C that the proposed HRM using IF-TEM shows great resemblance to that of the reference ECG, compared to the other techniques.

Finally, to evaluate the quality of the estimates using the method of the disclosure, the inventors used the following statistical metrics: 1. Success rate, defined here as the percentage of time in which the HR estimate was different from the reference output by less than 2 beats per minute (b.p.m.), 2. Pearson Correlation Coefficient (PCC), 3. Mean-Absolute Error (MAE), and 4. RMSE. Various SNR cases were tested (defined as the inverse of an i.i.d. Gaussian noise variance), each of which involves ECG data of 30 individuals from [6]. Hence, the performance score produced for each metric, given SNR, is taken as the median across all 30 participants.

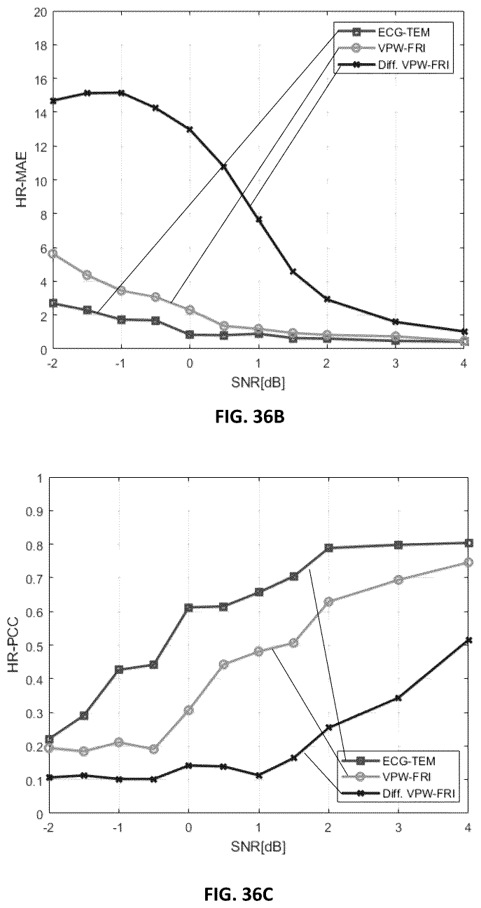

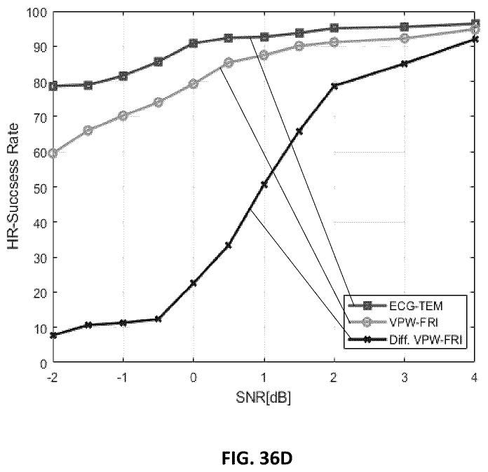

FIGS. 36A to 36D show, respectively, the RMSE, MAE, PCC, and Success-Rate, for HR estimation by all examined methods, as a function of the SNR. One sees that the HRM based on the IF-TEM outperforms the other compared methods in all 4 metrics, for every SNR value. Detailed median accuracy scores for the case of SNR=2 [dB] can be found in Table 4, showing superior HRM results.

TABLE 4

| Method | Success rate | PCC | MAE | RMSE |
|---|---|---|---|---|
| ECG-TEM | 95.1% | 0.78 | 0.60 | 1.7 |
| VPW-FRI [4] | 91.1% | 0.63 | 0.83 | 2.19 |
| Differential VPW-FRI [5] | 78.7% | 0.25 | 2.92 | 6.03 |

Thus, in the present disclosure, using an IF-TEM sampler, a time-based sub-Nyquist sampling and reconstruction approach for ECG signals was proposed. The inventors applied their method to the calculation of HRM from the recovered ECG signal and demonstrated high accuracy in comparison to a known HRM evaluation using a synchronous ADC. The simulation results indicate that the proposed method outperforms previous techniques and enables efficient sampling at sub-Nyquist rate.

The drawings and the examples of the present disclosure present just some examples of the invented systems and methods. Many variations are possible within the scope of the disclosure, and they can provide ground to further claims than listed below.

1. A signal processing system for processing an input analog signal, x(t), comprising a train of L pulses of a predetermined shape, the system comprising a sampling system comprising:
a kernel characterized by predetermined size of a kernel support set, [symbol] , and configured to receive the input analog signal and generate a kernel-filtered signal, y(t);
a sampler configured as an integrate and fire time encoding machine, IF-TEM, being parametrized by one or more predetermined characteristic parameters comprising one or more positive real numbers, said sampler being operable to receive the kernel-filtered signal and produce sampling data indicative of a series of N time-encodings, tₙ, of the kernel-filtered signal forming discrete time representation of said analog signal;
wherein said size of the kernel support set is in a predetermined relation with a number F of degrees of freedom in the input signal defined by characteristic parameters of the input signal.

2. (canceled)

3. The system of claim 1, characterized by at least one of the following: said characteristic parameters defining the degrees of freedom comprise amplitude and time delays of said train of L pulses forming the input signal, and said characteristic parameters defining the degrees of freedom comprise amplitudes and time parameters of symmetric and anti-symmetric parts of the pulses.

4. (canceled)

5. The system of claim 1, wherein said kernel is configured with a minimal transmission coefficient for zero frequency component of the input signal as compared to transmission coefficients for other frequency components to thereby substantially suppress transmission of the zero frequency component of the input signal, thereby enabling noise-resilient reconstruction of the input analog signal.

6. (canceled)

7. The system of claim 1, wherein the IF-TEM comprises: an integrator and a discharge circuit, a comparator, and a switch positioned to receive a signal transmitted from the comparator for initiating reset of the integrator and for switching on the discharge circuit, wherein the discharge circuit comprises a capacitor configured to operate in its linear zone to provide rapid and complete discharge of the integrator.

8. (canceled)

9. (canceled)

10. (canceled)

11. (canceled)

12. (canceled)

13. The system according to claim 1, further comprising a reconstruction system configured to receive data indicative of the time-encodings of the kernel-filtered signal and process said data indicative of the time-encodings of the kernel-filtered signal, said processing comprising: creating data indicative of vector representation, y, of the kernel-filtered signal by utilizing data indicative of the one or more characteristic parameters of the IF-TEM, and by utilizing data indicative of the kernel support set, to define a linear relation between said data indicative of vector representation, y, of the kernel-filtered FRI signal and data indicative of a vector representation, \hat{x}, of Fourier series coefficients of the signal, thereby enabling reconstruction of the input analog signal, x(t).

14. The system according to claim 13, wherein the reconstruction system comprises:
an analyzer configured and operable to analyze the data indicative of the time-encodings of the kernel-filtered signal and utilize the data indicative of the characteristic parameters of the IF-TEM to generate data indicative of vector representation, y, of the kernel-filtered signal;
a processor configured and operable to utilize said data indicative of the time-encodings of the kernel-filtered signal and said data indicative of the kernel support set and define a linear relation between the data indicative of the vector representation, y, of the kernel-filtered signal and the vector representation, \hat{x}, of the Fourier series coefficients of the input signal; and
a signal reconstructor processor configured and operable to utilize said linear relation to determine, from said data indicative of the vector representation, y, the vector representation, \hat{x}, of the Fourier series coefficients of the input signal, thereby enabling reconstruction of the analog signal x(t).

15. The system according to claim 14, wherein said signal reconstructor processor comprises an extractor utility configured and operable to process the vector representation, \hat{x}, of the Fourier series coefficients and extract parameters of the L pulses forming the input analog signal.

16. The system according to claim 13, wherein said linear relation comprises a characteristic matrix having pseudoinverse representation thereof and being configured for describing a relation between said data indicative of vector representation, y, of the kernel-filtered FRI signal and data indicative of a vector representation, \hat{x}, of Fourier series coefficients of the signal.

17. The system according to claim 16, characterized by at least one of the following:
said processor comprises a matrix creator utility configured and operable to process the data indicative of the time encodings of the kernel-filtered signal utilizing said data indicative of the kernel support set to create said characteristic matrix and is configured and operable to utilize said characteristic matrix to process said data indicative of the vector representation, y, of the kernel-filtered signal by applying thereto the pseudoinverse representation of said characteristic matrix to obtain the vector representation, \hat{x}, of the Fourier series coefficients of the input signal, and
said kernel is configured with a minimal transmission coefficient for zero frequency component of the input signal as compared to transmission coefficients for other frequency components to thereby substantially suppress transmission of the zero frequency component of the input signal, said kernel support set [symbol] includes integers symmetric around zero: [symbol] ={−K, . . . , −1,1, . . . , K}; said reconstruction system being configured and operable to create said characteristic matrix being a Vandermonde type invertible matrix having linearly independent columns, said characteristics matrix describing the relation between partial sums vector z of said vector representation y, of the kernel-filtered FRI signal and a vector \hat{z} associated with said vector representation \hat{x}, of the Fourier series coefficients of the FRI signal.

18. The system according to claim 13, characterized by at least one of the following:
said kernel support set [symbol] , includes integers symmetric around zero: [symbol] ={−K, . . . , −1, 0, 1, . . . , K};
said kernel is configured with a minimal transmission coefficient for zero frequency component of the input signal as compared to transmission coefficients for other frequency components to thereby substantially suppress transmission of the zero frequency component of the input signal, said kernal support set [symbol] includes integers symmetric around zero: [symbol] ={−K, . . . , −1,1, . . . , K};
the reconstruction system is configured and operable to determine the parameters of the input signal with a reconstruction error not exceeding −25 dB, for the input signal being sampled by the sampling system at asynchronous sampling rates of at least 10 times lower than the Nyquist rate.

19. (canceled)

20. The system according to claim 16, wherein said kernel is configured with a minimal transmission coefficient for zero frequency component of the input signal as compared to transmission coefficients for other frequency components to thereby substantially suppress transmission of the zero frequency component of the input signal, said kernel support set [symbol] includes integers symmetric around zero: [symbol] ={−K, . . . , −1,1, . . . , K}; said reconstruction system being configured and operable to create said characteristic matrix being a Vandermonde type invertible matrix having linearly independent columns, said characteristic matrix describing the relation between partial sums vector z of said vector representation y, of the kernel-filtered FRI signal and a vector \hat{z} associated with said vector representation \hat{x}, of the Fourier series coefficients of the FRI signal, the reconstruction system being configured and operable to carry out the following: utilize said vector representation, y, of the kernel-filtered FRI signal to generate the partial sums vector \hat{z}: utilize the partial sums vector z and said characteristic matrix to determine the vector \hat{z} being in a predetermined relation with the vector representation, \hat{x}, of the Fourier series coefficients of the analog signal; and determine the vector representation, \hat{x}, from said vector z by selecting predetermined elements of the vector \hat{z}.

21. (canceled)

22. The system of claim 17, wherein said kernel is configured with a minimal transmission coefficient for zero frequency component of the input signal as compared to transmission coefficients for other frequency components to thereby substantially suppress transmission of the zero frequency component of the input signal, said kernel support set [symbol] includes integers symmetric around zero, [symbol] ={−K, . . . , −1,1, . . . , K}; said reconstruction system being configured and operable to create said characteristic matrix being a Vandermonde type invertible matrix having linearly independent columns, said characteristic matrix describing the relation between partial sums vector z of said vector representation y, of the kernel-filtered FRI signal and a vector \hat{z} associated with said vector representation \hat{x}, of the Fourier series coefficients of the FRI signal, wherein each successive component of the vector of partial sums, being a successive partial sum, is determined as a sum of a preceding partial sum and a linear transform, yₙ, of a respective difference between two consecutive time encodings tₙ₊₁ and tₙ defined as: yₙ=−b(tₙ₊₁−tₙ)+κδ.

23. The system of claim 15, wherein said extractor utility is configured and operable to apply spectral analysis to the vector representation, \hat{x}, of the Fourier series coefficients to thereby extract the parameters of the L pulses of the input signal.

24. (canceled)

25. The system of claim 1, characterized by at least one of the following:
the kernel support set, [symbol] is configured with a number K of non-zero frequency components in the input signal, said number K being defined to allow determination of a minimum number of Fourier series coefficients (FSC) of the input signal allowing a unique reconstruction of the input signal;
the kernel comprises any one of the following, a sinc function kernel, a sum-of-sincs (SoS) kernel, a sum-of-modulated spline kernel, a polynomial-reproducing kernel, or an exponential-reproducing kernel;
the kernel is compactly supported.

26. The system of claim 25, wherein the kernel support set, [symbol] , is configured with a number K of non-zero frequency components in the input signal, said number K being defined to allow determination of a minimum number of Fourier series coefficients (FSC) of the input signal allowing a unique reconstruction of the input signal, said kernel being configured with a minimal transmission coefficient for zero frequency component of the input signal as compared to transmission coefficients for other frequency components to thereby substantially suppress transmission of the zero frequency component of the input signal, said support set [symbol] of indices being chosen to exclude zero and include integers symmetric around zero:
$$𝒦 = \{ - K , … , - 1 , 1 , … , K \} .$$

27. (canceled)

28. (canceled)

29. (canceled)

30. (canceled)

31. The system of claim 13, wherein said kernel support set, [symbol] , includes integers symmetric around zero: [symbol] ={−K, . . . , −1, 0, 1, . . . , K}, the kernel being configured with the support set [symbol] satisfying a condition that | [symbol] |≥2 L, where 2 L is the number F of the degrees of freedom in the input signal having said L pulses of the predetermined shape defining L amplitudes and L time delays characterizing the input signal.

32. (canceled)

33. (canceled)

34. (canceled)

35. (canceled)

36. (canceled)

37. (canceled)

38. (canceled)

39. The system of claim 1, wherein
said input signal has a predetermined time characteristic T;
the kernel is configured with the support set [symbol] satisfying a condition that | [symbol] |≥L;
said L pulses are of the predetermined shape such that the input signal is characterized by L amplitudes and L time delays of said L pulses defining the number F=2 L of degrees of freedom in the input signal, and the time delays are arranged in accordance with a predetermined time grid; and
the IF-TEM is configured to sample a minimum value of the number N of the time-encodings, N≥2K+2, within the predetermined time characteristic T of the input signal, wherein K satisfies a condition that K≥L, to thereby enable reconstruction of the L amplitudes and the L time delays of the L pulses, and wherein the time characteristic T is one of the following: a period T of a periodic input signal in the form of said train of L pulses; or a time interval T defined by a finite time interval [0, T) of time delays of a finite train of the L pulses of a nonperiodic input signal.

40. (canceled)

41. (canceled)

42. (canceled)

43. (canceled)

44. An analog to digital converter (ADC) comprising the signal processing system of claim 1.

45. A signal reconstruction system for reconstructing an analog signal, x(t), in the form of a train of L pulses of a predetermined shape, from data indicative of discrete time representation of said analog signal generated by the signal processing system ofan claim 1, the signal reconstruction system being configured and operable to carry out the following:
utilizing input data comprising data indicative of the kernel support set used in generation of said kernel-filtered signal and data indicative of the characteristic parameters of the IF-TEM, to analyze said series of N time-encodings and create a linear relation between data indicative of vector representation, y, of the kernel-filtered signal and data indicative of a vector representation, \hat{x}, of Fourier series coefficients of the signal, thereby enabling reconstruction of the input analog signal, x(t).

46. A signal reconstruction system for reconstructing an analog signal, x(t), formed by a train of L pulses of a predetermined shape, the system being configured and operable to carry out the following:
receiving data indicative of discrete time representation of said analog signal being indicative of a series of N time-encodings, tₙ, obtained by an integrate and fire time encoding mechanism (IF-TEM), applied to a kernel-filtered signal, y(t);
utilizing input data comprising data indicative of a kernel support set used in generation of said kernel-filtered signal and data indicative of one or more characteristic parameters of the IF-TEM, to analyze said data indicative of the series of N time-encodings and create a linear relation between data indicative of vector representation, y, of the kernel-filtered signal and data indicative of a vector representation, \hat{x}, of Fourier series coefficients of the signal, thereby enabling reconstruction of the input signal, x(t).

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)
